(19) United States
(12) Patent Application Publication
(10) Pub. No.: US 2024/0021497 A1
(43) Pub. Date: Jan. 18, 2024

(54) SEMICONDUCTOR STRUCTURE WITH THROUGH VIA STRUCTURE AND METHOD FOR MANUFACTURING THE SAME

(71) Applicant: Taiwan Semiconductor Manufacturing Company, Ltd., Hsinchu (TW)

(72) Inventors: Yi-Bo LIAO, Hsinchu (TW); Li-Zhen YU, New Taipei City (TW); Lin-Yu HUANG, Hsinchu (TW)

(73) Assignee: Taiwan Semiconductor Manufacturing Company, Ltd., Hsinchu (TW)

(21) Appl. No.: 17/867,083

(22) Filed: Jul. 18, 2022

(51) Int. Cl. H01L 23/48; H01L 23/532; H01L 29/06; H01L 29/423; H01L 29/417; H01L 29/786; H01L 29/775; H01L 21/764; H01L 21/768; H01L 29/40; H01L 29/66

(52) U.S. Cl. CPC H01L 23/481; H01L 23/5329; H01L 29/0673; H01L 29/42392; H01L 29/41733; H01L 29/78696; H01L 29/775; H01L 21/764; H01L 21/76898; H01L 29/401; H01L 29/66742; H01L 29/66439

(57) ABSTRACT

Semiconductor structures and methods for manufacturing the same are provided. The semiconductor structure includes a channel member having a longitudinal axis in a first direction, and the channel member has a first portion and a second portion separated from each other by a blank region. The semiconductor structure also includes a first gate structure formed over the blank region and having a longitudinal axis in a second direction different from the first direction and an isolation structure formed in the blank region and abutting the first gate structure in the second direction. The semiconductor structure also includes a through via structure formed through the isolation structure. In addition, the through via structure includes a first conductive filling layer, and a first air gap is sandwiched between the first conductive filling layer and the isolation structure.

### BACKGROUND

The electronics industry is experiencing ever-increasing demand for smaller and faster electronic devices that are able to perform a greater number of increasingly complex and sophisticated functions. Accordingly, there is a continuing trend in the semiconductor industry to manufacture low-cost, high-performance, and low-power integrated circuits (ICs). So far, these goals have been achieved in large part by scaling down semiconductor IC dimensions (e.g., minimum feature size) and thereby improving production efficiency and lowering associated costs. However, such miniaturization has introduced greater complexity into the semiconductor manufacturing process. Thus, the realization of continued advances in semiconductor ICs and devices calls for similar advances in semiconductor manufacturing processes and technology.

Recently, multi-gate devices have been introduced in an effort to improve gate control by increasing gate-channel coupling, reduce OFF-state current, and reduce short-channel effects (SCEs). However, integration of fabrication of the multi-gate devices can be challenging.

### BRIEF DESCRIPTION OF THE DRAWINGS

Aspects of the present disclosure are best understood from the following detailed description when read with the accompanying Figures. It should be noted that, in accordance with the standard practice in the industry, various features are not drawn to scale. In fact, the dimensions of the various features may be arbitrarily increased or reduced for clarity of discussion.

FIG. 1 illustrates a diagrammatic top view of a semiconductor structure in accordance with some embodiments.

FIGS. 2A to 2ZJ illustrate diagrammatic perspective views of intermediate stages of manufacturing the semiconductor structure shown in region R of FIG. 1 in accordance with some embodiments.

FIGS. 2A-1 to 2ZJ-1 illustrate cross-sectional views of intermediate stages of manufacturing the semiconductor structure shown along line A-A′ of FIG. 1 in accordance with some embodiments.

FIG. 2V-2 illustrates an enlarged cross-sectional view of the semiconductor structure in block B_{2V} shown in FIG. 2V-1 in accordance with some embodiments.

FIG. 2W-2 illustrates an enlarged cross-sectional view of the semiconductor structure in block B_{2W} shown in FIG. 2W-1 in accordance with some embodiments.

FIG. 2ZJ-2 illustrates an enlarged cross-sectional view of the semiconductor structure in block B2ZJ shown in FIG. 2ZJ-1 in accordance with some embodiments.

FIG. 3 illustrates a cross-sectional view of a semiconductor structure in accordance with some embodiments.

FIG. 4 illustrates a cross-sectional view of a semiconductor structure in accordance with some embodiments.

FIG. 5 illustrates a cross-sectional view of a semiconductor structure in accordance with some embodiments.

FIG. 6 illustrates a cross-sectional view of a semiconductor structure in accordance with some embodiments.

FIG. 7 illustrates a cross-sectional view of a semiconductor structure in accordance with some embodiments.

FIGS. 8A to 8C illustrate cross-sectional views of intermediate stages of manufacturing a semiconductor structure in accordance with some embodiments.

FIGS. 9A to 9C illustrate cross-sectional views of intermediate stages of manufacturing a semiconductor structure in accordance with some embodiments.

FIG. 10A illustrates a cross-sectional view of a semiconductor structure in accordance with some embodiments.

FIG. 10B illustrates a cross-sectional view of a semiconductor structure in accordance with some embodiments.

FIG. 10C illustrates a cross-sectional view of a semiconductor structure in accordance with some embodiments.

FIG. 10D illustrates a cross-sectional view of a semiconductor structure in accordance with some embodiments.

FIG. 10E illustrates a cross-sectional view of a semiconductor structure in accordance with some embodiments.

FIG. 11 illustrates a cross-sectional view of a semiconductor structure in accordance with some embodiments.

FIGS. 12A to 12Z illustrate diagrammatic perspective views of intermediate stages of manufacturing the semiconductor structure in accordance with some embodiments.

FIG. 12Z-1 illustrates a cross-sectional view of the semiconductor structure in accordance with some embodiments.

FIG. 12Z-2 illustrates an enlarged cross-sectional view of the semiconductor structure in block B_{12Z} shown in FIG. 12Z-1 in accordance with some embodiments.

FIG. 12Z-3 illustrates a cross-sectional view of the semiconductor structure along line Y_{12SD}-Y_{12SD}′ shown in FIG. 12Z in accordance with some embodiments.

FIG. 12Z-4 illustrates a cross-sectional view of the semiconductor structure along line Y_{12MG}-Y_{12MG}′ shown in FIG. 12Z in accordance with some embodiments.

FIG. 13 illustrates a cross-sectional view of a semiconductor structure 100o in accordance with some embodiments.

FIG. 14 illustrates a diagrammatic perspective view of a semiconductor structure in accordance with some embodiments.

FIG. 14-1 illustrates a cross-sectional view of the semiconductor structure in accordance with some embodiments.

FIGS. 15A and 15B illustrate diagrammatic perspective views of intermediate stages of manufacturing a semiconductor structure in accordance with some embodiments.

FIG. 15B-1 illustrates a cross-sectional view of the semiconductor structure in accordance with some embodiments.

FIG. 16 illustrates a cross-sectional view of a semiconductor structure in accordance with some embodiments.

FIG. 17 illustrates through via structures used as input and output connection in a semiconductor device in accordance with some embodiments.

### DETAILED DESCRIPTION

The following disclosure provides many different embodiments, or examples, for implementing different features of the subject matter provided. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Some variations of the embodiments are described. Throughout the various views and illustrative embodiments, like reference numerals are used to designate like elements. It should be understood that additional operations can be provided before, during, and after the method, and some of the operations described can be replaced or eliminated for other embodiments of the method.

The nanostructure transistors (e.g. nanosheet transistor, nanowire transistor, multi-bridge channel, nano-ribbon FET, gate all around (GAA) transistor structures) described below may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, smaller pitches than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the nanostructure transistors.

Embodiments of semiconductor structures and methods for forming the same are provided. The semiconductor structures may include an isolation structure formed through a gate structure and a through via structure formed through the isolation structure. The through via structure may be configured to connect a top interconnect structure and a bottom interconnect structure at opposite side of the transistors, so that the complicated electrical routing may be reduced. Furthermore, an air gap may be formed adjacent to the through via structure, and therefore coupling capacitance of the resulting device may be greatly reduced.

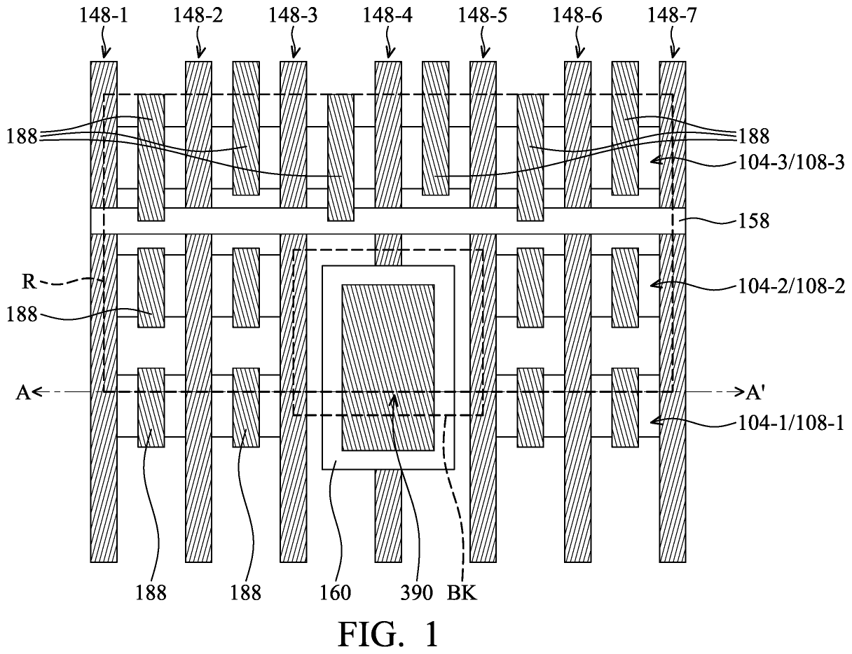

FIG. 1 illustrates a diagrammatic top view of a semiconductor structure 100 in accordance with some embodiments. The semiconductor structure 100 includes channel members 108-1, 108-2, and 108-2 (or fin structures 104-1, 104-2, and 104-3), gate structures 148 (including gate structures 148-1, 148-2, 148-3, 148-4, 148-5, 148-6, and 148-7), a gate isolation structure 158, a wide isolation structure 160, source/drain contacts 188, and a though via structure 390 in accordance with some embodiments. In some embodiments, the channel members 108-1, 108-2, and 108-2 have longitudinal axis in the X direction, and the gate structures 148 have longitudinal axis in the Y direction. It should be noted that the semiconductor structure 100 shown in FIG. 1 has been simplified for the sake of clarity to better understand the inventive concepts of the present disclosure, and additional features may be included in the semiconductor structure 100, and some of the features described below may be replaced, modified, or eliminated.

The semiconductor structure 100 may include multi-gate devices and may be included in a microprocessor, a memory, and/or other IC devices. For example, the semiconductor structure 100 may be a portion of an IC chip that include various passive and active microelectronic devices such as resistors, capacitors, inductors, diodes, p-type field effect transistors (PFETs), n-type field effect transistors (NFETs), metal-oxide semiconductor field effect transistors (MOSFETs), complementary metal-oxide semiconductor (CMOS) transistors, bipolar junction transistors (BJTs), laterally diffused MOS (LDMOS) transistors, high voltage transistors, high frequency transistors, other applicable components, or combinations thereof. The formation of the semiconductor structure 100 will be described in more details below.

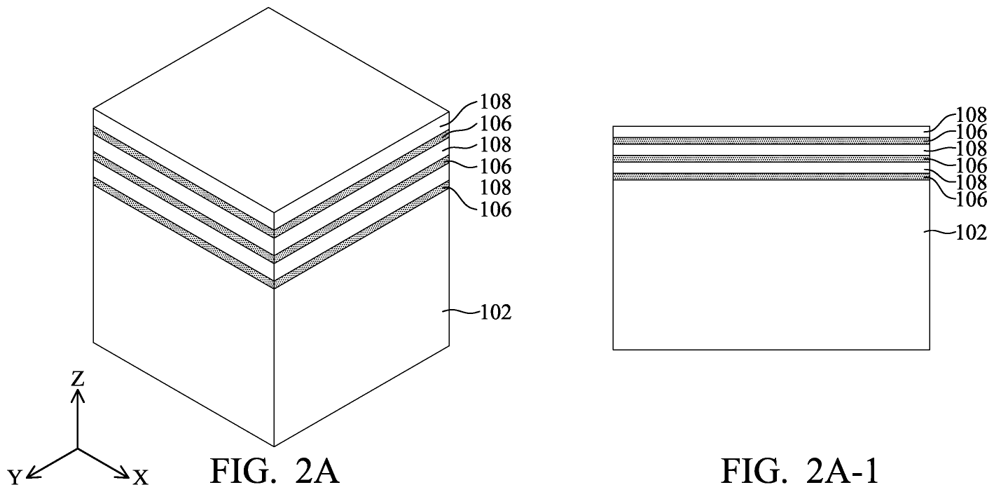

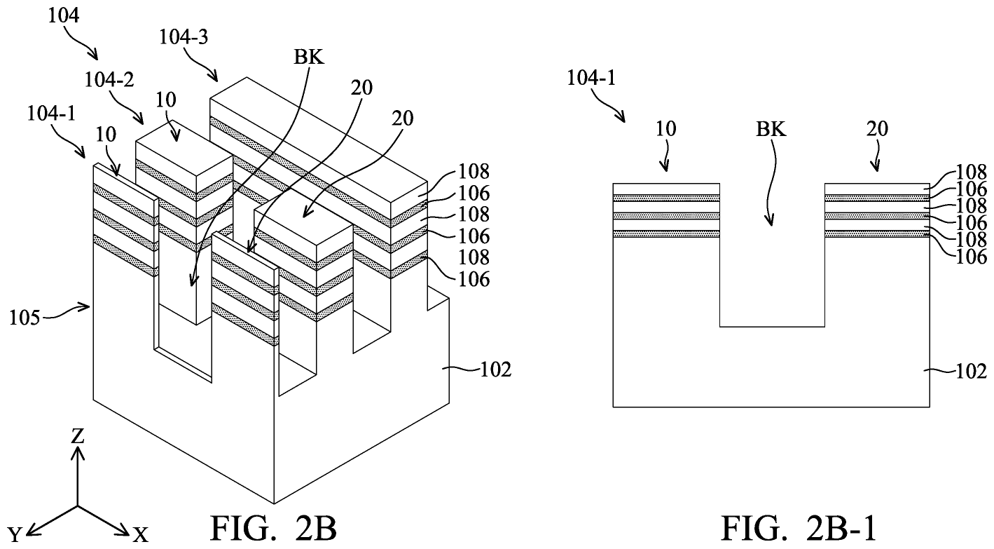

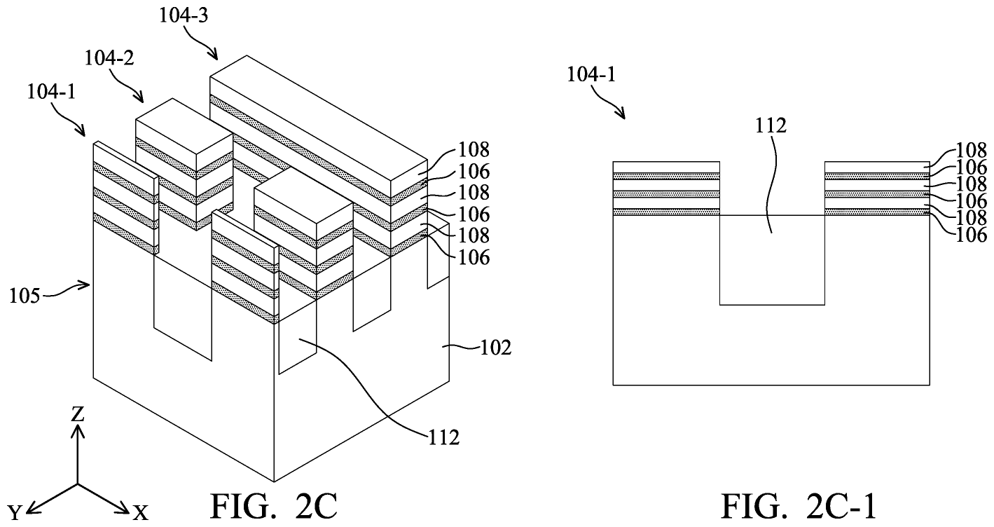

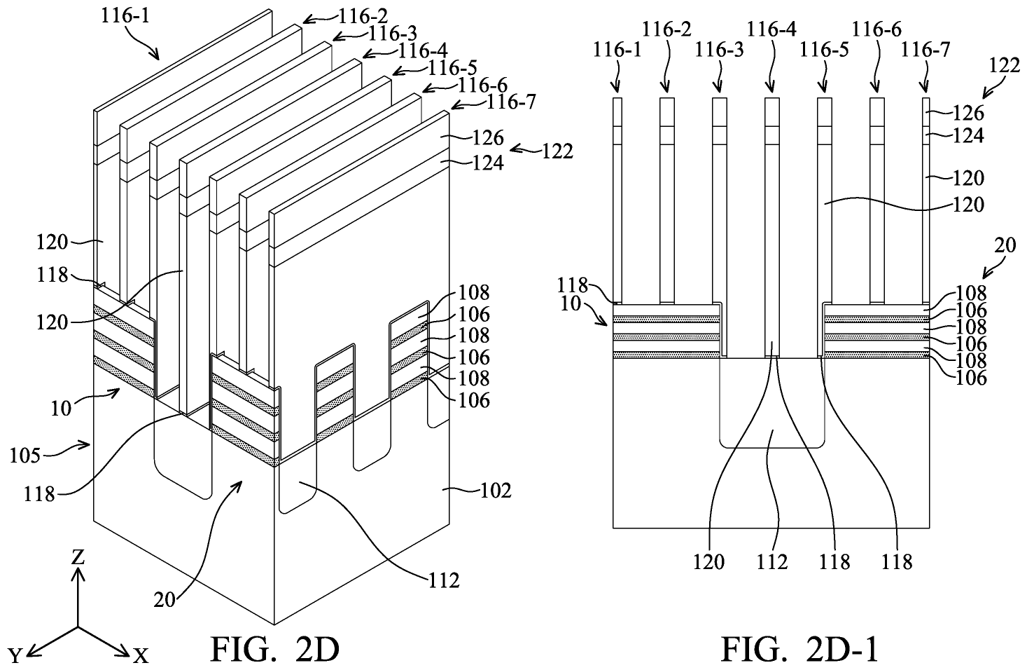

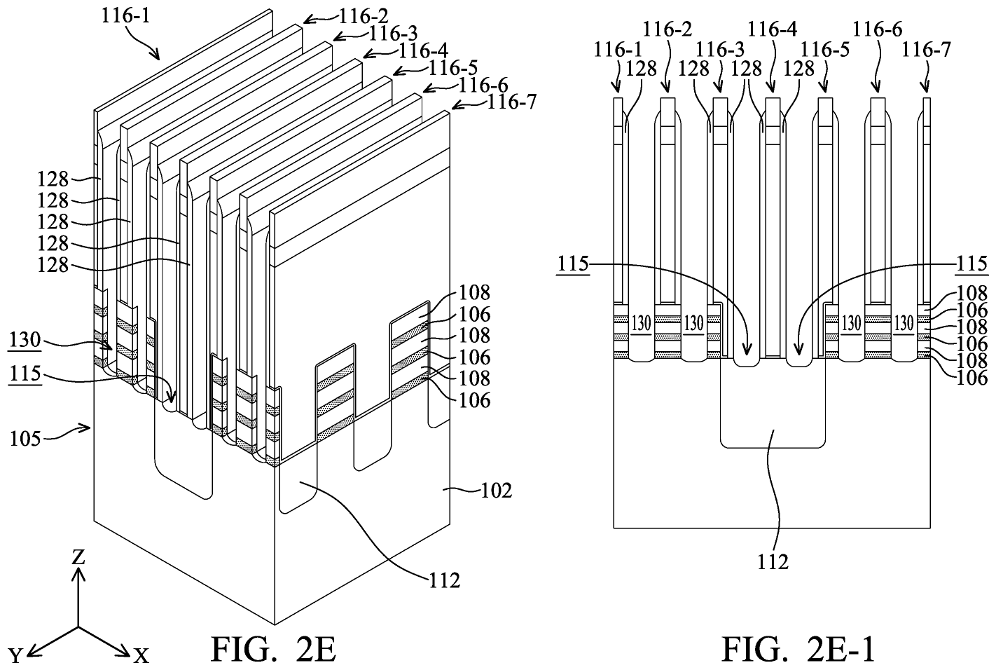

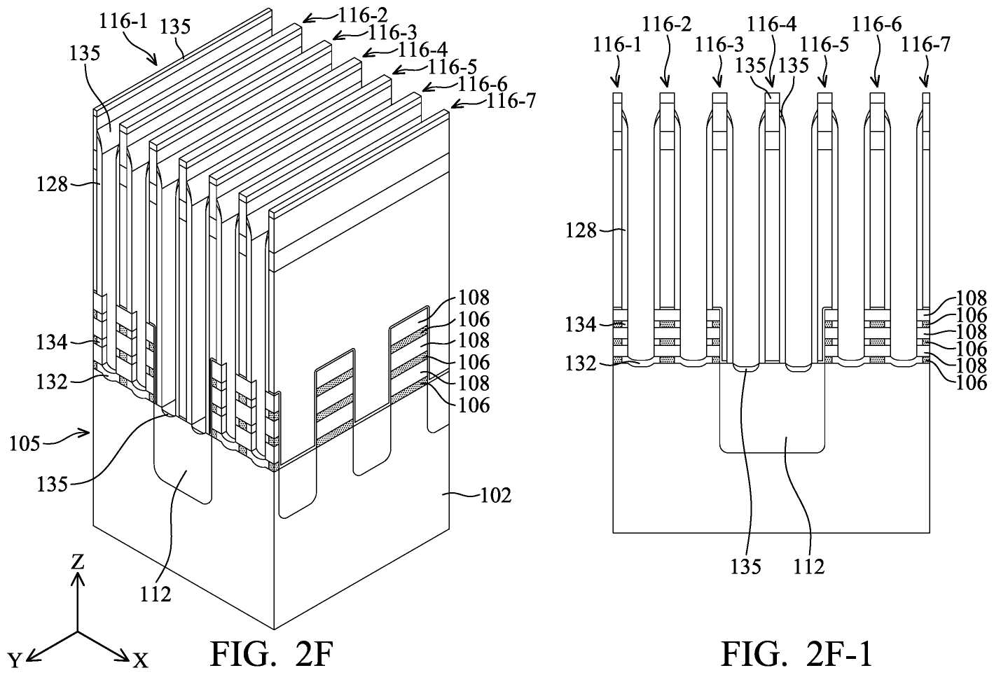

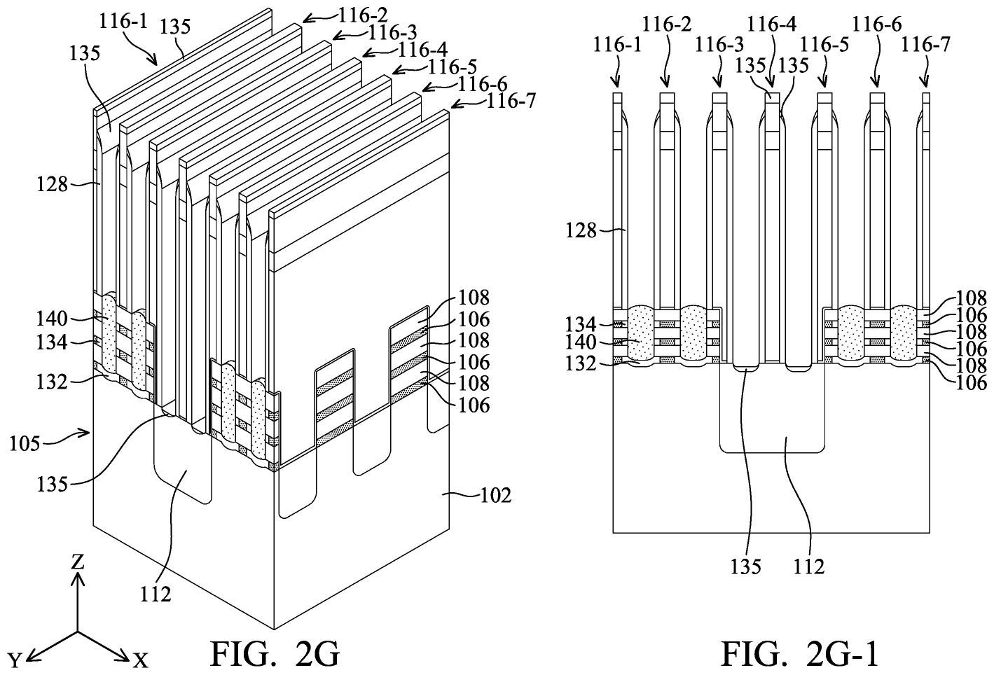

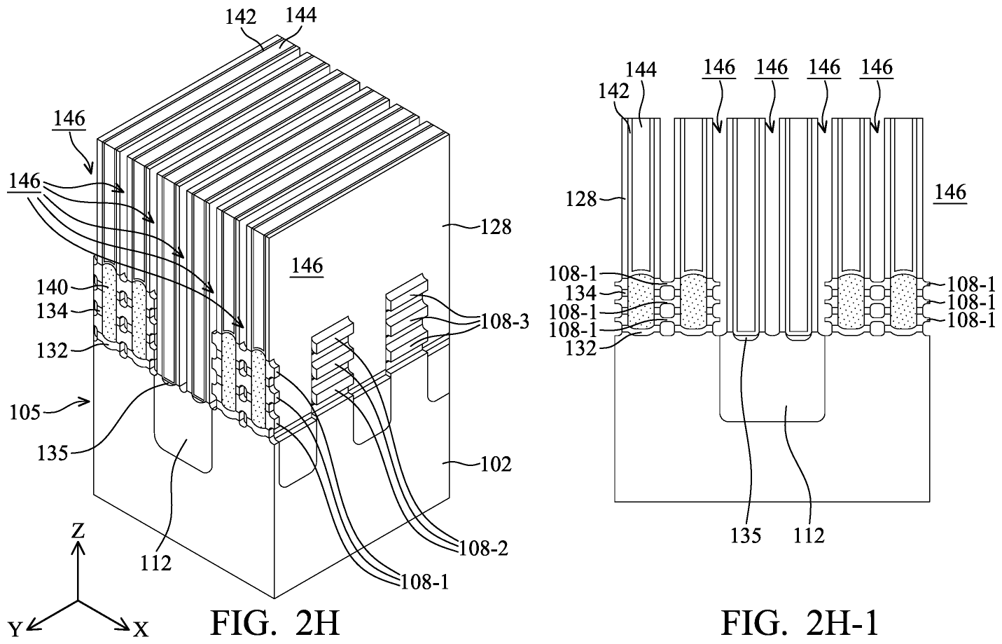

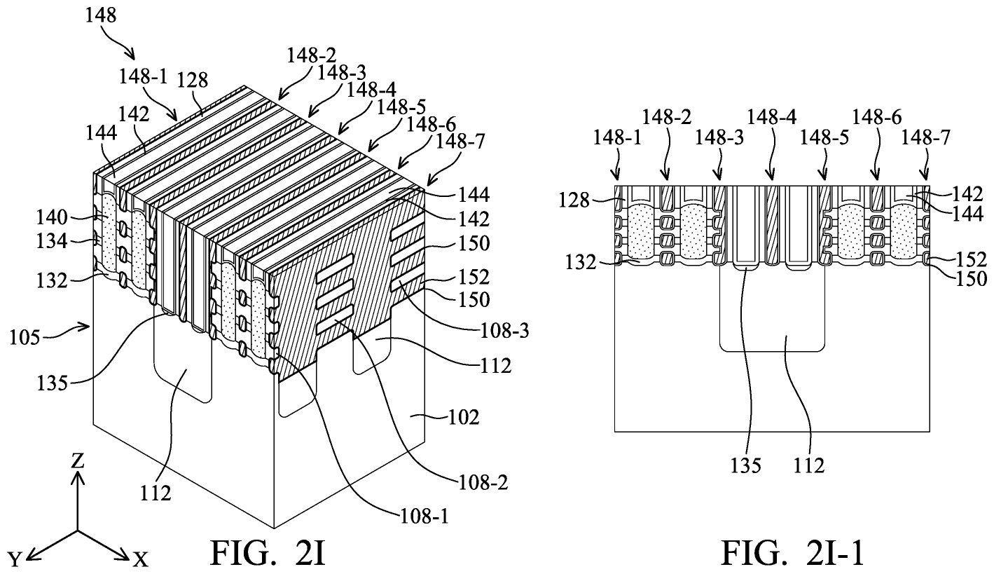

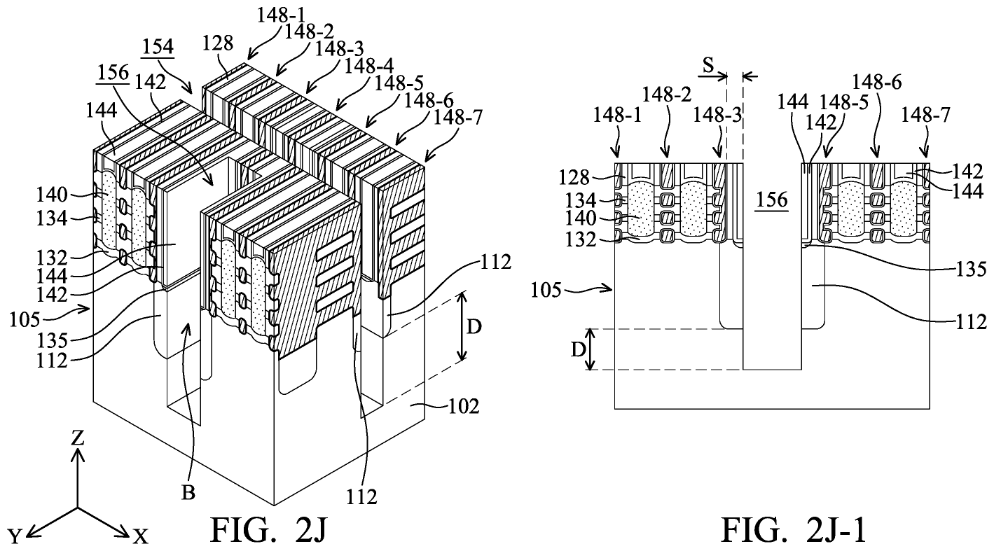

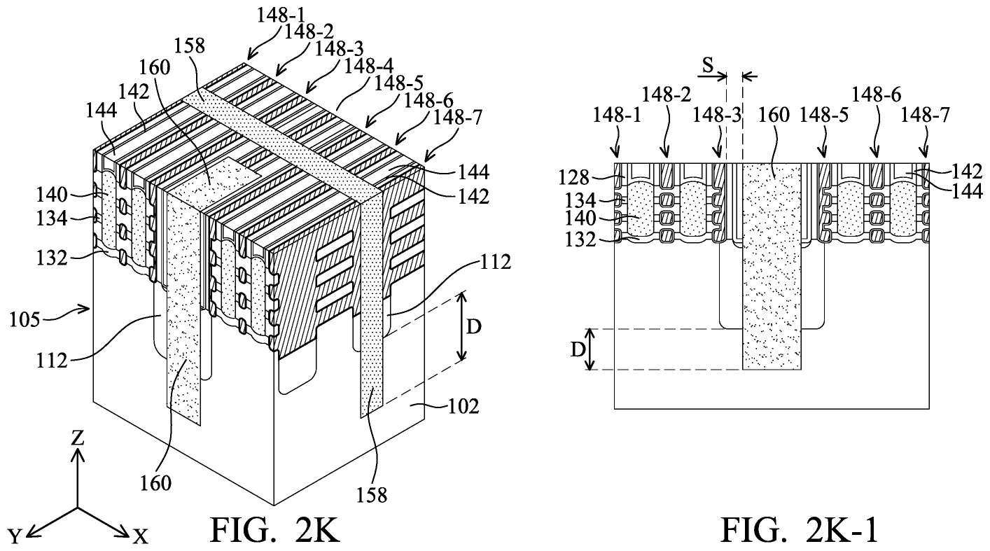

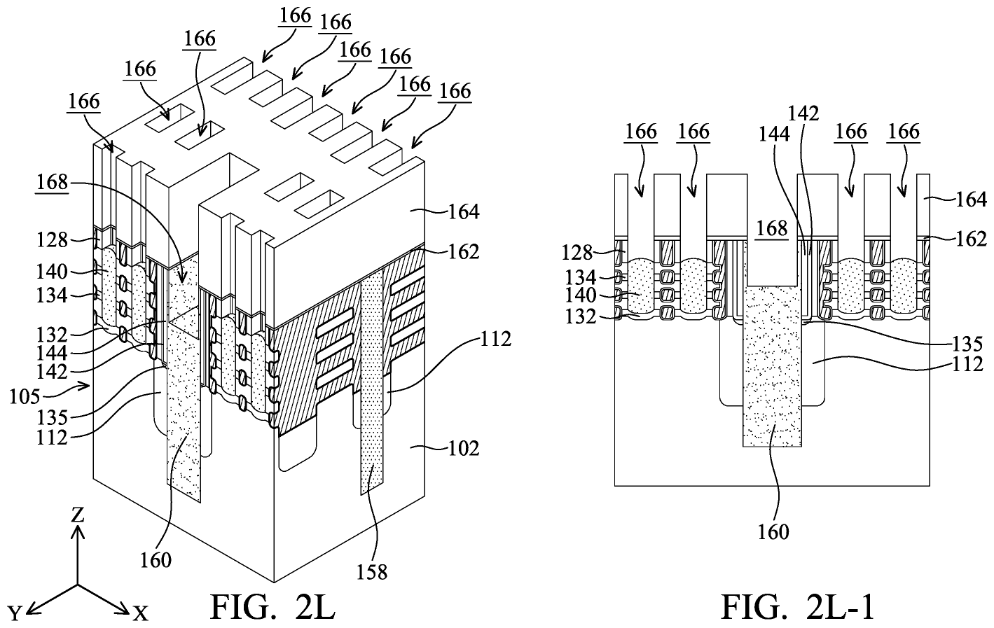

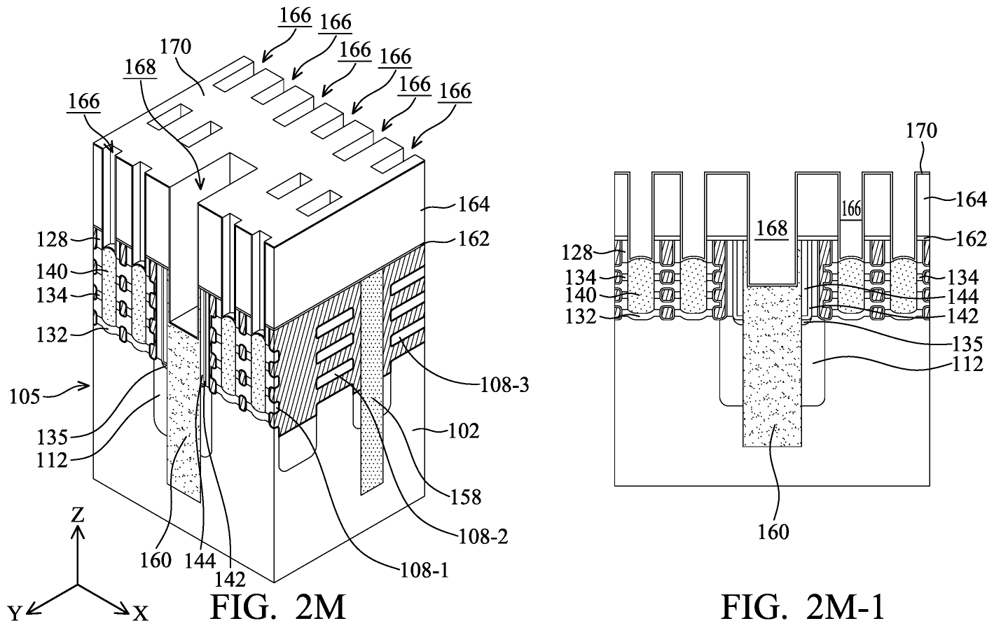

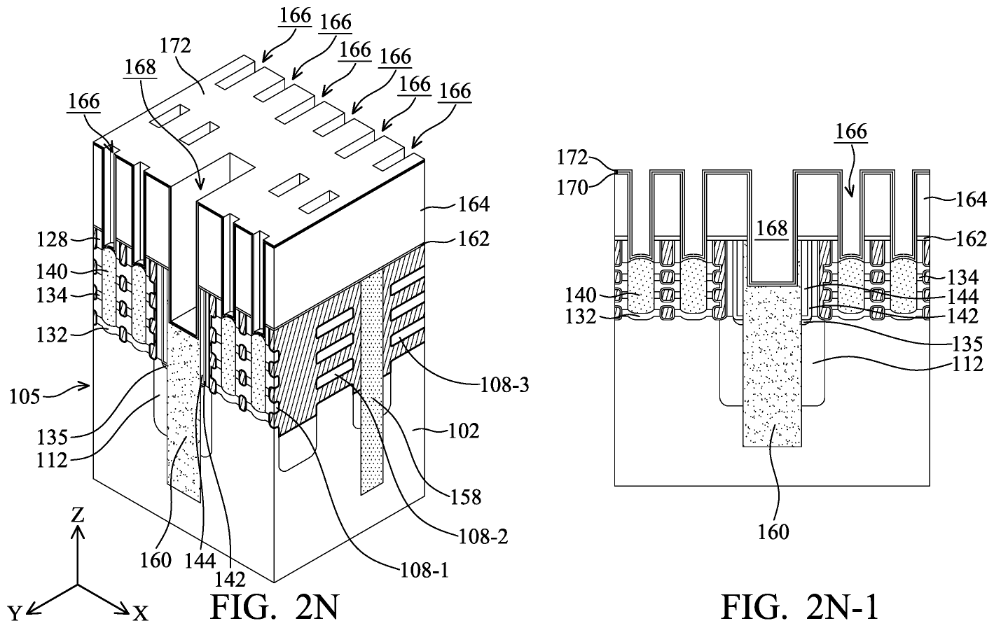

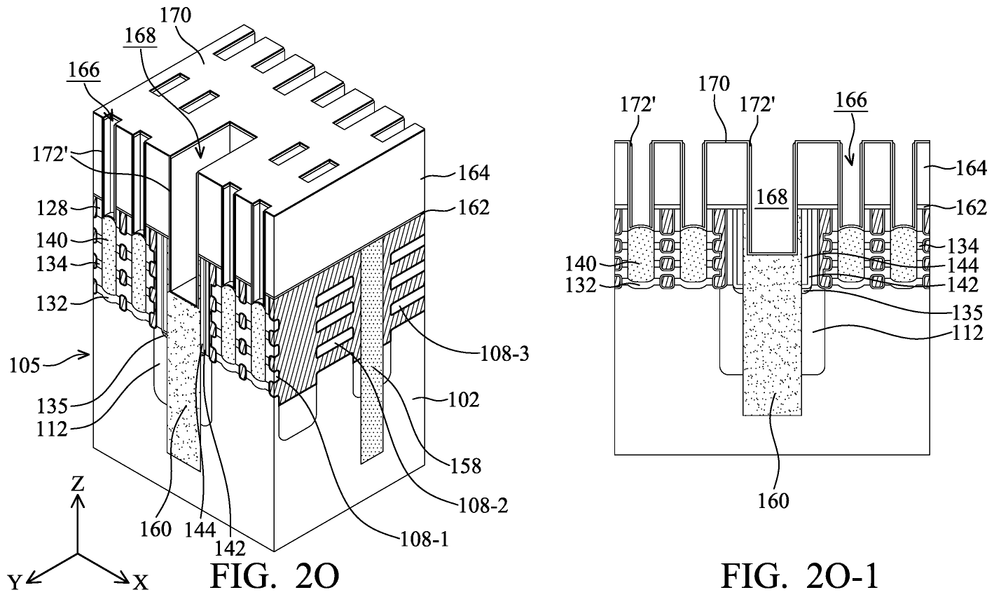

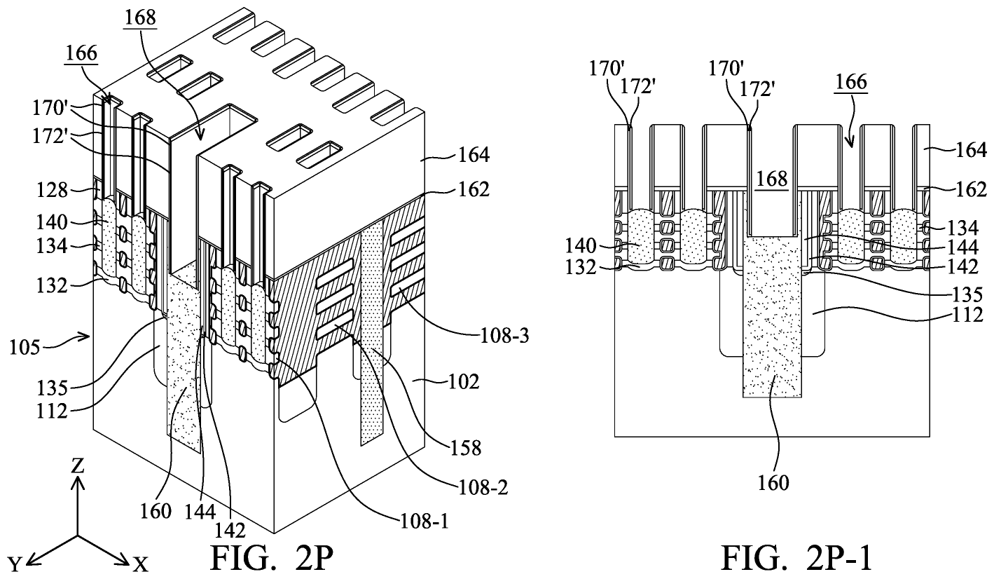

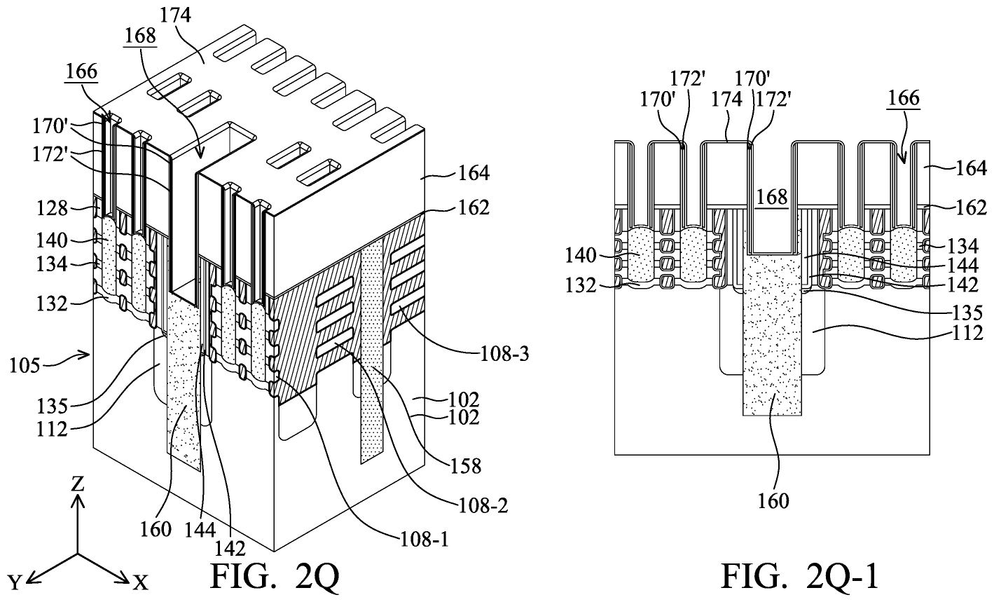

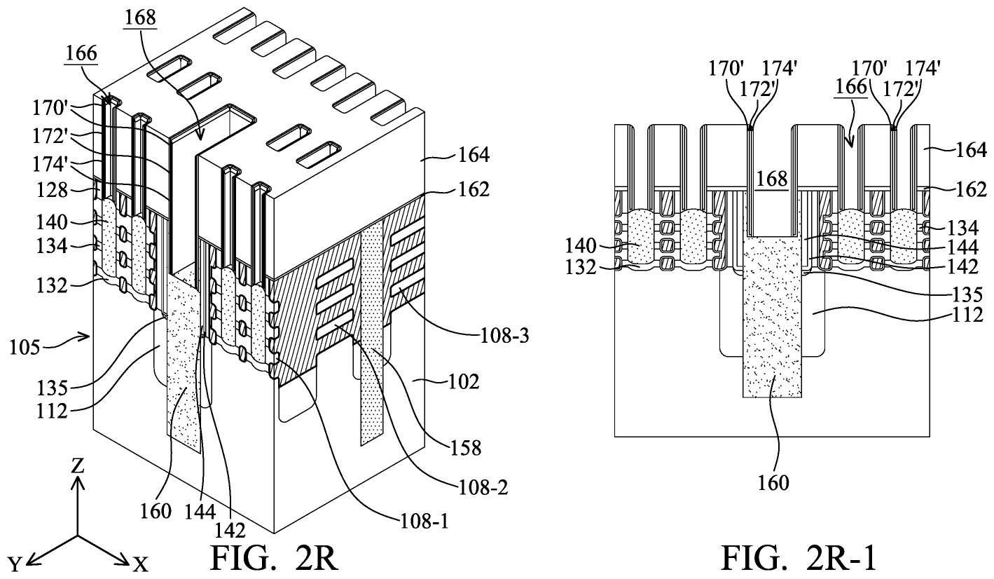

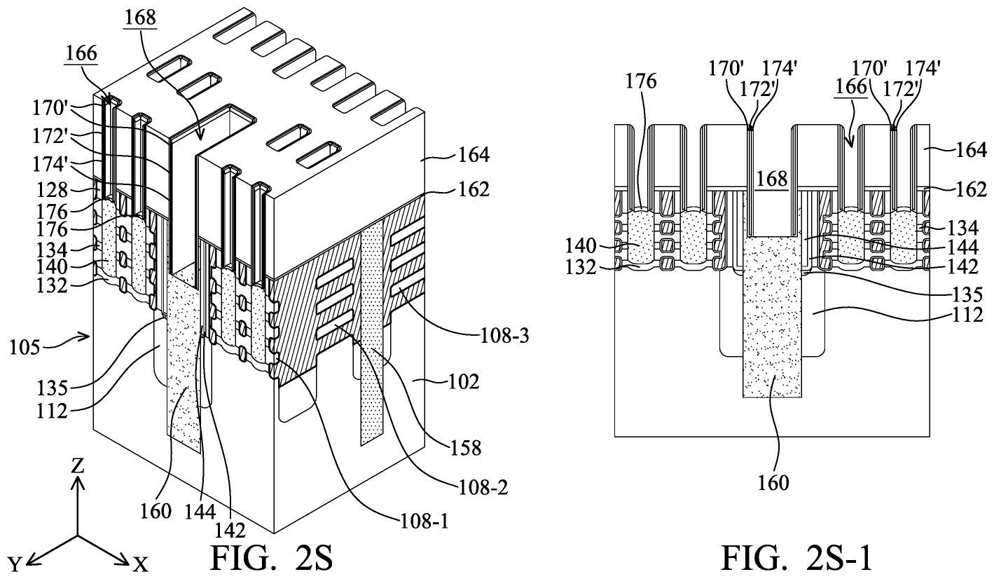

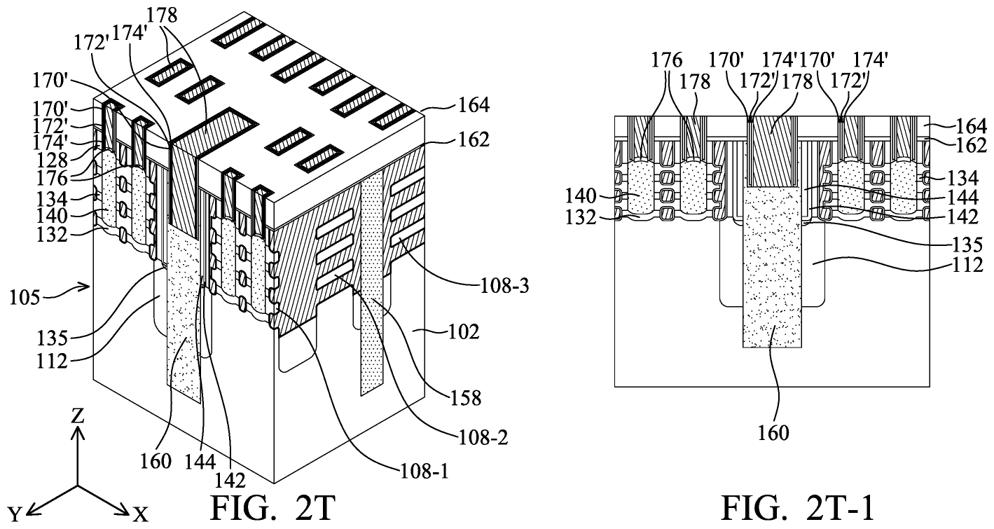

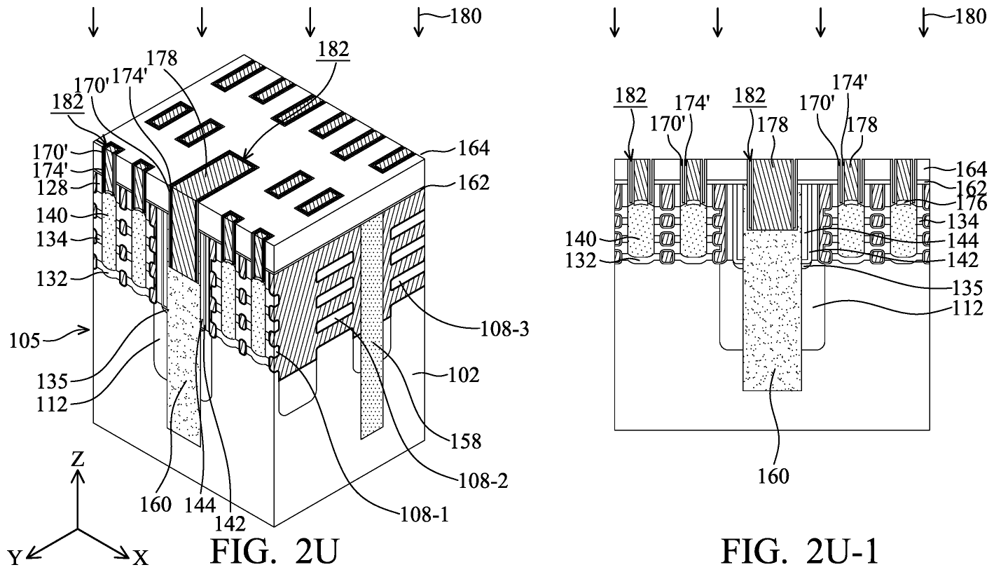

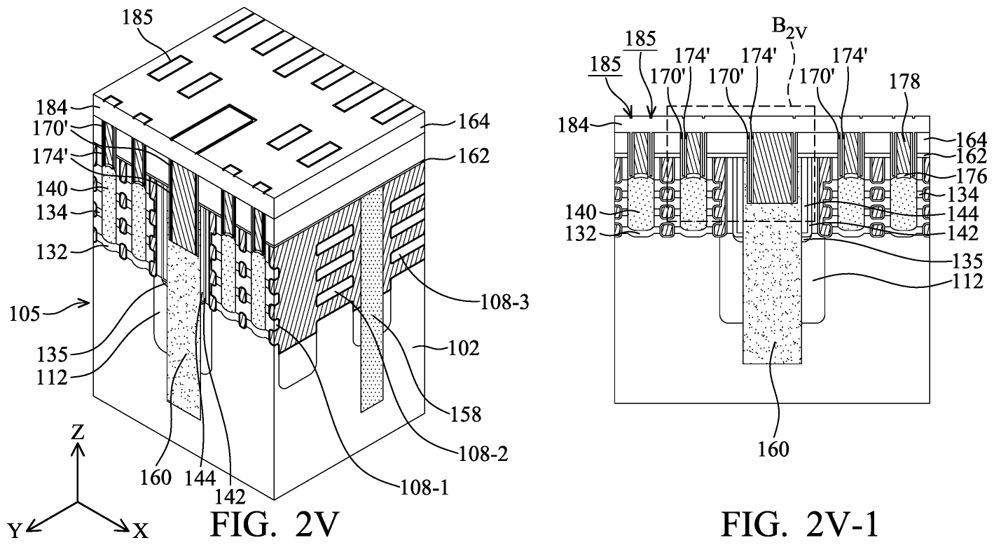

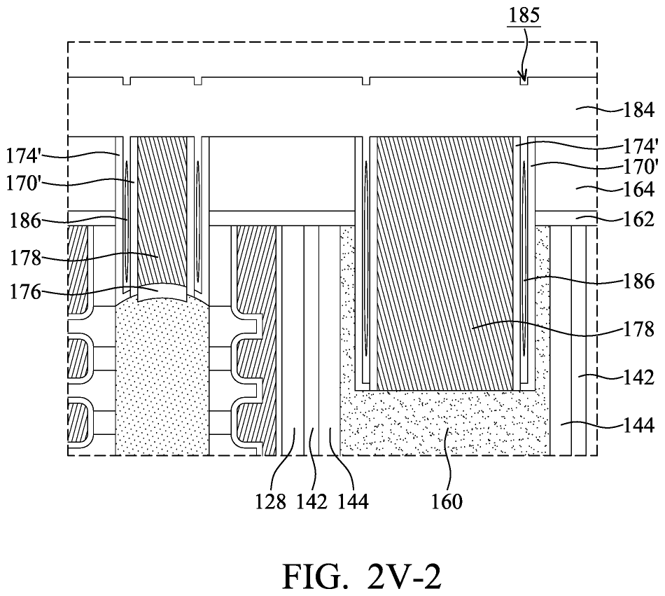

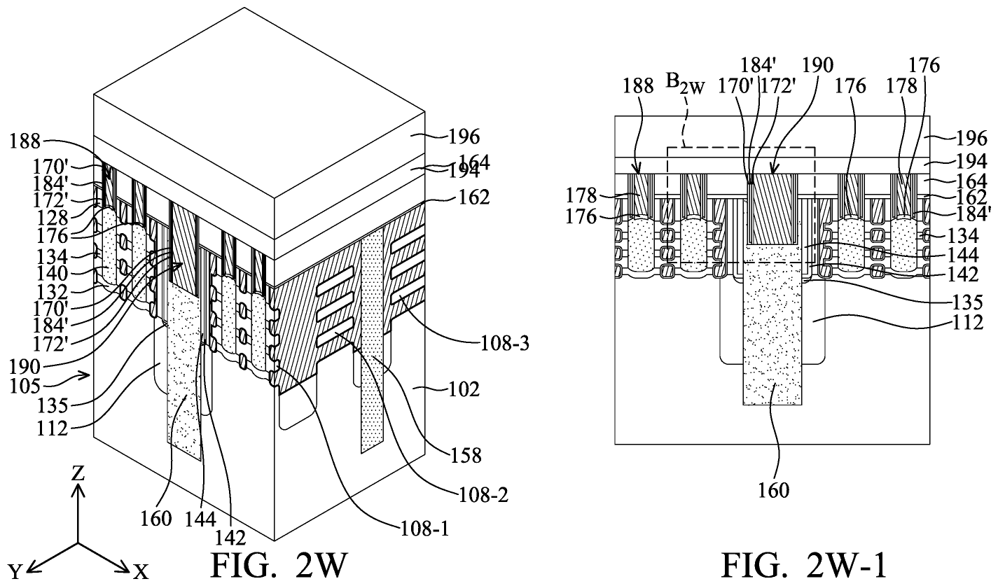

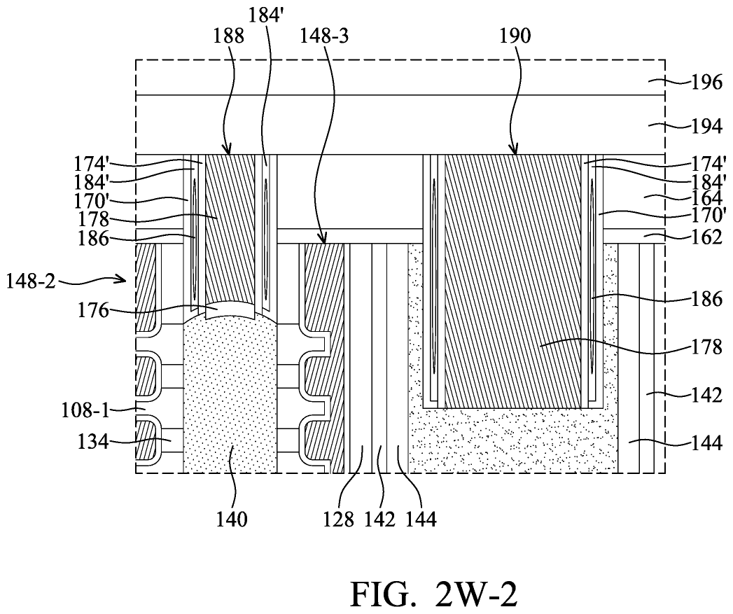

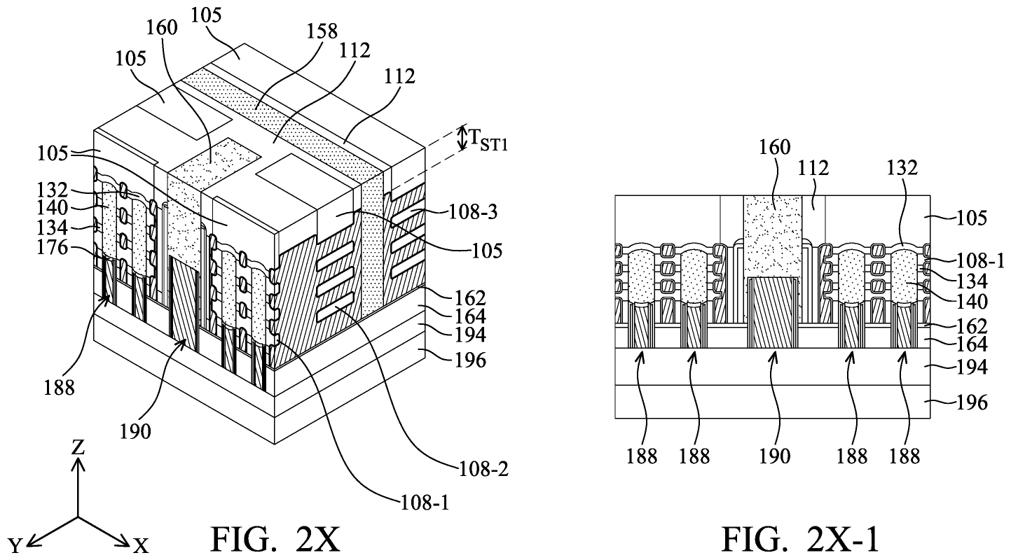

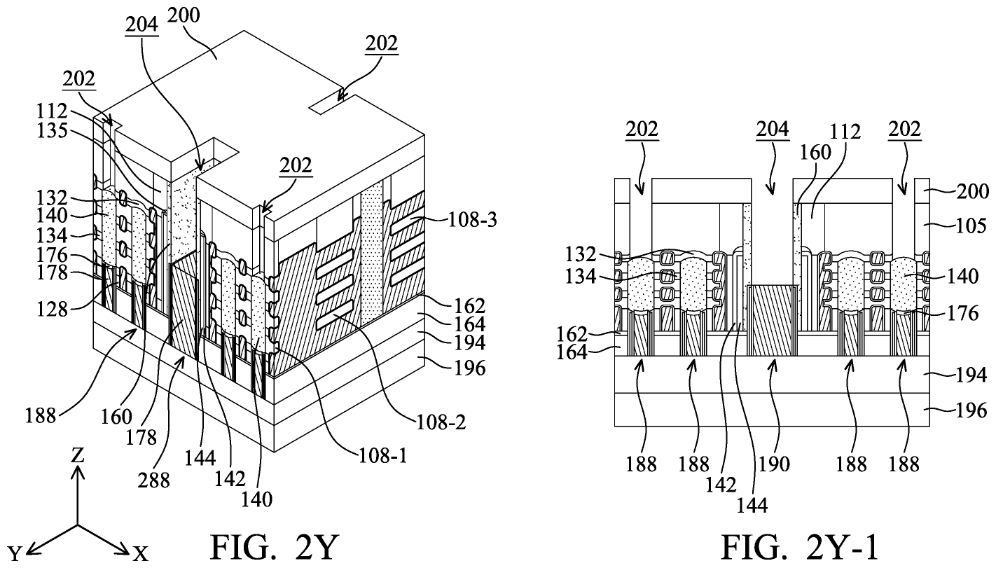

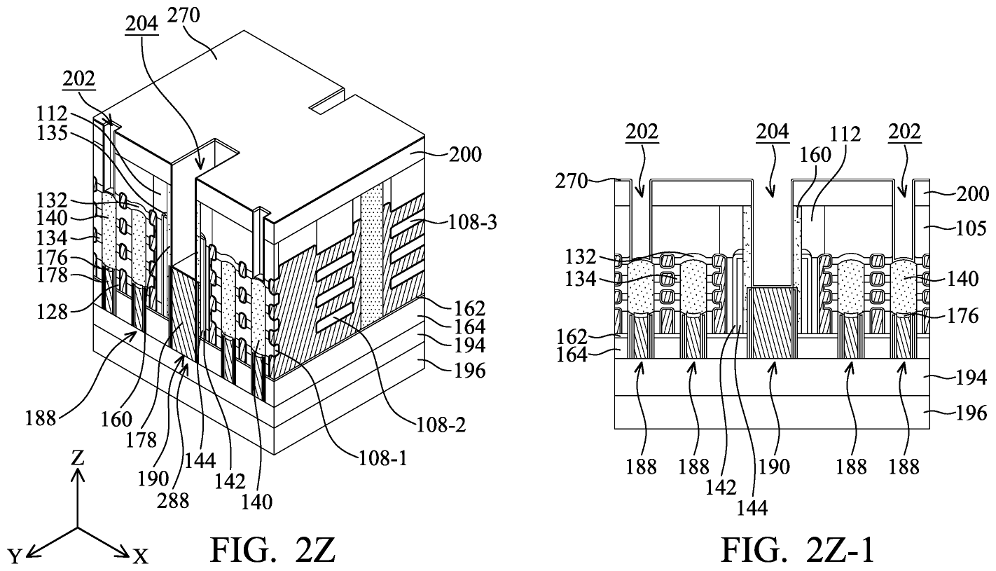

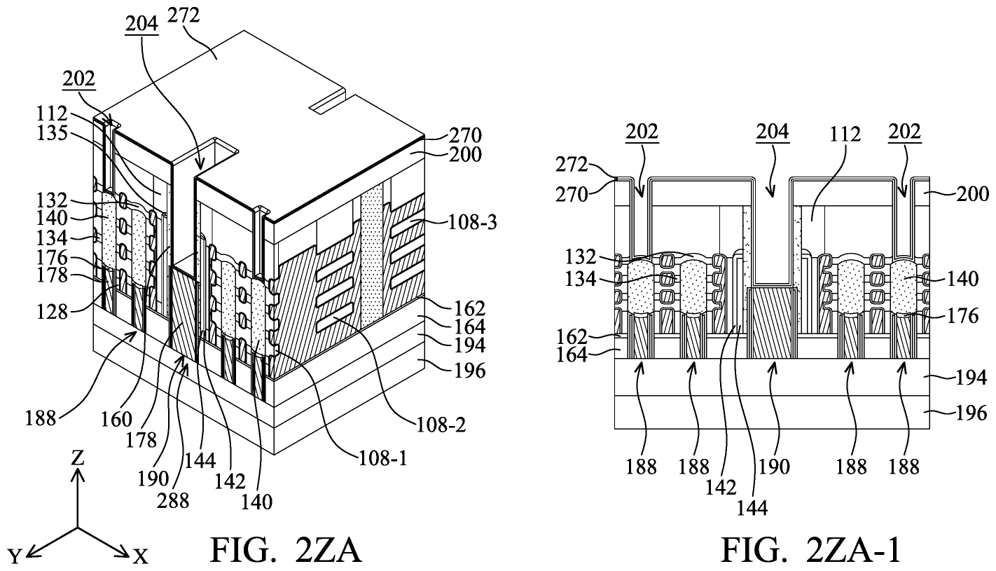

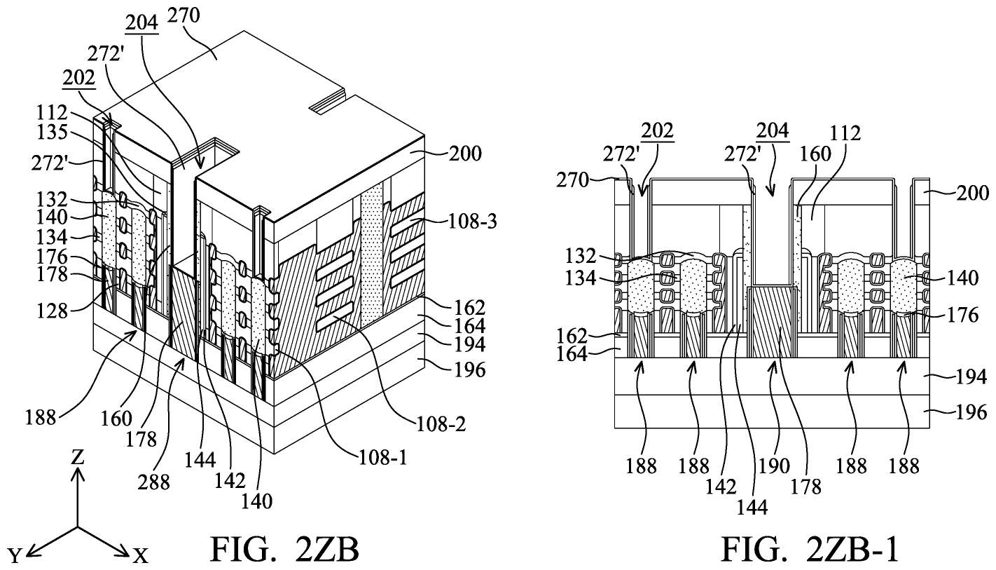

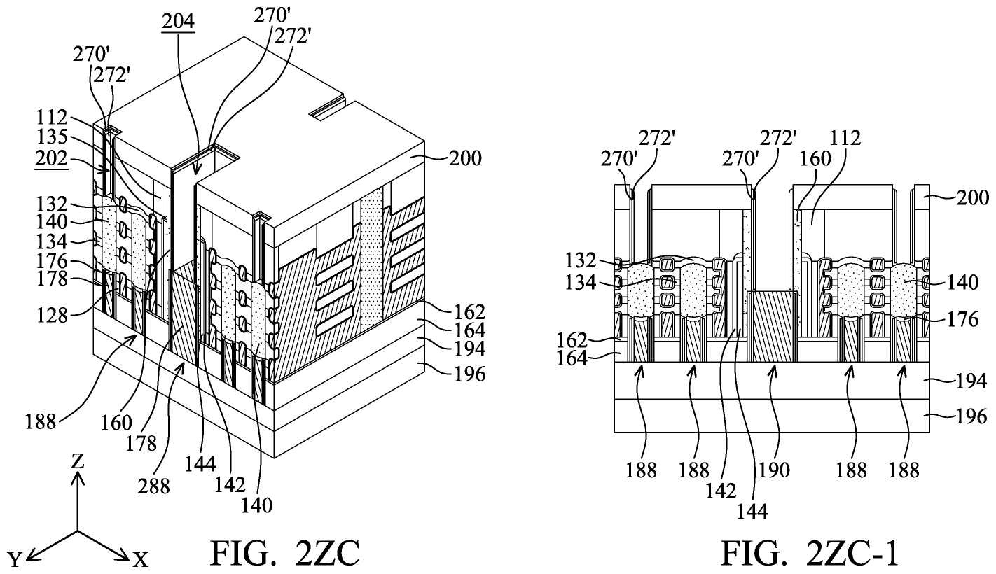

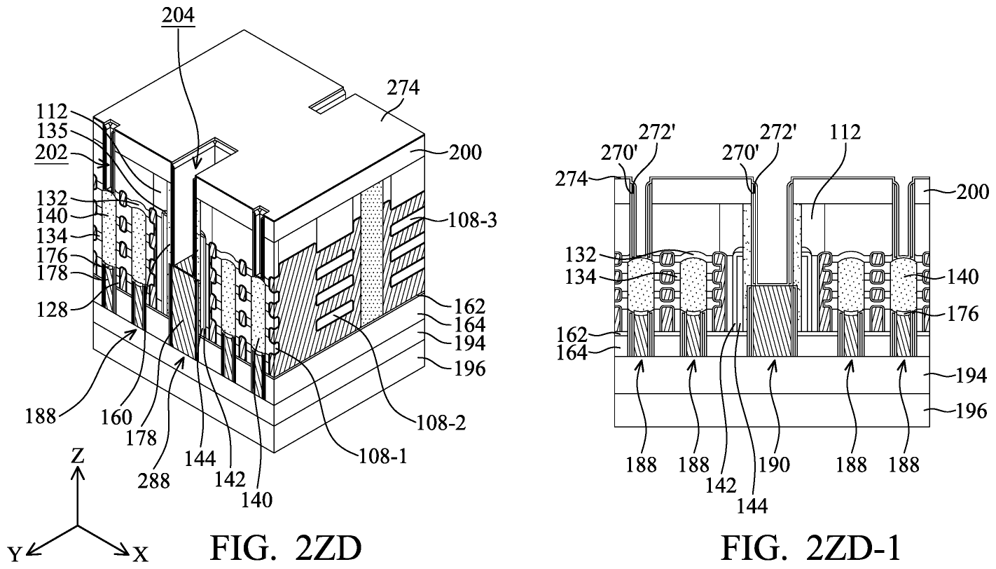

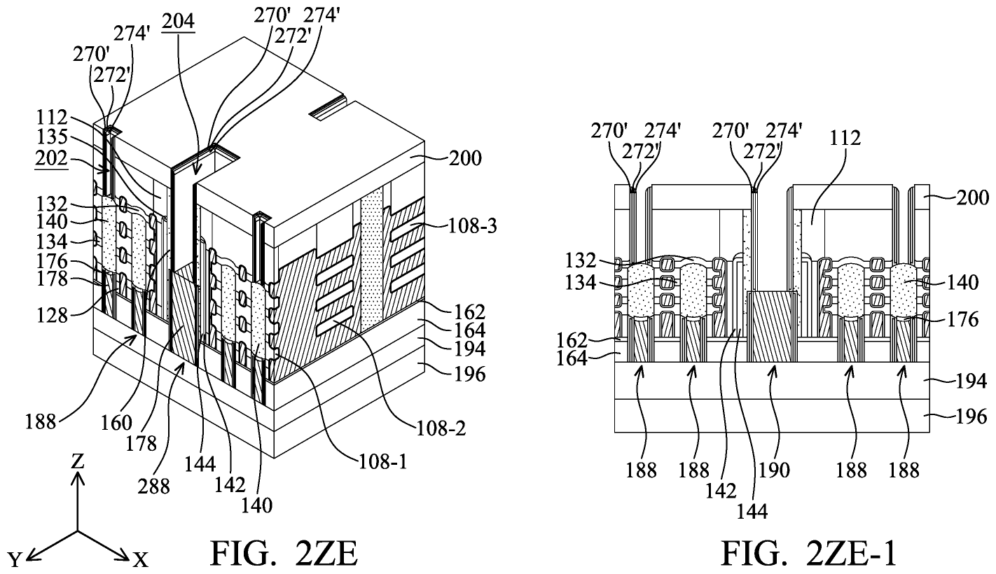

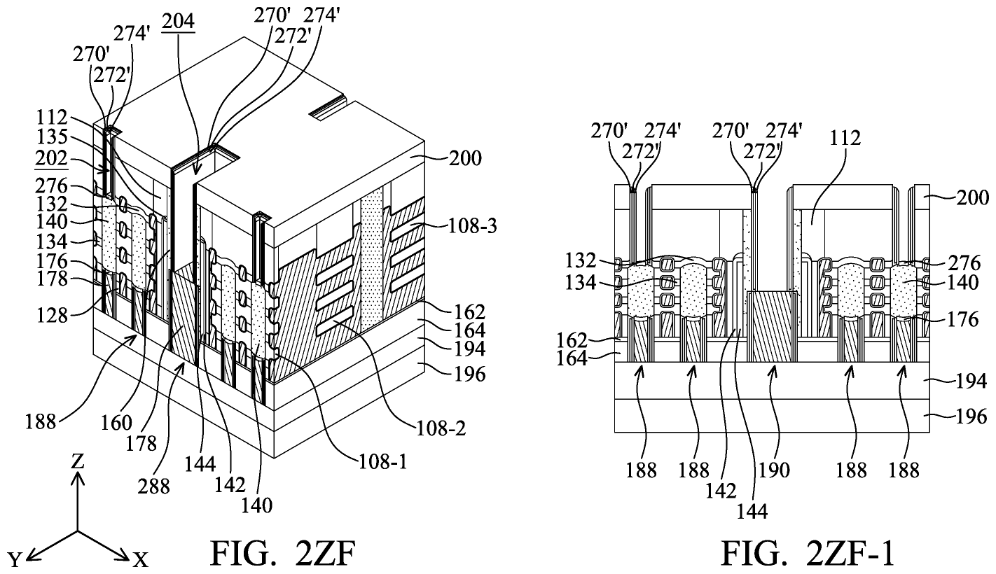

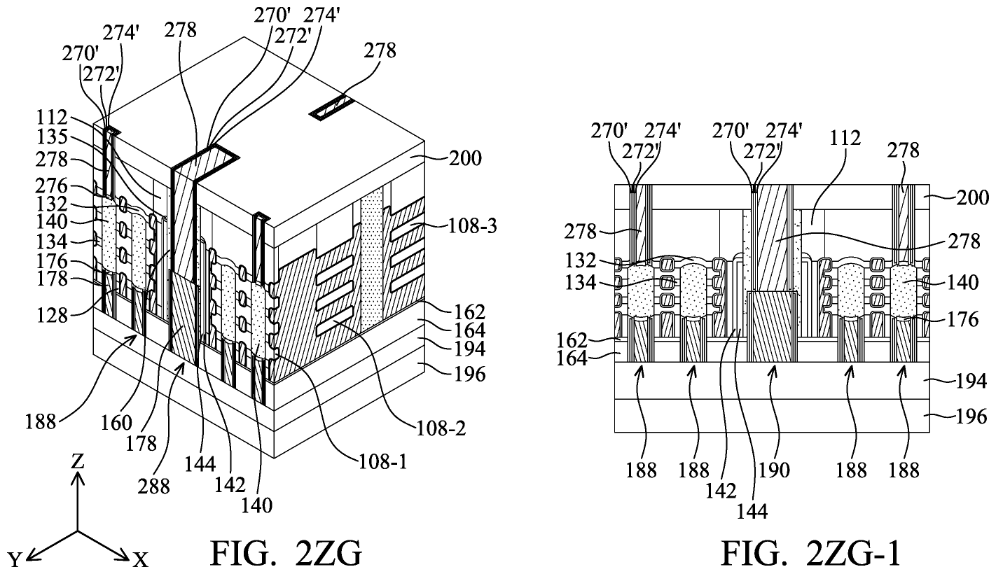

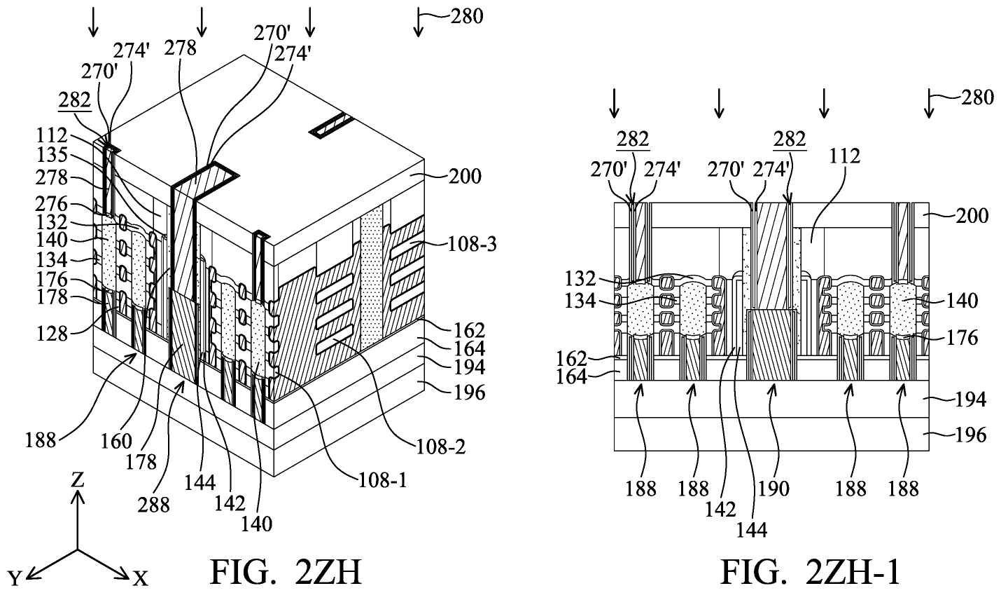

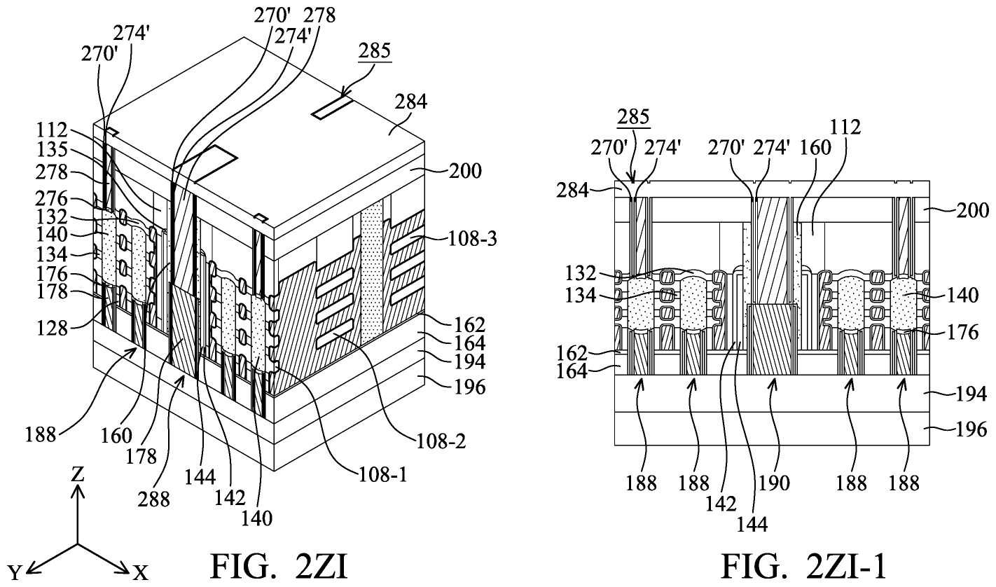

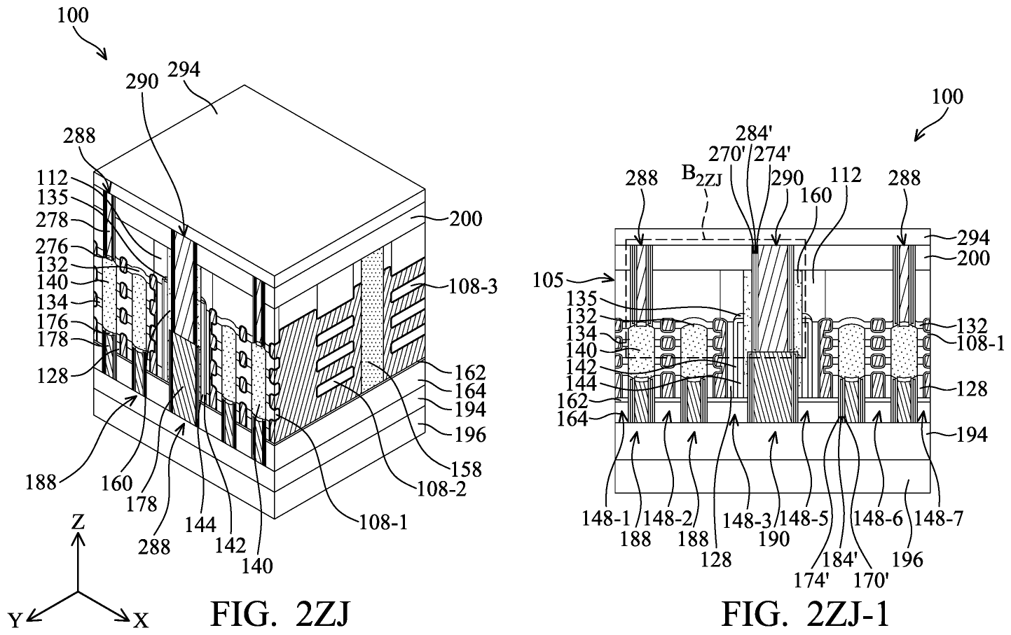

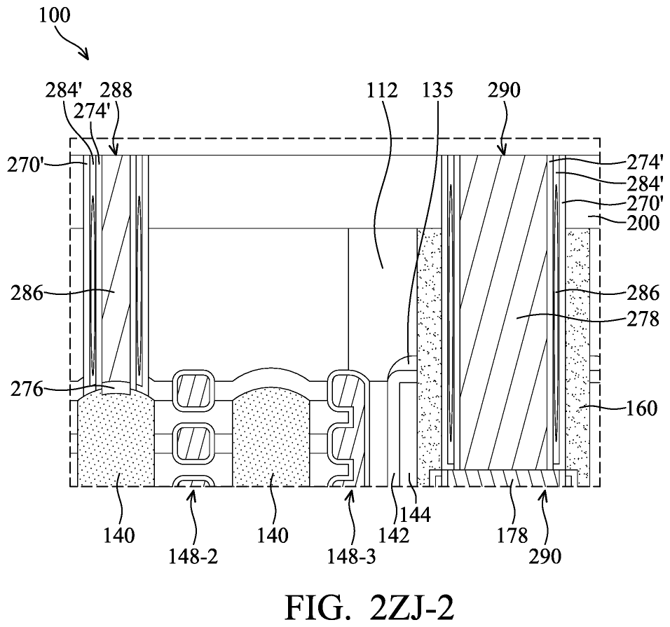

FIGS. 2A to 2ZJ illustrate diagrammatic perspective views of intermediate stages of manufacturing the semiconductor structure 100 shown in region R of FIG. 1 in accordance with some embodiments. FIGS. 2A-1 to 2ZJ-1 illustrate cross-sectional views of the intermediate stages of manufacturing the semiconductor structure 100 shown along line A-A′ of FIG. 1 in accordance with some embodiments.

First, a semiconductor material stack, including first semiconductor material layers 106 and second semiconductor material layers 108, is formed over a substrate 102, as shown in FIGS. 2A and 2A-1 in accordance with some embodiments. The substrate 102 may be a semiconductor wafer such as a silicon wafer. Alternatively or additionally, the substrate 102 may include elementary semiconductor materials, compound semiconductor materials, and/or alloy semiconductor materials. Elementary semiconductor materials may include, but are not limited to, crystal silicon, polycrystalline silicon, amorphous silicon, germanium, and/or diamond. Compound semiconductor materials may include, but are not limited to, silicon carbide, gallium arsenic, gallium phosphide, indium phosphide, indium arsenide, and/or indium antimonide. Alloy semiconductor materials may include, but are not limited to, SiGe, GaAsP, AlInAs, AlGaAs, GaInAs, GaInP, and/or GaInAsP.

In some embodiments, the first semiconductor material layers 106 and the second semiconductor material layers 108 are alternately stacked over the substrate 102 to form the semiconductor stack. In some embodiment, the first semiconductor material layers 106 and the second semiconductor material layers 108 are made of different semiconductor materials. In some embodiments, the first semiconductor material layers 106 are made of SiGe, and the second semiconductor material layers 108 are made of silicon. It should be noted that although three first semiconductor material layers 106 and three second semiconductor material layers 108 are shown in FIGS. 2A and 2A-1, the semiconductor material stack may include more or fewer first semiconductor material layers 106 and second semiconductor material layers 108. For example, the semiconductor material stack may include two to six of the first semiconductor material layers 106 and two to six of the second semiconductor material layers 108.

The first semiconductor material layers 106 and the second semiconductor material layers 108 may be formed using low-pressure chemical vapor deposition (LPCVD), epitaxial growth process, another suitable method, or a combination thereof. In some embodiments, the epitaxial growth process includes molecular beam epitaxy (MBE), metal organic chemical vapor deposition (MOCVD), or vapor phase epitaxy (VPE).

After the first semiconductor material layers 106 and the second semiconductor material layers 108 are formed as the semiconductor material stack over the substrate 102, the semiconductor stack is patterned to form fin structures 104, including fin structures 104-1, 104-2, and 104-3, extending in a first direction (i.e. X direction), as shown in FIGS. 2B and 2B-1 in accordance with some embodiments.

In some embodiments, the fin structures 104-1, 104-2, and 104-3 are protruding from the front side of the substrate 102. In some embodiments, the fin structures 104-1, 104-2, and 104-3 include base fin structures 105 and the semiconductor material stacks formed over the base fin structure 105. In some embodiments, each of the fin structures 104-1 and 104-2 includes a first portion 10 and a second portion 20 that are separated by a blank region BK. More specifically, the first portion 10 and the second portion 20 of the fin structure 104-1 are aligned with each other in the X direction but are isolated from each other in accordance with some embodiments. Similarly, the first portion 10 and the second portion 20 of the fin structure 104-2 are aligned with each other in the X direction but are isolated from each other in accordance with some embodiments.

The fin structures 104-1, 104-2, and 104-3 may be formed by performing a patterning process. In some embodiments, the patterning process includes forming mask structures over the semiconductor material stack and etching the semiconductor material stack and the underlying substrate 102 through the mask structure. In some embodiments, the mask structures are a multilayer structure including a pad oxide layer and a nitride layer formed over the pad oxide layer. The pad oxide layer may be made of silicon oxide, which may be formed by thermal oxidation or CVD, and the nitride layer may be made of silicon nitride, which may be formed by CVD, such as LPCVD or plasma-enhanced CVD (PECVD).

After the fin structures 104-1, 104-2, and 104-3 are formed, an isolation structure 112 is formed around the fin structures 104-1, 104-2, and 104-3, as shown in FIG. 1C in accordance with some embodiments. In some embodiments, the isolation structure 112 is made of silicon oxide, silicon nitride, silicon oxynitride (SiON), other applicable insulating materials, or a combination thereof. In some embodiments, an isolation liner is formed to cover the sidewalls of the base fin structures 105 of the fin structures 104-1, 104-2, and 104-3. The isolation liner may be made of a single or multiple dielectric materials. In some embodiments, the isolation liner includes an oxide layer and a nitride layer formed over the oxide layer.

The isolation liner and the isolation structure 112 may be formed by conformally forming a liner layer covering the fin structures 104-1, 104-2, and 104-3, forming an insulating material over the liner layer, and recessing the liner layer and the insulating material to form the isolation liner and the isolation structure 112. The isolation structure 112 is configured to electrically isolate active regions (e.g. the fin structures 104-1, 104-2, and 104-3) of the semiconductor structure and is also referred to as shallow trench isolation (STI) feature in accordance with some embodiments.

After the isolation structure 112 is formed, dummy gate structures 116-1, 116-2, 116-3, 116-4, 116-5, 116-6, and 116-7 are formed across the fin structures 104-1, 104-2, and 104-3 and extending along a second direction (i.e. Y direction), as shown in FIGS. 2D and 2D-1 in accordance with some embodiments. More specifically, the gate structures 116-1 and 116-2 are formed across the fin structure 104-3 and the first portions 10 of the fin structures 104-1 and 104-2, and the gate structures 116-6 and 116-7 are formed across the fin structure 104-3 and the second portions 20 of the fin structures 104-1 and 104-2 in accordance with some embodiments. The gate structure 116-4 is formed across the fin structure 104-3 and extends over the blank region BK between the first portions 10 and the second portions 20 of the fin structures 104-1 and 104-2 in accordance with some embodiments. The gate structure 116-3 is formed across the fin structure 104-3 and over the edge portions of the first portions 10 of the fin structures 104-1 and 104-2, and the gate structure 116-5 is formed across the fin structure 104-3 and over the edge portions of the second portions 20 of the fin structures 104-1 and 104-2 in accordance with some embodiments.

The dummy gate structures 116-1 to 116-7 may be used to define the source/drain regions and the channel regions of the resulting semiconductor structure 100. In some embodiments, each of the dummy gate structures 116-1 to 116-7 includes a dummy gate dielectric layer 118 and a dummy gate electrode layer 120. In some embodiments, the dummy gate dielectric layer 118 is made of one or more dielectric materials, such as silicon oxide, silicon nitride, silicon oxynitride (SiON), HfO₂, HfZrO, HfSiO, HfTiO, HfAlO, or a combination thereof. In some embodiments, the dummy gate dielectric layer 118 is formed using thermal oxidation, CVD, ALD, physical vapor deposition (PVD), another suitable method, or a combination thereof.

In some embodiments, the dummy gate electrode layer 120 is made of conductive material includes polycrystalline-silicon (poly-Si), poly-crystalline silicon-germanium (poly-SiGe), or a combination thereof. In some embodiments, the dummy gate electrode layer 120 is formed using CVD, PVD, or a combination thereof.

The formation of the dummy gate structures 116-1 to 116-7 may include conformally forming a dielectric material as the dummy gate dielectric layers 118. Afterwards, a conductive material may be formed over the dielectric material as the dummy gate electrode layers 120, and a hard mask layer 122 may be formed over the conductive material. Next, the dielectric material and the conductive material may be patterned through the hard mask layer 122 to form the dummy gate structures 116-1 to 116-7. In some embodiments, the hard mask layer 122 includes multiple layers, such as an oxide layer 124 and a nitride layer 126. In some embodiments, the oxide layer 124 is silicon oxide, and the nitride layer 126 is silicon nitride.

After the dummy gate structures 116-1 to 116-7 are formed, a gate spacer layer is conformally formed to cover the gate structures 116-1 to 116-7 and the fin structures 104-1 to 104-3, and an etching process is performed to form gate spacers 128 and source/drain recesses 130, as shown in FIGS. 2E and 2E-1 in accordance with some embodiments.

More specifically, the gate spacer layer is etched to form the gate spacers 128 on opposite sidewalls of the dummy gate structures 116-1 to 116-7 in accordance with some embodiments. The gate spacers 128 may be configured to separate source/drain structures (formed afterwards) from the dummy gate structure 116-1 to 116-7. In some embodiments, the gate spacers 128 are made of a dielectric material, such as silicon oxide (SiO₂), silicon nitride (SiN), silicon carbide (SiC), silicon oxynitride (SiON), silicon carbon nitride (SiCN), silicon oxide carbonitride (SiOCN), and/or a combination thereof.

The portions of the fin structures 104-1 to 104-3 not covered by the dummy gate structures 116-1 to 116-7 and the gate spacers 128 are etched to form the source/drain recesses 130 by the etching process in accordance with some embodiments. The etching process may be an anisotropic etching process, such as dry plasma etching, and the dummy gate structure 116-1 to 116-6 and the gate spacers 128 may be used as etching masks during the etching process. In some embodiments, the isolation structure 112 is also slightly etched during the etching process, such that recessed portions 115 are formed in the isolation structure 112.

After the source/drain recesses 130 are formed, the first semiconductor material layers 106 exposed by the source/drain recesses 130 are laterally recessed to form notches, and bottom isolation layers 132 and inner spacers 134 are formed, as shown in FIGS. 2F and 2F-1 in accordance with some embodiments. The bottom isolation layers 132 are configured to improve the isolation between the source/drain structure formed thereon and the substrate below. The inner spacers 134 are configured to separate the source/drain structures and the gate structures formed in subsequent manufacturing processes.

In some embodiments, an etching process is performed to laterally recess the first semiconductor material layers 106 of the fin structure 104-1, 104-2, and 104-3 from the source/drain recesses 130. In some embodiments, during the etching process, the first semiconductor material layers 106 have a greater etching rate (e.g. etching amount) than the second semiconductor material layers 108, thereby forming the notches between the adjacent second semiconductor material layers 108. In some embodiments, the etching process is dry chemical etching, remote plasma etching, wet chemical etching, another suitable technique, and/or a combination thereof.

After the notches are formed, a dielectric layer is formed in the notches and in the source/drain recesses 130, and an etching process is performed onto the dielectric layer to form the inner spacers 134 in the notches and to form the bottom isolation layers 132 in the bottom portions of the source/drain recesses 130 in accordance with some embodiments. In addition, after the etching process is performed, some portions of the dielectric layer may still remain on the isolation structure 112 and on top portions of the gate spacers 128 and the hard mask layers 122 to form isolating capping layers 135.

In some other embodiments, the inner spacers 134 are formed in the notches between the second semiconductor material layers 108 first, and the bottom isolation layers 132 and the isolating capping layers 135 are formed afterwards. For example, after the inner spacers 134 are formed, an additional dielectric layer may be conformally formed to cover the inner spacers 134 and an etching process may be performed to form the bottom isolation layers 132 and the isolating capping layers 135. In some other embodiments, a bottom-up deposition process is performed to form the bottom isolation layers 132 and the isolating capping layers 135.

In some embodiments, the inner spacers 134, the bottom isolation layers 132, and the isolating capping layers 135 are made of a dielectric material, such as silicon oxide (SiO₂), silicon nitride (SiN), silicon carbide (SiC), silicon oxynitride (SiON), silicon carbon nitride (SiCN), silicon oxide carbonitride (SiOCN), or a combination thereof.

Afterwards, source/drain structures 140 are formed in the source/drain recesses 130, as shown in FIGS. 2H and 2H-1 in accordance with some embodiments. In some embodiments, the source/drain structures 140 are formed using an epitaxial growth process, such as MBE, MOCVD, VPE, other applicable epitaxial growth process, or a combination thereof. In some embodiments, the source/drain structures 140 are made of any applicable material, such as Ge, Si, GaAs, AlGaAs, SiGe, GaAsP, SiP, SiC, SiCP, or a combination thereof. In some embodiments, the source/drain structures 140 are in-situ doped during the epitaxial growth process. For example, the source/drain structures 140 may be the epitaxially grown SiGe doped with boron (B). For example, the source/drain structures 140 may be the epitaxially grown Si doped with carbon to form silicon:carbon (Si:C) source/drain features, phosphorous to form silicon:phosphor (Si:P) source/drain features, or both carbon and phosphorous to form silicon carbon phosphor (SiCP) source/drain features. In some embodiments, the source/drain structures 140 are doped in one or more implantation processes after the epitaxial growth process. The source/drain structures (or region(s)) may refer to a source or a drain, individually or collectively dependent upon the context

After the source/drain structures 140 are formed, a contact etch stop layer (CESL) 142 is conformally formed to cover the source/drain structures 140 and dummy gate structures 116-1 to 116-7, and an interlayer dielectric (ILD) layer 144 is formed over the contact etch stop layers 142, as shown in FIGS. 2H and 2H-1 in accordance with some embodiments.

In some embodiments, the contact etch stop layer 142 is made of a dielectric material, such as silicon nitride, silicon oxide, silicon oxynitride, another suitable dielectric material, or a combination thereof. The dielectric material for the contact etch stop layers 142 may be conformally deposited over the semiconductor structure by performing CVD, ALD, other application methods, or a combination thereof.

The interlayer dielectric layer 144 may include multilayers made of multiple dielectric materials, such as silicon oxide, silicon nitride, silicon oxynitride, phosphosilicate glass (PSG), borophosphosilicate glass (BPSG), or other applicable low-k dielectric materials. The interlayer dielectric layer 144 may be formed by chemical vapor deposition (CVD), physical vapor deposition, (PVD), atomic layer deposition (ALD), or other applicable processes.

After the contact etch stop layer 142 and the interlayer dielectric layer 144 are deposited, a planarization process such as CMP or an etch-back process is performed until the gate electrode layers 120 of the dummy gate structures 116-1 to 116-7 are exposed in accordance with some embodiments. The isolating capping layers 135 formed over the gate spacers 128 and the hard mask layers 122 are also removed during the planarization process in accordance with some embodiments.

Next, the dummy gate structures 116-1 to 116-7 and the first semiconductor material layers 106 of the fin structures 104-1, 104-2, and 104-3 are removed to form gate trenches 146, as shown in FIGS. 2H and 2H-1 in accordance with some embodiments. More specifically, the dummy gate structures 116-1 to 116-7 and the first semiconductor material layers 106 of the fin structures 104-1, 104-2, and 104-3 are removed to form channel members 108-1, 108-2, and 108-3 with the second semiconductor material layers 108 of the fin structures 104-1, 104-2, and 104-3 respectively, in accordance with some embodiments. In addition, the channel members 108-1 and 108-2 also include first portions and second portions spaced apart from each other, similar to the fin structures 104-1 and 104-2.

The removal process may include one or more etching processes. For example, when the dummy gate electrode layers 120 are polysilicon, a wet etchant such as a tetramethylammonium hydroxide (TMAH) solution may be used to selectively remove the dummy gate electrode layers 120. Afterwards, the dummy gate dielectric layers 118 may be removed using a plasma dry etching, a dry chemical etching, and/or a wet etching. The first semiconductor material layers 106 may then be removed by performing a selective wet etching process, such as APM (e.g., ammonia hydroxide-hydrogen peroxide-water mixture) etching process. For example, the wet etching process uses etchants such as ammonium hydroxide (NH₄OH), TMAH, ethylenediamine pyrocatechol (EDP), and/or potassium hydroxide (KOH) solutions.

In some embodiments, a trimming process is performed to trim (e.g. slightly etched) the second semiconductor material layers 108 and the base fin structures 105. Accordingly, the resulting channel members 108-1, 108-2, and 108-3 are narrower at the channel regions than those under the gate spacers 128 in accordance with some embodiments. In addition, the isolation structure 112 under the dummy gate structures 116-1 to 116-7 is also partially removed during the trimming process, and therefore the isolation structure 112 have recessed portions exposed by the gate trenches 146, as shown in FIG. 2H-1 in accordance with some embodiments.

Next, gate structures 148, including gate structures 148-1, 148-2, 148-3, 148-4, 148-5, 148-6, and 148-7, are formed in the gate trenches 146, as shown in FIGS. 2I and 2I-1 in accordance with some embodiments. More specifically, the gate structures 148-1 and 148-2 wraps around the first portions of the channel members 108-1 and 108-2 and the channel members 108-3 in accordance with some embodiments. The gate structures 148-6 and 148-7 wraps around the second portions of the channel members 108-1 and 108-2 and the channel members 108-3 in accordance with some embodiments. The gate structure 148-4 wraps around the channel members 108-3 and is spaced apart from the channel members 108-1 and 108-2 in the X direction in accordance with some embodiments.

In addition, the gate structure 148-3 not only wraps around the first portions of the channel members 108-1 and 108-2 and the channel members 108-3 but also covers the edges portions of the first portions of the channel members 108-1 and 108-2 in accordance with some embodiments. That is, an extending portion of the gate structure 148-3 is sandwiched between the first portions of the channel members 108-1 and 108-2 and the gate spacers 128 in the X direction. Similarly, the gate structure 148-5 not only wraps around the second portions of the channel members 108-1 and 108-2 and the channel members 108-3 but also covers the edges portions of the second portions of the channel members 108-1 and 108-2 in accordance with some embodiments. That is, an extending portion of the gate structure 148-5 is sandwiched between the second portions of the channel members 108-1 and 108-2 and the gate spacers 128 in the X direction.

In some embodiments, each of the gate structures 148 includes a gate dielectric layer 150 and a gate electrode layer 152. In some embodiments, an interfacial layer is formed before the gate dielectric layer 150 is formed, although not shown in FIGS. 2I and 2I-1. In some embodiments, the interfacial layer is an oxide layer formed around the channel members 108-1, 108-2, and 108-3 and on the exposed portions of the base fin structures 105. In some embodiments, the interfacial layer is formed by performing a thermal process.

In some embodiments, the gate dielectric layer 150 is formed over the interfacial layer, so that the channel members 108-1, 108-2, and 108-3 are surrounded (e.g. wrapped) by the gate dielectric layer 150. In addition, the gate dielectric layer 150 also covers the sidewalls of the gate spacers 128, the inner spacers 134, and the channel members 108-1, 108-2, and 108-3 in accordance with some embodiments. In some embodiments, the gate dielectric layers 150 are made of one or more layers of dielectric materials, such as HfO₂, HfSiO, HfSiON, HfTaO, HfTiO, HfZrO, zirconium oxide, aluminum oxide, titanium oxide, hafnium dioxide-alumina (HfO₂—Al₂O₃) alloy, other applicable high-k dielectric materials, or a combination thereof. In some embodiments, the gate dielectric layers 150 are formed using CVD, ALD, other applicable methods, or a combination thereof.

In some embodiments, the gate electrode layers 152 are formed on the gate dielectric layers 150. In some embodiments, the gate electrode layers 152 are made of one or more layers of conductive material, such as aluminum, copper, titanium, tantalum, tungsten, cobalt, molybdenum, tantalum nitride, nickel silicide, cobalt silicide, TiN, WN, TiAl, TiAlN, TaCN, TaC, TaSiN, metal alloys, another suitable material, or a combination thereof. In some embodiments, the gate electrode layers 152 are formed using CVD, ALD, electroplating, another applicable method, or a combination thereof. Other conductive layers, such as work function metal layers, may also be formed in the gate structures 148, although they are not shown in the figures. After the gate dielectric layers 150 and the gate electrode layers 152 are formed, a planarization process such as CMP or an etch-back process may be performed.

Next, isolation structures may be formed through the gate structures 148. More specifically, a gate isolation trench 154 and a wide isolation trench 156 are formed through the gate structures 148 and through the interlayer dielectric layer 144, the contact etch stop layer 142, the isolating capping layers 135, and the isolation structure 112, as shown in FIGS. 2J and 2J-1 in accordance with some embodiments. In some embodiments, the gate isolation trench 154 and the wide isolation trench 156 further extends into the substrate 102. In some embodiments, the gate isolation trench 154 and the wide isolation trench 156 extend through the isolation structure 112 and into the substrate 102 to a depth D in a range from about 10 nm to about 50 nm.

In some embodiments, the gate isolation trench 154 is formed through the gate structures 148-1 to 148-7 to cut the gate structures 148 into divided portions in the Y direction. In some embodiments, the gate isolation trench 154 is located between the channel members 108-2 and 108-3 and has a longitudinal axis in the X direction.

Meanwhile, the wide isolation trench 156 is formed through the gate structure 148-4 in the blank region BK between the first portions and the second portions of the channel members 108-1 and 108-2 and is sandwiched between the first portions and the second portions of the channel members 108-1 and 108-2 in the X direction, in accordance with some embodiments. In some embodiments, the wide isolation trench 156 has a width of about 20 nm to about 60 nm in the X direction. In some embodiments, the wide isolation trench 156 has a width of about 35 nm to about 130 nm in the Y direction. In some embodiments, the wide isolation trench 156 is spaced a distance of S apart from the neighboring gate structures 148-3 and 148-5 in the X direction, in accordance with some embodiments. In some embodiments, the distance S is greater than about 15 nm, so that there will be enough space between the neighboring gate structures 148-3 and 148-5 and the through via structure formed afterwards. In some other embodiments, the wide isolation trench 156 cuts more than one gate structure (not shown) in the Y direction.

After the gate isolation trench 154 and the wide isolation trench 156 are formed, a gate isolation structure 158 and a wide isolation structure 160 are formed in the gate isolation trench 154 and the wide isolation trench 156 respectively, as shown in FIGS. 2K and 2K-1 in accordance with some embodiments. In some embodiments, a dielectric material is deposited to fill the gate isolation trench 154 and the wide isolation trench 156 and a polishing process is performed to remove the excess dielectric layer. In some embodiments, the dielectric material includes SiO, SiOC, AlO, AlON, ZrO, HfO, TiO, ZrAlO, ZnO, SiOCN, SiOCN, SiCN, or the like. The gate isolation structure 158 and the wide isolation structure 160 may be formed by performing chemical vapor deposition (CVD), physical vapor deposition, (PVD), atomic layer deposition (ALD), or other applicable processes. In some embodiments, the gate isolation structure 158 and the wide isolation structure 160 have substantially the same thickness.

Next, source/drain contacts and through via structure may be formed. More specifically, an etch stop layer 162 and a dielectric layer 164 are formed over the gate structures 148, the interlayer dielectric layer 144, the gate isolation structure 158, and the wide isolation structure 160, as shown in FIGS. 2L and 2L-1 in accordance with some embodiments.

In some embodiments, the etch stop layer 162 is made of a dielectric material, such as silicon nitride, silicon oxide, silicon oxynitride, another suitable dielectric material, or a combination thereof. The dielectric material for the etch stop layers 162 may be conformally deposited over the semiconductor structure by performing CVD, ALD, other application methods, or a combination thereof.

The dielectric layer 164 may include multilayers made of multiple dielectric materials, such as SiO, HfSi, SiOC, AlO, ZrSi, AlON, ZrO, HfO, TiO, ZrAlO, ZnO, TaO, LaO, YO, TaCN, SiN, SiOCN, Si, SiOCN, ZrN, SiCN, or other applicable low-k dielectric materials. The dielectric layer 164 may be formed by chemical vapor deposition (CVD), physical vapor deposition, (PVD), atomic layer deposition (ALD), or other applicable processes.

Afterwards, source/drain contact trenches 166 and a though via trench 168 are formed through the etch stop layer 162 and the dielectric layer 164, as shown in FIGS. 2L and 2L-1 in accordance with some embodiments. In addition, the source/drain contact trenches 166 are further formed through the contact etch stop layer 142 and the interlayer dielectric layer 144 to expose the top surface of the source/drain structures 140 in accordance with some embodiments. In some embodiments, the source/drain structures 140 are also partially removed (e.g. etched), such that the source/drain contact trenches 166 further extends into the source/drain structures 140.

In some embodiments, the though via trench 168 is formed through the etch stop layer 162 and the dielectric layer 164 and extends into the wide isolation structure 160. In some embodiments, the though via trench 168 has a first width in the X direction and a second width in the Y direction, and the first width is smaller than the width of the wide isolation structure 160 in the X direction and the second width is smaller than the width of the wide isolation structure 160 in the Y direction. In some other embodiments, the first width and the second width of the through via trench 168 are substantially equal to the widths of the wide isolation structure along X and Y direction respectively.

The source/drain contact trenches 166 and the though via trench 168 may be formed by forming a mask structure with openings and transferring the pattern of the mask structure to the dielectric layer 164 by performing an etching process. In some embodiments, the etching process is dry chemical etching, remote plasma etching, wet chemical etching, another suitable technique, and/or a combination thereof.

After the source/drain contact trenches 166 and the though via trench 168 are formed, a liner layer 170 is conformally formed, as shown in FIGS. 2M and 2M-1 in accordance with some embodiments. More specifically, the liner layer 170 is formed over the bottom surfaces and sidewalls of the source/drain contact trenches 166 and the though via trench 168 in accordance with some embodiments. That is, the liner layer 170 covers the sidewall surfaces of the etch stop layer 162, the dielectric layer 164, the gate spacers 128, the contact etch stop layer 142, and the interlayer dielectric layer 144 and the top surfaces of the source/drain structures 140 exposed by the source/drain contact trenches 166 in accordance with some embodiments. In addition, the liner layer 170 also cover the etch stop layer 162, the dielectric layer 164, and the wide isolation structure 160 exposed by the through via trench 168 in accordance with some embodiments. Furthermore, the top surface of the dielectric layer 164 is also covered by the liner layer 170 in accordance with some embodiments.

In some embodiments, the liner layer 170 is made of SiO, HfSi, SiOC, AlO, ZrSi, AlON, ZrO, HfO, TiO, ZrAlO, ZnO, TaO, LaO, YO, TaCN, SiN, SiOCN, Si, SiOCN, ZrN, SiCN, or the like. In some embodiments, the liner layer 170 formed over the vertical sidewalls (e.g. the sidewalls of the gate spacers 128 and the sidewalls of the wide isolation structure 160) has a thickness in the X direction in a range from about 1 nm to about 5 nm. In some embodiments, the liner layer 170 formed over the lateral surfaces (e.g. the top surface of the source/drain structures 140 and the top surface of the wide isolation structure 160 exposed by the through via trench 168) has a thickness in the Z direction in a range from about 0.8 to about 4.5 nm. The liner layer 170 may be formed by performing chemical vapor deposition (CVD), physical vapor deposition, (PVD), atomic layer deposition (ALD), or other applicable processes.

After the liner layer 170 is formed, a dummy spacer layer 172 is formed over the liner layer 170, as shown in FIGS. 2N and 2N-1 in accordance with some embodiments. In some embodiments, the dummy spacer layer 172 is made of Si, SiGe, SiGeB, SiB, or the like. In some embodiments, the dummy spacer layer 172 has a thickness in the X direction in a range from about 1 nm to about 5 nm.

After the dummy spacer layer 172 is formed, an etching process is performed to remove the dummy spacer layer 172 formed over the lateral surfaces, so that dummy spacers 172′ are formed on the sidewalls of the source/drain contact trenches 166 and the sidewalls of the though via trench 168, as shown in FIGS. 2O and 2O-1 in accordance with some embodiments. In some embodiments, the etching process includes dry chemical etching, remote plasma etching, wet etching, other applicable technique, and/or a combination thereof.

After the dummy spacers 172′ are formed, another etching process is performed to remove the portions of the liner layer 170 formed over the lateral surfaces, so that liners 170′ are formed on the sidewalls of the source/drain contact trenches 166 and the sidewalls of the though via trench 168, as shown in FIGS. 2P and 2P-1 in accordance with some embodiments. In some embodiments, the etching process includes dry chemical etching, remote plasma etching, wet etching, other applicable technique, and/or a combination thereof. As shown in FIG. 2P-1, the liner 170′ has an L shape in the cross-sectional view in the X direction. In some embodiments, the liners 170′ and the dummy spacers 172′ have rounded top corners.

Afterwards, a liner layer 174 is conformally formed to cover the liners 170′, the dummy spacers 172′, the top surfaces of the dielectric layer 164, the source/drain structures 140, and the wide isolation structure 160, as shown in FIGS. 2Q and 2Q-1 in accordance with some embodiments. In some embodiments, the liner layer 174 is made of SiO, HfSi, SiOC, AlO, ZrSi, AlON, ZrO, HfO, TiO, ZrAlO, ZnO, TaO, LaO, YO, TaCN, SiN, SiOCN, Si, SiOCN, ZrN, SiCN, or the like. In some embodiments, the liner layer 174 has a thickness in the X direction in a range from about 1 nm to about 5 nm. The liner layer 174 may be formed by performing chemical vapor deposition (CVD), physical vapor deposition, (PVD), atomic layer deposition (ALD), or other applicable processes.

After the liner layer 174 is formed, an etching process is performed to remove the portions of the liner layer 174 formed over the lateral surfaces, so that liners 174′ are formed on the sidewalls of the source/drain contact trenches 166 and the sidewalls of the though via trench 168, as shown in FIGS. 2R and 2R-1 in accordance with some embodiments. In some embodiments, the etching process includes dry chemical etching, remote plasma etching, wet etching, other applicable technique, and/or a combination thereof.

After the liners 174′ are formed, silicide layers 176 are formed over the exposed source/drain structures 140, as shown in FIGS. 2S and 2S-1 in accordance with some embodiments. In some embodiments, the silicide layers 176 are formed by forming metal layers over the top surface of the source/drain structures 140 and annealing the metal layers so the metal layers react with the source/drain structures 140 to form the silicide layers 176. The unreacted metal layers are then removed after the silicide layers 176 are formed in accordance with some embodiments. In some embodiments, the silicide layers 176 are N-type epi silicide such as TiSi, CrSi, TaSi, MoSi, ZrSi, HfSi, ScSi, Ysi, HoSi, TbSI, GdSi, LuSi, DySi, ErSi, YbSi, or the like. In some embodiments, the silicide layers 176 are P-type epi silicide such as NiSi, CoSi, MnSi, Wsi, FeSi, RhSi, PdSi, RuSi, PtSi, IrSi, OsSi, or the like. In some embodiments, the silicide layer 176 has a thickness in the Z direction in a range from about 2 nm to about 10 nm.

After the silicide layers 176 are formed, a conductive filling layer 178 is formed to fill the source/drain contact trenches 166 and the through via trench 168 and a polishing process is performed, as shown in FIGS. 2T and 2T-1 in accordance with some embodiments. In some embodiments, the conductive filling layer 178 is made of W, Ru, Co, Cu, Ti, TiN, Ta, TaN, Mo, Ni, other applicable conductive materials, or a combination thereof. The conductive filling layer 178 may be formed using a process such as chemical vapor deposition (CVD), physical vapor deposition (PVD), plasma enhanced CVD (PECVD), plasma enhanced physical vapor deposition (PEPVD), atomic layer deposition (ALD), or any other applicable deposition processes. In some embodiments, the conductive filling layer 178 formed over the dielectric layer 164 and the upper portion of the dielectric layer 164 is removed by the polishing process.

After the polishing process is performed, an etching process 180 is performed to remove the dummy spacers 172′ and to form gaps 182, as shown in FIGS. 2U and 2U-1 in accordance with some embodiments. In some embodiments, the etching process 180 includes using a chemical base gas containing F or Cl along with carrier gas such as He or H₂. In some embodiments, the etching process 180 is performed under a pressure in a range from about 0.1 Torr to about 100 Torr. In some embodiments, the etching process 180 is performed at a temperature in a range from about 0° C. to about 200° C. In some embodiments, the etching process 180 is performed for a period of time in a range from about 15 sec to about 200 sec. The etching process 180 may be an isotropic etching (with little or no bombardment), so that the removal of the dummy spacers 172′ can be achieved even with high aspect ratio, as long as the etching time is long enough for the removal.

After the gaps 182 are formed, a sealing layer 184 is formed, as shown in FIGS. 2V and 2V-1 in accordance with some embodiments. FIG. 2V-2 illustrates an enlarged cross-sectional view of the semiconductor structure in block B_{2V} shown in FIG. 2V-1 in accordance with some embodiments. More specifically, the sealing layer 184 is formed over the conductive filling layers 178, the liners 170′ and 174′, and the dielectric layer 164 in accordance with some embodiments. In addition, the sealing layer 184 further extends into the gaps 182 between the liners 170′ and 174′, and air gaps 186 are formed in the sealing layer 184 between the liners 170′ and 174′, as shown in FIG. 2V-2 in accordance with some embodiments. In some embodiments, the sealing layer 184 has a thickness over the sidewalls of the liners 170′ or 174′ in the X direction in a range from about 0.1 nm to about 2 nm. In some embodiments, the sealing layer 184 has recessed portions 185 at its top surface due to the gaps 182 underneath. In some embodiments, the sealing layer 184 is made of SiO, HfSi, SiOC, AlO, ZrSi, AlON, ZrO, HfO, TiO, ZrAlO, ZnO, TaO, LaO, YO, TaCN, SiN, SiOCN, Si, SiOCN, ZrN, SiCN, or the like. The sealing layer 184 may be formed by performing chemical vapor deposition (CVD), physical vapor deposition, (PVD), atomic layer deposition (ALD), or other applicable processes.

After the sealing layer 184 is formed, a polishing process is performed to form source/drain contacts 188 and a though via structure 190, as shown in FIGS. 2W and 2W-1 in accordance with some embodiments. More specifically, the portions of the sealing layer 184 outside the gaps 182 are removed during the polishing process, so that sealing structures 184′ are formed in the gaps 182 to block the gaps 182. FIG. 2W-2 illustrates an enlarged cross-sectional view of the semiconductor structure in block B_{2W} shown in FIG. 2W-1 in accordance with some embodiments.

In some embodiments, the source/drain contacts 188 include the conductive filling layer 178 formed over the silicide layers 176, liners 170′ and 174′ surrounding the sidewalls of the conductive filling layers 178, and the sealing structures 184′ laterally sandwiched between the liners 170′ and 174′. In addition, the air gaps 186 are embedded in the sealing structures 184′ in accordance with some embodiments. In some embodiments, the topmost portion of the air gap 186 in the source/drain contacts 188 is lower than the top surface of the dielectric layer 164 and higher than a bottom surface of the dielectric layer 164. In some embodiments, the bottommost portion of the air gap 186 in the source/drain contacts 188 is higher than the topmost surface of the channel members 108-1, 108-2, and 108-3. In some embodiments, the air gap 186 in the source/drain contacts 188 has a width in the X direction in a range from about 1.5 nm to about 5 nm.

In some embodiments, the through via structure 190 includes the conductive filling layer 178 formed over the wide isolation structure 160, liners 170′ and 174′ surrounding the sidewalls of the conductive filling layers 178, and the sealing structures 184′ laterally sandwiched between the liners 170′ and 174′. In addition, the air gaps 186 are embedded in the sealing structures 184′ in accordance with some embodiments. In some embodiments, the topmost portion of the air gap 186 in the through via structure 190 is lower than the top surface of the dielectric layer 164 and higher than a bottom surface of the dielectric layer 164. In some embodiments, the bottommost portion of the air gap 186 in the through via structure 190 is lower than the topmost surface of the channel members 108-1, 108-2, and 108-3. In some embodiments, the air gap 186 in the through via structure 190 has a width in the X direction in a range from about 1.5 nm to about 5 nm. In some embodiments, the sealing structure 184′ that laterally surrounds the air gap 186 has a thickness of 0.1 nm to 2 nm.

Next, a front end structure 194 is formed over the dielectric layer 164, the source/drain contacts 188, and the through via structure 190, and a carrier substrate 196 is formed over the front end structure 194, as shown in FIGS. 2W, 2W-1, and 2W-2 in accordance with some embodiments. In some embodiments, the front end structure 194 includes an interconnect structure (e.g. a top interconnect structure). In some embodiments, the interconnect structure includes conductive structures (e.g. vias and metal lines) formed in multiple dielectric layers. In some embodiments, the source/drain contacts 188 and the through via structure 190 are electrically connected to the conductive structures in the interconnect structure of the front end structure 194. After the front end structure 194 is formed, the carrier substrate 196 is attached to the front end structure 194 to support the semiconductor structure in subsequent manufacturing process.

Next, the substrate 102 may be turned upside down to form elements over the backside of the substrate. More specifically, after the carrier substrate 196 is attached to the front end structure 194, the substrate 102 is turned upside down, and a planarization process is performed to the backside of the substrate 102, as shown in FIGS. 2X and 2X-1 in accordance with some embodiments. In some embodiments, the planarization process is performed to the substrate 102 until the isolation structure 112 is exposed. In some embodiments, the gate isolation structure 158, the wide isolation structure 160, and the isolation structure 112 are also partially removed during the planarization process. In some embodiments, the isolation structure 112 has a thickness T_{STI} in a range from about 30 nm to about 70 nm after the planarization process is performed. The remaining thickness T_{STI} of the isolation structure 112 should be thick enough to prevent the metal layers formed thereover being too close to the gate structures 148 underneath. On the other hand, the thickness T_{STI} of the isolation structure 112 should not be too thick or the through via structure formed through it may have a relatively high aspect ratio that may result in high resistance. The planarization process may be an etching process, a CMP process, a mechanical grinding process, a dry polishing process, or a combination thereof.

It should be appreciated that although the structures in FIGS. 2X to 2ZJ and 2X-1 to 2ZJ-1 are shown in upside down for better understanding the manufacturing processes, the spatial positions of the elements (e.g. top portions, bottom portions, topmost, bottommost, or the like) are described according to the original positions shown in FIGS. 2A to 2W so they can be in consistence with those described previously for clarity. For example, the top surface of the source/drain structure 140 is referred to the surface in contact with the source/drain contacts 188, and the bottom surface of the source/drain structures 140 is referred to the surface in contact with the base fin structures 105, since the structure shown in FIG. 2X is upside down.

Next, conductive structures may be formed at the backside of the semiconductor structure. More specifically, a mask layer 200 is formed, and backside conductive via trenches 202 and a through via trench 204 are formed through the mask layer 200, as shown in FIGS. 2Y and 2Y-1 in accordance with some embodiments. In some embodiments, the mask layer 200 is made of SiO, SiOC, AlO, AlON, ZrO, HfO, TiO, ZrAlO, ZnO, SiOCN, SiOCN, SiCN, or the like. The mask layer may be formed by performing chemical vapor deposition (CVD), physical vapor deposition, (PVD), atomic layer deposition (ALD), or other applicable processes.

In some embodiments, the backside conductive via trenches 202 are formed through the mask layer 200, the base fin structure 105, and the bottom isolation layers 132, so that the bottom portions of the source/drain structures 140 are exposed. In some embodiments, the bottom portions of the source/drain structures 140 are also slightly removed. In some embodiments, the through via trench 204 is formed through the mask layer 200 and extends into the wide isolation structure 160, so that the bottom portion of the though via structure 190 is exposed. In some embodiments, the width of the through via trench 204 is no greater (e.g. smaller) than the width of the though via structure 190 along both the X direction and the Y direction.

The conductive structures formed in the backside conductive via trenches 202 and the through via trench 204 may have structures that are similar to, or the same as, the source/drain contacts 188 and the though via structure 190 described above. More specifically, a liner layer 270 is conformally formed, as shown in FIGS. 2Z and 2Z-1 in accordance with some embodiments. More specifically, the liner layer 270 is formed over the bottom surfaces and sidewalls of the backside conductive via trenches 202 and the though via trench 204 in accordance with some embodiments. That is, the liner layer 270 covers the sidewall surfaces of the bottom isolation layers 132, the base fin structures 105, and the mask layer 200 and also covers the bottom surfaces of the source/drain structures 140 exposed by the backside conductive via trenches 202 in accordance with some embodiments. In addition, the liner layer 270 also covers the sidewalls of the wide isolation structure 160 and the bottom portion of the though via structure 190 exposed by the through via trench 204 in accordance with some embodiments. Furthermore, the top surface of the mask layer 200 is also covered by the liner layer 270 in accordance with some embodiments.

In some embodiments, the liner layers 170 and 270 are made of different materials. In some embodiments, the liner layers 170 and 270 are made of the same material. In some embodiments, the liner layer 270 is made of SiO, HfSi, SiOC, AlO, ZrSi, AlON, ZrO, HfO, TiO, ZrAlO, ZnO, TaO, LaO, YO, TaCN, SiN, SiOCN, Si, SiOCN, ZrN, SiCN, or the like. In some embodiments, the liner layer 270 formed over the vertical sidewalls (e.g. the sidewalls of the base fin structures 105 and the sidewalls of the wide isolation structure 160) has a thickness in the X direction in a range from about 1 nm to about 5 nm. In some embodiments, the liner layer 270 formed over the lateral surfaces (e.g. the bottom surface of the source/drain structures 140 and the bottom surface of the though via structure 190) has a thickness in the Z direction in a range from about 0.8 to about 4.5 nm. The liner layer 120 may be formed by performing chemical vapor deposition (CVD), physical vapor deposition, (PVD), atomic layer deposition (ALD), or other applicable processes.

After the liner layer 270 is formed, a dummy spacer layer 272 is formed over the liner layer 270, as shown in FIGS. 2ZA and 2ZA-1 in accordance with some embodiments. In some embodiments, the dummy spacer layers 172 and 272 are made of the same material. In some embodiments, the dummy spacer layer 272 is made of Si, SiGe, SiGeB, SiB, or the like. In some embodiments, the dummy spacer layer 272 has a thickness in the X direction in a range from about 1 nm to about 5 nm.

After the dummy spacer layer 272 is formed, an etching process is performed to remove the dummy spacer layer 272 formed over the lateral surfaces, so that dummy spacers 272′ are formed on the sidewalls of the backside conductive via trenches 202 and the sidewalls of the though via trench 204, as shown in FIGS. 2ZB and 2ZB-1 in accordance with some embodiments. In some embodiments, the etching process includes dry chemical etching, remote plasma etching, wet etching, other applicable technique, and/or a combination thereof.

After the dummy spacers 272′ are formed, another etching process is performed to remove the portions of the liner layer 270 formed over the lateral surfaces, so that liners 270′ are formed on the sidewalls of the backside conductive via trenches 202 and the sidewalls of the though via trench 204, as shown in FIGS. 2ZC and 2ZC-1 in accordance with some embodiments. In some embodiments, the etching process includes dry chemical etching, remote plasma etching, wet etching, other applicable technique, and/or a combination thereof. As shown in FIG. 2ZC-1, the liner 270′ has an L shape in the cross-sectional view in the X direction. In some embodiments, the liners 270′ and the dummy spacers 272′ have rounded top corners.

Afterwards, a liner layer 274 is conformally formed to cover the liners 270′, the dummy spacers 272′, the top surfaces of the mask layer 200, the source/drain structures 140, and the though via structure 190, as shown in FIGS. 2ZD and 2ZD-1 in accordance with some embodiments. In some embodiments, the liner layers 174, 274, 170, and 270 are made of different materials. In some embodiments, the liners layers 174, 274, 170, and 270 are made of the same material. In some embodiments, the liner layer 274 is made of SiO, HfSi, SiOC, AlO, ZrSi, AlON, ZrO, HfO, TiO, ZrAlO, ZnO, TaO, LaO, YO, TaCN, SiN, SiOCN, Si, SiOCN, ZrN, SiCN, or the like. In some embodiments, the liner layer 274 has a thickness in the X direction in a range from about 1 nm to about 5 nm. The liner layer 274 may be formed by performing chemical vapor deposition (CVD), physical vapor deposition, (PVD), atomic layer deposition (ALD), or other applicable processes.

After the liner layer 274 is formed, an etching process is performed to remove the portions of the liner layer 274 formed over the lateral surfaces, so that liners 274′ are formed on the sidewalls of the backside conductive via trenches 202 and the sidewalls of the though via trench 204, as shown in FIGS. 2ZE and 2ZE-1 in accordance with some embodiments. In some embodiments, the etching process includes dry chemical etching, remote plasma etching, wet etching, other applicable technique, and/or a combination thereof.

After the liners 274′ are formed, silicide layers 276 are formed over the exposed source/drain structures 140, as shown in FIGS. 2ZF and 2ZF-1 in accordance with some embodiments. In some embodiments, the silicide layers 276 are formed by forming metal layers over the top surface of the source/drain structures 140 and annealing the metal layers so the metal layers react with the source/drain structures 140 to form the silicide layers 276. The unreacted metal layers are then removed after the silicide layers 276 are formed in accordance with some embodiments. In some embodiments, the silicide layers 276 are N-type epi silicide such as TiSi, CrSi, TaSi, MoSi, ZrSi, HfSi, ScSi, Ysi, HoSi, TbSI, GdSi, LuSi, DySi, ErSi, YbSi, or the like. In some embodiments, the silicide layers 276 are P-type epi silicide such as NiSi, CoSi, MnSi, Wsi, FeSi, RhSi, PdSi, RuSi, PtSi, IrSi, OsSi, or the like. In some embodiments, the silicide layers 176 and 276 are made of different materials. In some embodiments, the silicide layers 176 and 276 are made of the same material. In some embodiments, the silicide layer 276 has a thickness in the Z direction in a range from about 2 nm to about 10 nm.

After the silicide layers 276 are formed, a conductive filling layer 278 is formed to fill the backside conductive via trenches 202 and the through via trench 204, and a polishing process is performed, as shown in FIGS. 2ZG and 2ZG-1 in accordance with some embodiments. In some embodiments, the conductive filling layers 178 and 278 are made of different materials. In some embodiments, the conductive filling layers 178 and 278 are made of the same material. In some embodiments, the conductive filling layer 278 is made of W, Ru, Co, Cu, Ti, TiN, Ta, TaN, Mo, Ni, other applicable conductive materials, or a combination thereof. The conductive filling layer 278 may be formed using a process such as chemical vapor deposition (CVD), physical vapor deposition (PVD), plasma enhanced CVD (PECVD), plasma enhanced physical vapor deposition (PEPVD), atomic layer deposition (ALD), or any other applicable deposition processes. In some embodiments, the conductive filling layer 278 formed over the mask layer 200 are removed by the polishing process.

After the polishing process is performed, an etching process 280 is performed to remove the dummy spacers 272′ and to form gaps 282, as shown in FIGS. 2ZH and 2ZH-1 in accordance with some embodiments. In some embodiments, the etching process 280 includes using a chemical base gas containing F or Cl along with carrier gas such as He or H₂. In some embodiments, the etching process 280 is performed under a pressure in a range from about 0.1 Torr to about 100 Torr. In some embodiments, the etching process 280 is performed at a temperature in a range from about 0° C. to about 200° C. In some embodiments, the etching process 280 is performed for a period of time in a range from about 15 sec to about 200 sec. The etching process 280 may be an isotropic etching (with little or no bombardment), so that the removal of the dummy spacers 272′ can be achieved even with a high aspect ratio as long as the etching time is long enough to complete the removal.

After the gaps 282 are formed, a sealing layer 284 is formed, as shown in FIGS. 2ZI and 2ZI-1 in accordance with some embodiments. More specifically, the sealing layer 284 is formed over the conductive filling layers 278, the liners 270′ and 274′, and the mask layer 200 in accordance with some embodiments. In addition, the sealing layer 284 further extends into the gaps 282 between the liners 270′ and 274′, and air gaps 286 are formed in the sealing layer 284 between the liners 270′ and 274′, as shown in FIG. 2ZI-1 in accordance with some embodiments. In some embodiments, the sealing layer 284 has a thickness over the sidewalls of the liners 270′ or 274′ in the X direction in a range from about 0.1 nm to about 2 nm. In some embodiments, the sealing layer 284 has recessed portions 285 in its top surface due to the gaps 282 underneath.

In some embodiments, the sealing layers 184 and 284 are made of different materials. In some embodiments, the sealing layers 184 and 284 are made of the same material. In some embodiments, the sealing layer 284 is made of SiO, HfSi, SiOC, AlO, ZrSi, AlON, ZrO, HfO, TiO, ZrAlO, ZnO, TaO, LaO, YO, TaCN, SiN, SiOCN, Si, SiOCN, ZrN, SiCN, or the like. The sealing layer 284 may be formed by performing chemical vapor deposition (CVD), physical vapor deposition, (PVD), atomic layer deposition (ALD), or other applicable processes.

After the sealing layer 284 is formed, a polishing process is performed to form backside conductive via 288 and a though via structure 290, as shown in FIGS. 2ZJ and 2ZJ-1 in accordance with some embodiments. More specifically, the portions of the sealing layer 284 outside the gaps 282 are removed during the polishing process, so that sealing structures 284′ are formed in the gaps 282 to block the gaps 282 in accordance with some embodiments. FIG. 2ZJ-2 illustrates an enlarged cross-sectional view of the semiconductor structure in block B2ZJ shown in FIG. 2ZJ-1 in accordance with some embodiments.

In some embodiments, the backside conductive vias 288 include the conductive filling layer 278 formed over the silicide layers 276, liners 270′ and 274′ surrounding the sidewalls of the conductive filling layers 278, and the sealing structures 284′ laterally sandwiched between the liners 270′ and 274′. In addition, the air gap 286 is embedded in the sealing structures 284′ in accordance with some embodiments. In some embodiments, a first end portion of the air gap 286 in the backside conductive vias 288 is lower than the top surface of the mask layer 200 and is higher than the bottom surface of the mask layer 200. In some embodiments, a second end portion of the air gap 286 in the backside conductive vias 288 is higher than the bottommost surface of the gate structures 148 and lower than the bottommost surface of the channel members 108-1, 108-2, and 108-3. In some embodiments, the air gap 286 in the backside conductive vias 288 has a width in the X direction in a range from about 1.5 nm to about 5 nm.

In some embodiments, the through via structure 290 includes the conductive filling layer 278 formed over the though via structure 190, liners 270′ and 274′ surrounding the sidewalls of the conductive filling layers 278, the sealing structures 284′ laterally sandwiched between the liners 270′ and 274′, and the air gap 286 embedded in the sealing structures 284′. In some embodiments, a first end portion of the air gap 286 in the through via structure 290 is lower than the top surface of the dielectric layer 200 and higher than the bottom surface of the dielectric layer 200. In some embodiments, a second end portion of the air gap 286 in the through via structure 290 is higher than the bottommost surface of the channel members 108-1, 108-2, and 108-3. In some embodiments, the air gap 286 in the through via structure 290 has a width in the X direction in a range from about 1.5 nm to about 5 nm. In some embodiments, the first conductive filling layer 178 has a first dimension in the X direction, the second conductive filling layer 278 has a second dimension in the X direction, and the first dimension is greater than the second dimension.

Next, a back end structure 294 is formed over the mask layer 200, the backside conductive vias 288, and the though via structure 290, and the semiconductor structure 100 is formed, as shown in FIGS. 2ZJ, 2ZJ-1, and 2ZJ-2 in accordance with some embodiments. In some embodiments, the back end structure 294 includes a bottom interconnect structure. In some embodiments, the interconnect structure includes conductive structures (e.g. vias and metal lines) formed in multiple dielectric layers. In some embodiments, the backside conductive via 288 and the through via structure 290 are electrically connected to the conductive structures in the interconnect structure of the back end structure 294.

In some embodiments, the through via structure 190 and the through via structure 290 form a through via structure 390. In some embodiments, the through via structure 290 is narrower than the through via structure 190 along both the X and the Y direction. In some other embodiments, the through via structure 290 and the through via structure 190 have substantially the same width along both the X and the Y direction. In some embodiments, the conductive filling layer 178 is in physical contact with the conductive filling layer 278 and the liners 270′ and 274′, while the conductive filling layer 278 is separated from the liners 170′ and 174′.

In some embodiments, the through via structure 390, including the through via structures 190 and 290, is laterally surrounded by the wide isolation structure 160, and the width of the wide isolation structure 160 is greater than the width of the through via structure 390 along both X and Y direction. In some embodiments, the thickness of the wide isolation structure 160 around the through via structure 278 is greater than the thickness of the wide isolation structure 160 around the through via structure 178 along both X and Y direction.

In some embodiments, the thickness of the through via structure 390 in the Z direction is substantially equal to the distance between the top surface of the source/drain contact 188 and a bottom surface of the backside conductive via 288 in the Z direction. In some embodiments, the backside conductive via 288 has a height in a range from about 5 nm to about 50 nm. In some embodiments, the backside conductive via 288 has a greater width in the mask layer 200 and a narrower width in the base fin structure 105. In some embodiments, the backside conductive via 288 formed in the mask layer 200 has a width in a range from about 10 nm to about 50 nm. In some embodiments, the backside conductive via 288 formed in the base fin structure 105 has a width in a range from about 8 nm to about 40 nm. In some embodiments, the silicide layer 276 has a thickness in a range from about 1 nm to about 10 nm. In some embodiments, the mask layer 200 has a thickness in a range from about 5 nm to about 40 nm.

In some embodiments, the through via structure 290 has a height in a range from about 20 nm to about 200 nm. In some embodiments, the through via structure 290 has a greater width in the mask layer 200 and a narrower width in the base fin structure 105. In some embodiments, the through via structure 290 formed in the mask layer 200 has a width in a range from about 30 nm to about 100 nm. In some embodiments, the through via structure 290 formed in the base fin structure 105 has a width in a range from about 25 nm to about 90 nm.

In some embodiments, the through via structure 190 has a height in a range from about 20 nm to about 200 nm. In some embodiments, the through via structure 190 has a greater width in the dielectric layer 164 and a narrower width around the gate spacers 128. In some embodiments, the through via structure 190 formed in dielectric layer 164 has a width in a range from about 30 nm to about 100 nm. In some embodiments, the through via structure 290 formed around the gate spacers 128 has a width in a range from about 25 nm to about 90 nm. In some embodiments, the source/drain contact 188 has a height in a range from about 5 nm to about 50 nm. In some embodiments, the source/drain contact 188 has a width in a range from about 6 nm to about 20 nm.

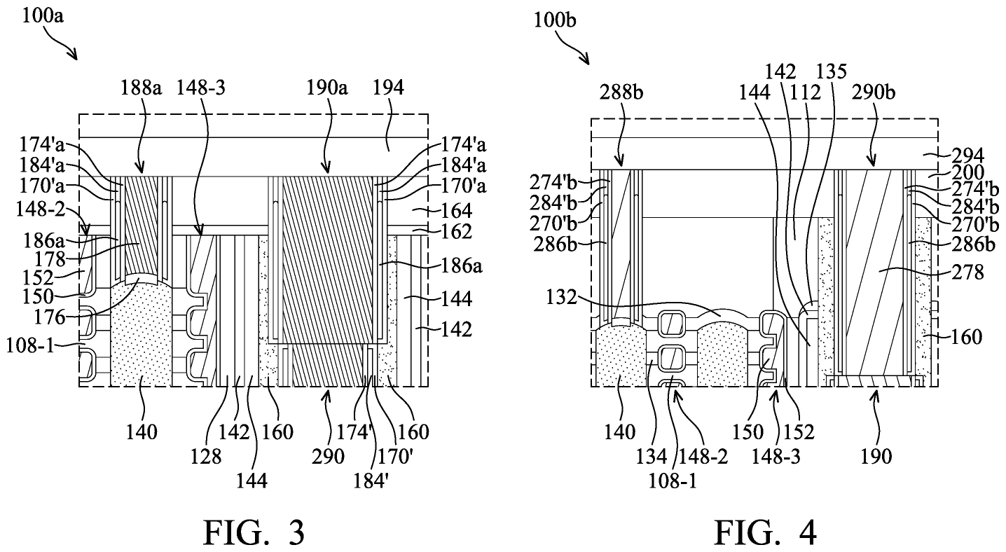

FIG. 3 illustrates a cross-sectional view of a semiconductor structure 100a in accordance with some embodiments. The semiconductor structure 100a may be similar to the semiconductor structure 100 described previously, except that the sealing structures in the source/drain contact and in the through via structure do not extend into the bottom portion of the gaps in accordance with some embodiments. Processes and materials for forming the semiconductor structure 100a may be similar to, or the same as, those for forming the semiconductor structure 100 described previously and are not repeated herein.

More specifically, the semiconductor structure 100a includes a source/drain contact 188a and a through via structure 190a in accordance with some embodiments. The source/drain contact 188a includes the conductive filling layer 178, liners 170′a, sealing structures 184′a, and liners 174′a in accordance with some embodiments. In addition, the sealing structures 184′a are formed over the upper portions of the gaps between the liners 170′a and 174′a, so that the sidewalls of the liners 170′a and 174′a are partially exposed by air gaps 186a. Similarly, the through via structure 190a also includes the conductive filling layer 178, liners 170′a, sealing structures 184′a, and the liners 174′a in ac, and the sealing structures 184′a are formed over the upper portions of the gaps between the liners 170′a and 174′a. The processes and materials for forming the liners 170′a, the sealing structures 184′a, and the liners 174′a are similar to, or the same as, those for forming the liners 170′, the sealing structures 184′, and the liners 174′ described previously and are not repeated herein.

FIG. 4 illustrates a cross-sectional view of a semiconductor structure 100b in accordance with some embodiments. The semiconductor structure 100b may be similar to the semiconductor structure 100 described previously, except the sealing structures in the backside conductive via and in the through via structure do not extend into the bottom portion of the gaps in accordance with some embodiments. Processes and materials for forming the semiconductor structure 100b may be similar to, or the same as, those for forming the semiconductor structure 100 described previously and are not repeated herein.

More specifically, the semiconductor structure 100b includes a backside conductive via 288b and a through via structure 290b in accordance with some embodiments. Both of the backside conductive via 288b and the through via structure 290b include the conductive filling layer 278, liners 270′b, sealing structures 284′b, and liners 274′b in accordance with some embodiments. In addition, the sealing structures 284′b are formed over the upper portions of the gaps between the liners 270′b and 274′b, so that the sidewalls of the liners 270′b and 274′b are partially exposed by air gaps 186b. The processes and materials for forming the liners 170′b, the sealing structures 184′b, and the liners 174′b are similar to, or the same as, those for forming the liners 170′, the sealing structures 184′, and the liners 174′ described previously and are not repeated herein.

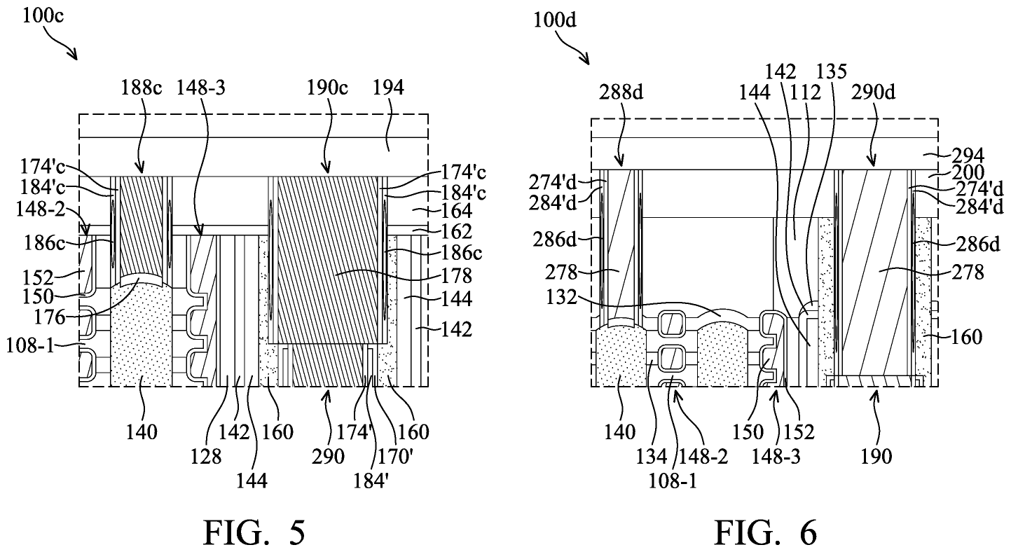

FIG. 5 illustrates a cross-sectional view of a semiconductor structure 100c in accordance with some embodiments. The semiconductor structure 100c may be similar to the semiconductor structure 100 described previously, except only a single liner is formed in the source/drain contact and the through via structure in accordance with some embodiments. Processes and materials for forming the semiconductor structure 100c may be similar to, or the same as, those for forming the semiconductor structure 100 described previously and are not repeated herein.

More specifically, the processes shown in FIGS. 2A to 2ZJ may be performed, except the formation of the liner layer 170 is omitted, so that the dummy spacer layer (e.g. the dummy spacer layer 172) is directly formed on the sidewalls of the source/drain contact trenches and the though via trench (e.g. the source/drain contact trenches 166 and the though via trench 168 shown in FIG. 2L). Therefore, the semiconductor structure 100c includes a source/drain contact 188c and a through via structure 190c, and both of the source/drain contact 188c and the through via structure 190c include the conductive filling layer 178, sealing structures 184′c, and liners 174′c in accordance with some embodiments. In addition, air gaps 186 are formed in the sealing structures 184′c. The processes and materials for forming the sealing structures 184′c and the liners 174′c are similar to, or the same as, those for forming the sealing structures 184′ and the liners 174′ described previously and are not repeated herein.

FIG. 6 illustrates a cross-sectional view of a semiconductor structure 100d in accordance with some embodiments. The semiconductor structure 100d may be similar to the semiconductor structure 100 described previously, except only a single liner is formed in the backside conductive via and the through via structure in accordance with some embodiments. Processes and materials for forming the semiconductor structure 100d may be similar to, or the same as, those for forming the semiconductor structure 100 described previously and are not repeated herein.

More specifically, the processes shown in FIGS. 2A to 2ZJ may be performed, except the formation of the liner layer 270 is omitted, so that the dummy spacer layer (e.g. the dummy spacer layer 272) is directly formed on the sidewalls of the backside conductive via trenches and the though via trench (e.g. the backside conductive via trenches 202 and the though via trench 204 shown in FIG. 2Y). Therefore, the semiconductor structure 100d includes a backside conductive via 288d and a through via structure 290d, and both of the backside conductive via 288d and the through via structure 290d include the conductive filling layer 278, sealing structures 284′d, and liners 274′d in accordance with some embodiments. In addition, air gaps 286d are formed in the sealing structures 284′d. The processes and materials for forming the sealing structures 284′d and the liners 274′d are similar to, or the same as, those for forming the sealing structures 284′ and the liners 274′ described previously and are not repeated herein.

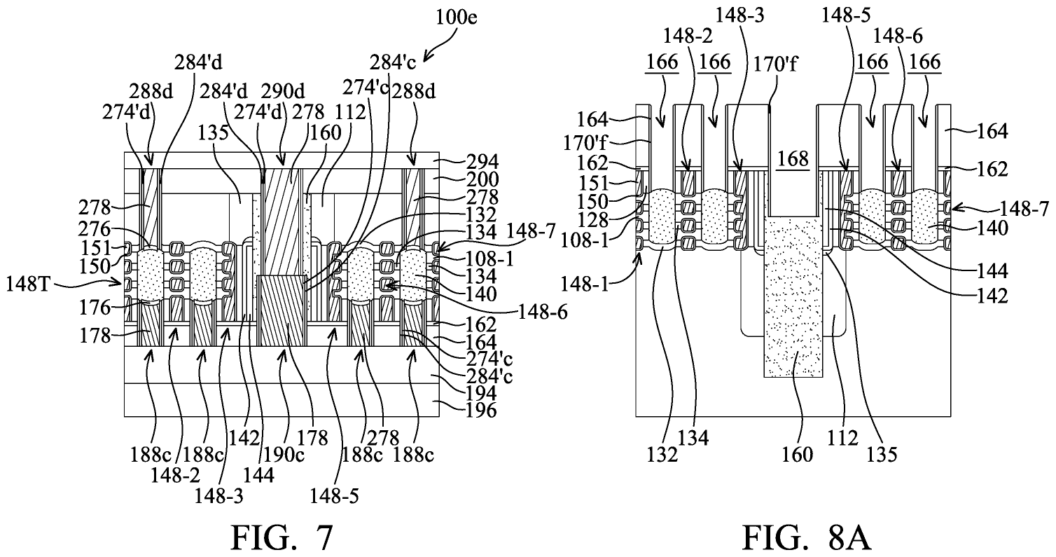

FIG. 7 illustrates a cross-sectional view of a semiconductor structure 100e in accordance with some embodiments. The semiconductor structure 100e may be similar to the semiconductor structure 100 described previously, except only a single liner is formed in the source/drain contact, the backside conductive via, and the through via structures in accordance with some embodiments. More specifically, the semiconductor structure 100e include the source/drain contacts 188c and the through via structures 190c as shown in FIG. 5 and the backside conductive vias 288d and the through via structures 290d as shown in FIG. 6 in accordance with some embodiments. Processes and materials for forming the semiconductor structure 100e may be similar to, or the same as, those for forming the semiconductor structures 100, 100c, and 100d described previously and are not repeated herein.

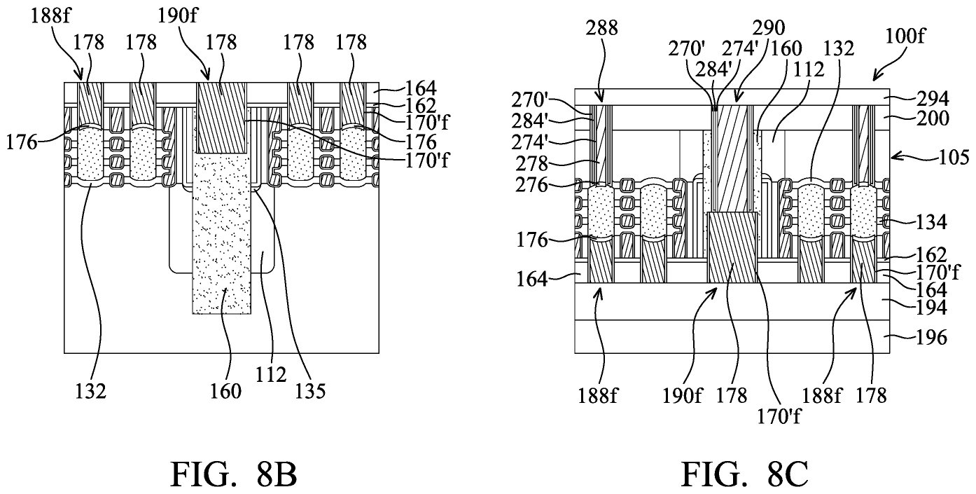

FIGS. 8A to 8C illustrate cross-sectional views of intermediate stages of manufacturing a semiconductor structure 100f in accordance with some embodiments. The semiconductor structure 100f may be similar to the semiconductor structure 100 described previously, except air gaps are not formed in the source/drain contact and the through via structure in accordance with some embodiments. Processes and materials for forming the semiconductor structure 100f may be similar to, or the same as, those for forming the semiconductor structure 100 described previously and are not repeated herein.

More specifically, the processes shown in FIGS. 2A to 2L and 2A-1 to 2L-1 are performed to form the source/drain contact trenches 166 and the though via trench 168, and liners 170′f are formed on the sidewalls of the source/drain contact trenches 166 and the though via trench 168, as shown in FIG. 8A in accordance with some embodiments. After the liners 170′f are formed, the conductive filling layer 178 is formed in the source/drain contact trenches 166 and the though via trench 168, and a polishing process is performed to form source/drain contact 188f and a though via structure 190f, as shown in FIG. 8B in accordance with some embodiments. In some embodiments, the formation of the liners 170′f is omitted.

Afterwards, the front end structure 194 and the carrier substrate 196 are formed, and the processes shown in FIGS. 2X to 2ZJ and 2X-1 to 2ZJ-1 are performed to form the semiconductor structure 100f, as shown in FIG. 8C in accordance with some embodiments. The processes and materials for forming the liners 170′f are similar to, or the same as, those for forming the liners 170′ described previously and are not repeated herein.

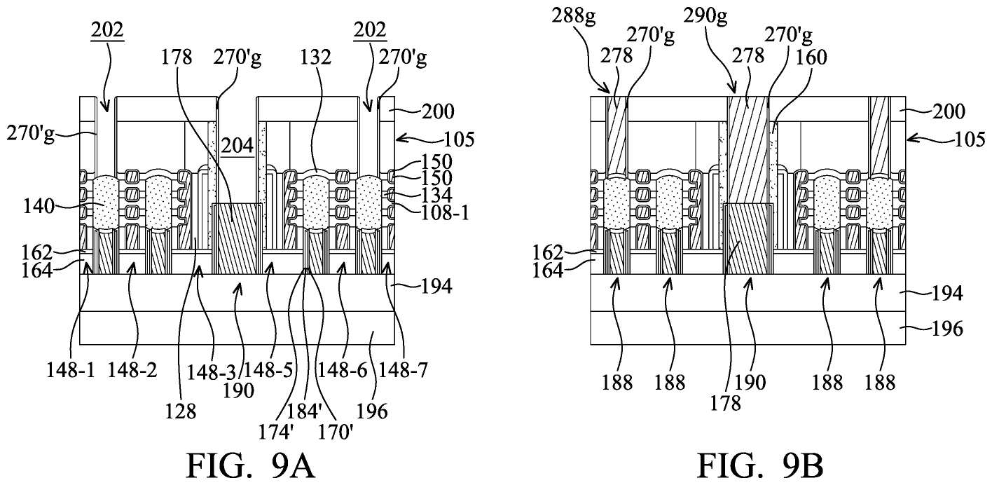

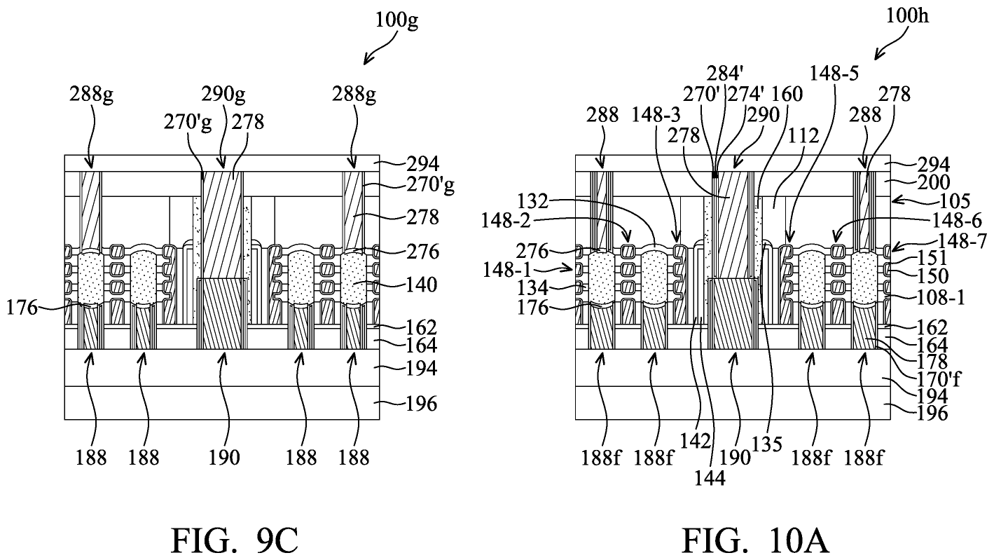

FIGS. 9A to 9C illustrate cross-sectional views of intermediate stages of manufacturing a semiconductor structure 100g in accordance with some embodiments. The semiconductor structure 100g may be similar to the semiconductor structure 100 described previously, except air gaps are not formed in the backside conductive via and the through via structure in accordance with some embodiments. Processes and materials for forming the semiconductor structure 100g may be similar to, or the same as, those for forming the semiconductor structure 100 described previously and are not repeated herein.

More specifically, the processes shown in FIGS. 2A to 2Y and 2A-1 to 2Y-1 are performed to form the backside conductive via trenches 202 and the through via trench 204, and liners 270′g are formed on the sidewalls of the backside conductive via trenches 202 and the through via trench 204, as shown in FIG. 9A in accordance with some embodiments. After the liners 270′g are formed, the conductive filling layer 278 is formed in the backside conductive via trenches 202 and the through via trench 204, and a polishing process is performed to form a backside conductive via 288g and a though via structure 290g, as shown in FIG. 9B in accordance with some embodiments. In some embodiments, the formation of the liners 270′g is omitted.

Afterwards, the back end structure 294 is formed, and the semiconductor structure 100g is formed, as shown in FIG. 9C in accordance with some embodiments. The processes and materials for forming the liners 270′g are similar to, or the same as, those for forming the liners 270′ described previously and are not repeated herein.

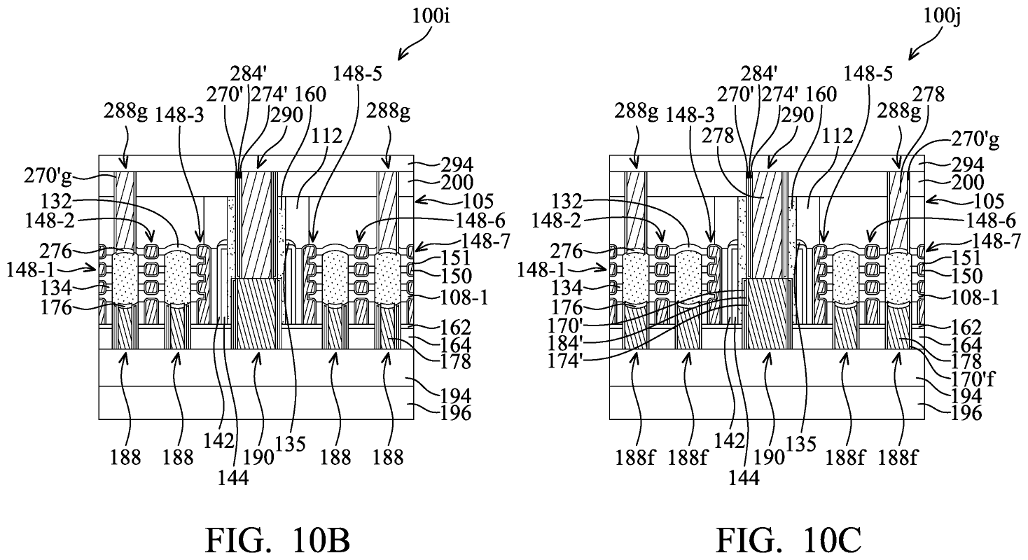

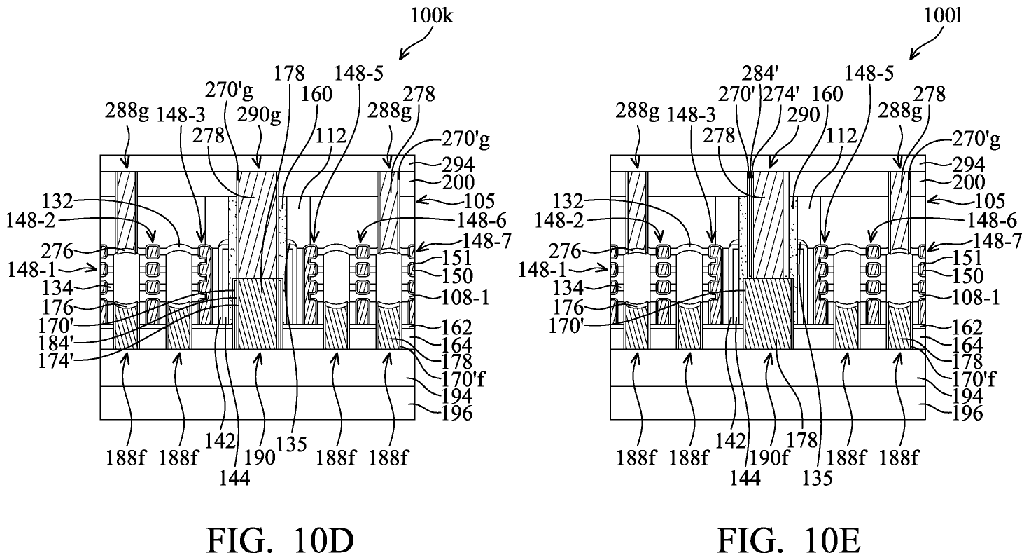

FIG. 10A illustrates a cross-sectional view of a semiconductor structure 100h in accordance with some embodiments. The semiconductor structure 100h may be similar to the semiconductor structure 100 described previously, except air gaps are not formed in the source/drain contacts 188f in accordance with some embodiments. More specifically, the source/drain contacts 188f are formed first, and the through via structure 190 are formed after the source/drain contacts 188f are formed in accordance with some embodiments. That is, the source/drain contacts 188f and the through via structure 190 may be formed in separated processes. Processes and materials for forming the semiconductor structure 100h may be similar to, or the same as, those for forming the semiconductor structures 100 and 100f described previously and are not repeated herein.

FIG. 10B illustrates a cross-sectional view of a semiconductor structure 100i in accordance with some embodiments. The semiconductor structure 100i may be similar to the semiconductor structure 100 described previously, except air gaps are not formed in the backside conductive vias 288g in accordance with some embodiments. More specifically, the backside conductive vias 288g and the through via structure 290 are formed separately, and the backside conductive vias 288g do not have air gaps formed therein in accordance with some embodiments. Processes and materials for forming the semiconductor structure 100i may be similar to, or the same as, those for forming the semiconductor structures 100 and 100g described previously and are not repeated herein.

FIG. 10C illustrates a cross-sectional view of a semiconductor structure 100j in accordance with some embodiments. The semiconductor structure 100j may be similar to the semiconductor structure 100 described previously, except air gaps are not formed in the source/drain contacts 188f and the backside conductive vias 288g in accordance with some embodiments. Processes and materials for forming the semiconductor structure 100j may be similar to, or the same as, those for forming the semiconductor structures 100, 100f, 100g, 100h, and 100i described previously and are not repeated herein.

FIG. 10D illustrates a cross-sectional view of a semiconductor structure 100k in accordance with some embodiments. The semiconductor structure 100k may be similar to the semiconductor structure 100 described previously, except air gaps are not formed in the source/drain contacts 188f, the backside conductive vias 288g, and the through via structure 290g in accordance with some embodiments. Processes and materials for forming the semiconductor structure 100k may be similar to, or the same as, those for forming the semiconductor structures 100, 100f, 100g, 100h, and 100i described previously and are not repeated herein.

FIG. 10E illustrates a cross-sectional view of a semiconductor structure 100l in accordance with some embodiments. The semiconductor structure 100l may be similar to the semiconductor structure 100 described previously, except air gaps are not formed in the source/drain contacts 188f, the backside conductive vias 288g, and the through via structure 190f in accordance with some embodiments. Processes and materials for forming the semiconductor structure 100l may be similar to, or the same as, those for forming the semiconductor structures 100, 100f, 100g, 100h, and 100i described previously and are not repeated herein.

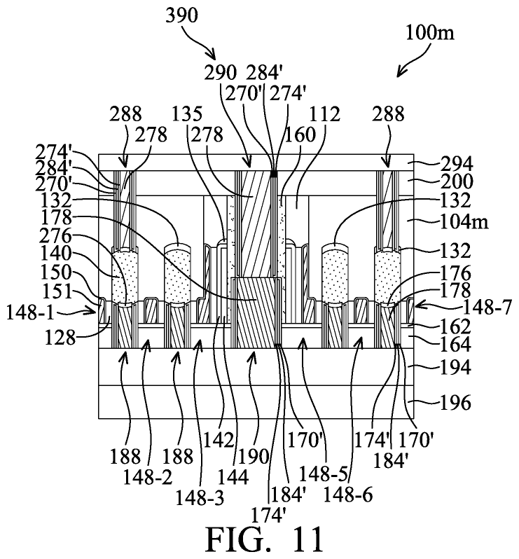

The through via structures described above may also be applied to other kinds of transistors, such as planner transistors or FinFET structures. FIG. 11 illustrates a cross-sectional view of a semiconductor structure 100m in accordance with some embodiments. The semiconductor structure 100m may be similar to the semiconductor structure 100 described previously, except the semiconductor structure 100m is a FinFET structure in accordance with some embodiments. Processes and materials for forming the semiconductor structure 100m may be similar to, or the same as, those for forming the semiconductor structure 100 described previously and are not repeated herein.

More specifically, the substrate 102 is patterned to form fin structures 104m without forming the first semiconductor material layers and the second semiconductor material layers thereon in accordance with some embodiments. The processes shown in FIGS. 2B to 2ZJ and 2B-1 to 2ZJ-1 may be performed, except the channel members and the inner spacers are not formed. As shown in FIG. 11, the through via structure 390, including the through via structures 290 and 190, is thicker than the fin structure 104m in the Z direction in accordance with some embodiments.

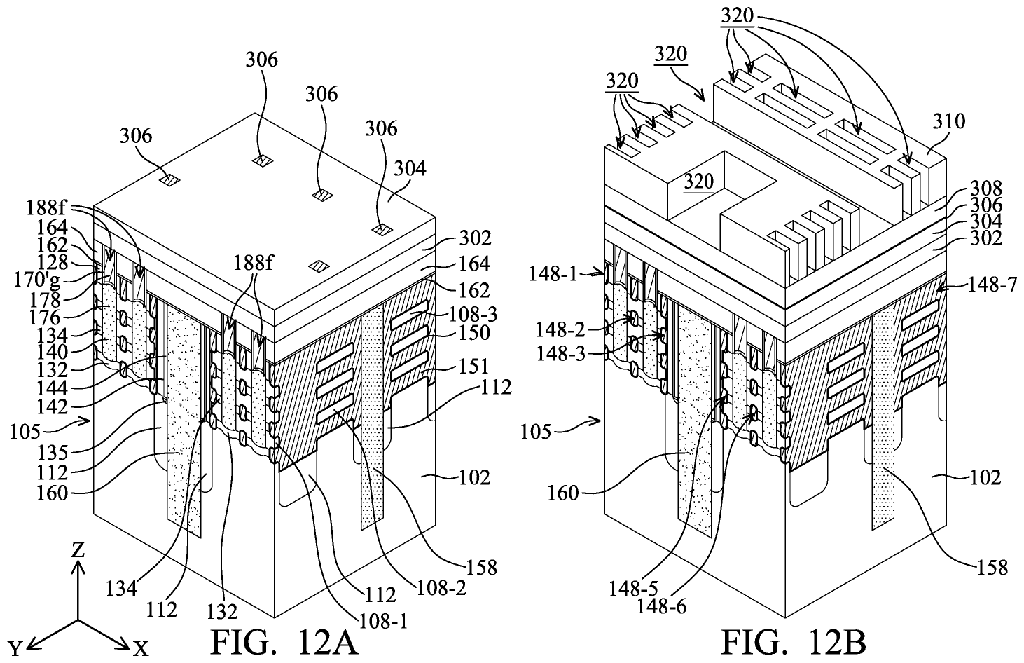

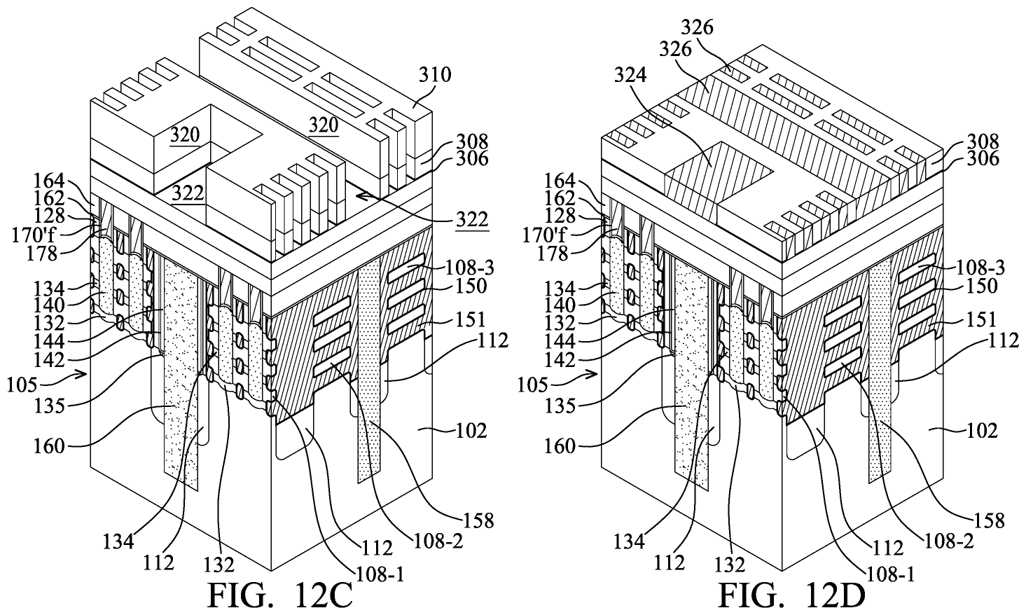

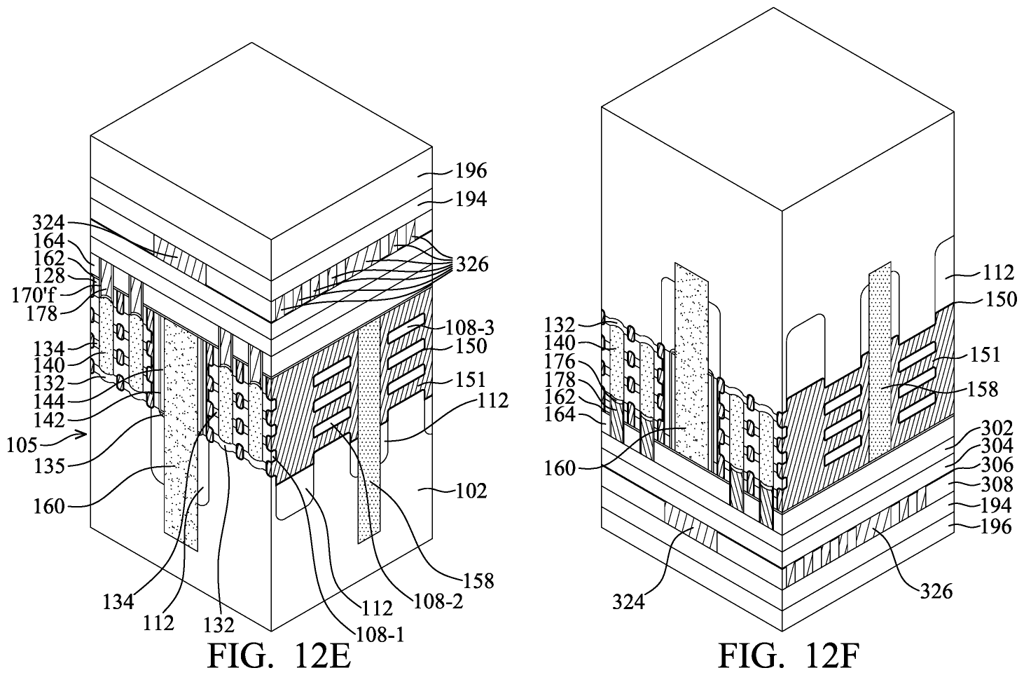

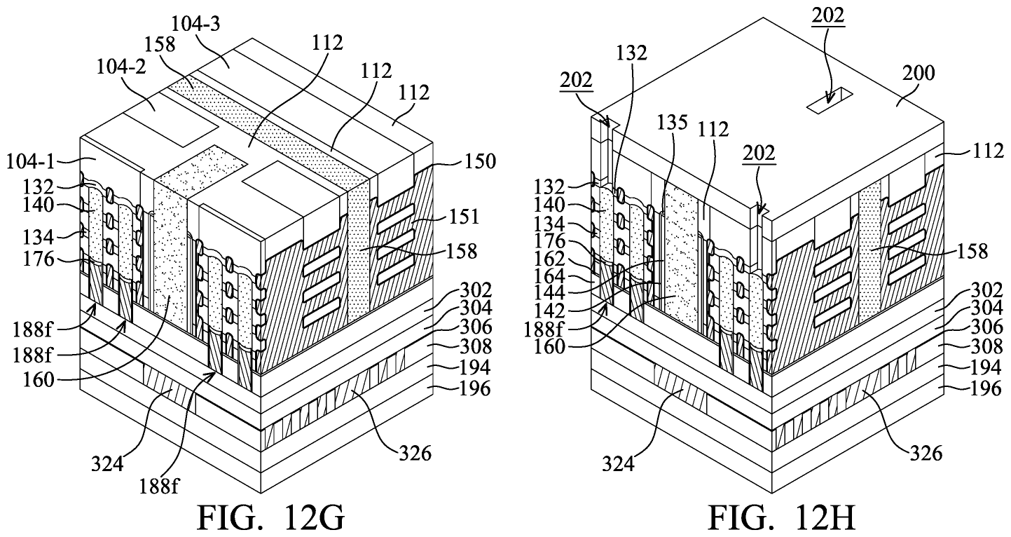

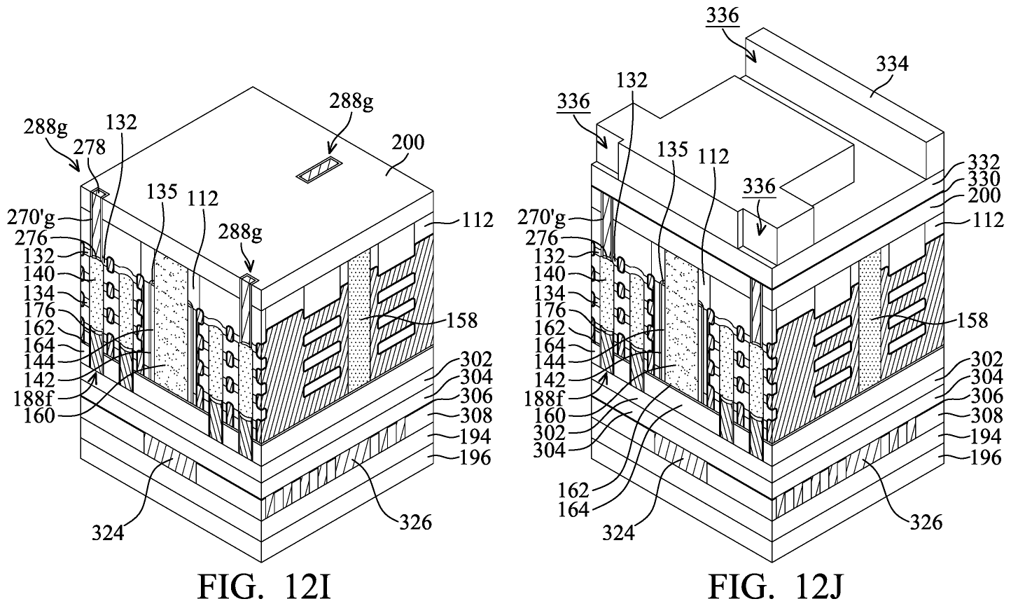

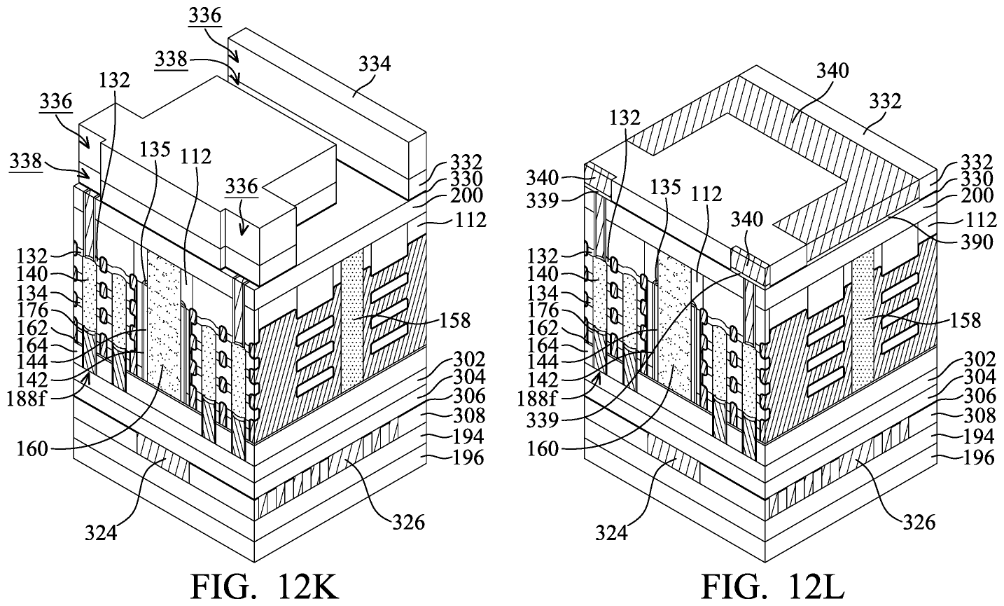

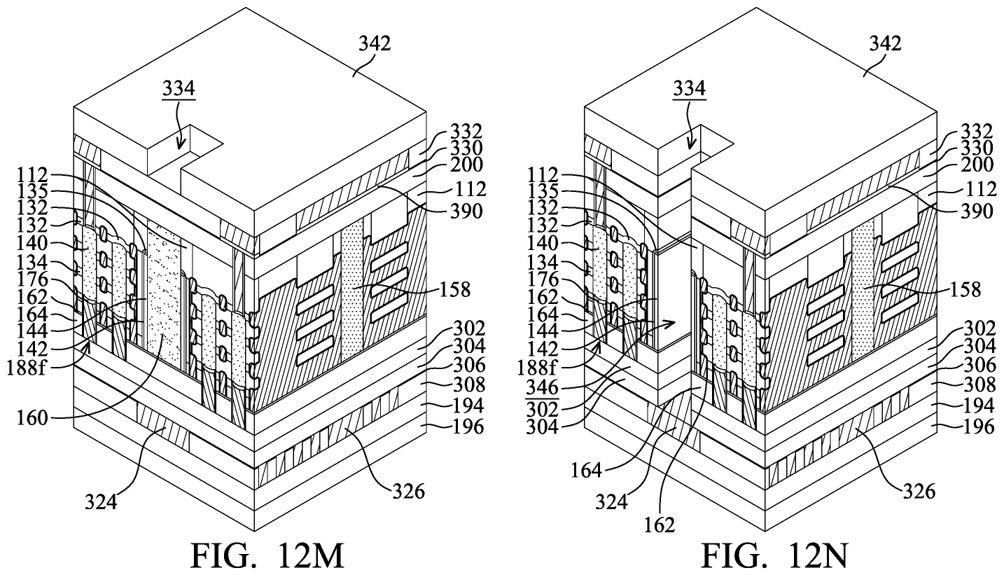

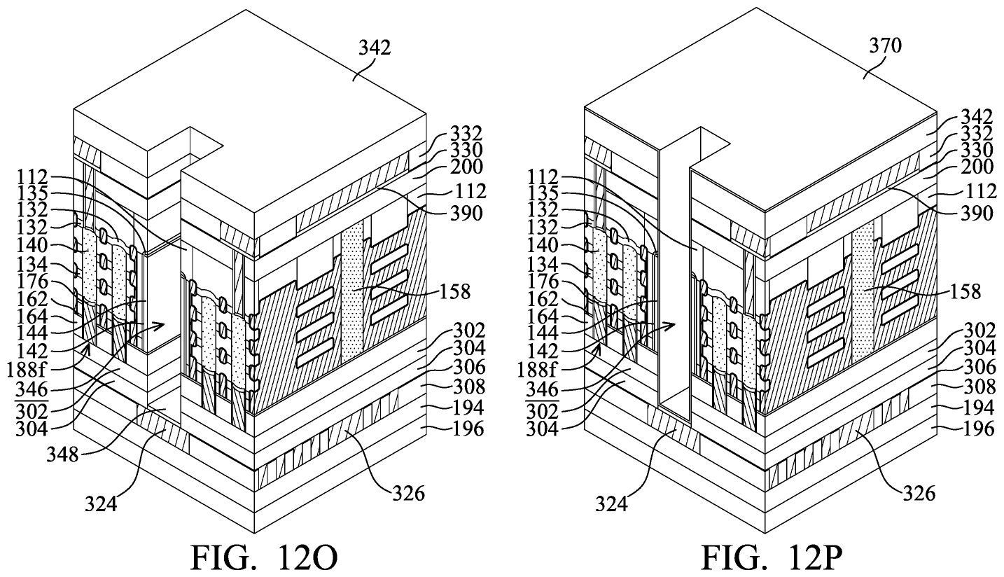

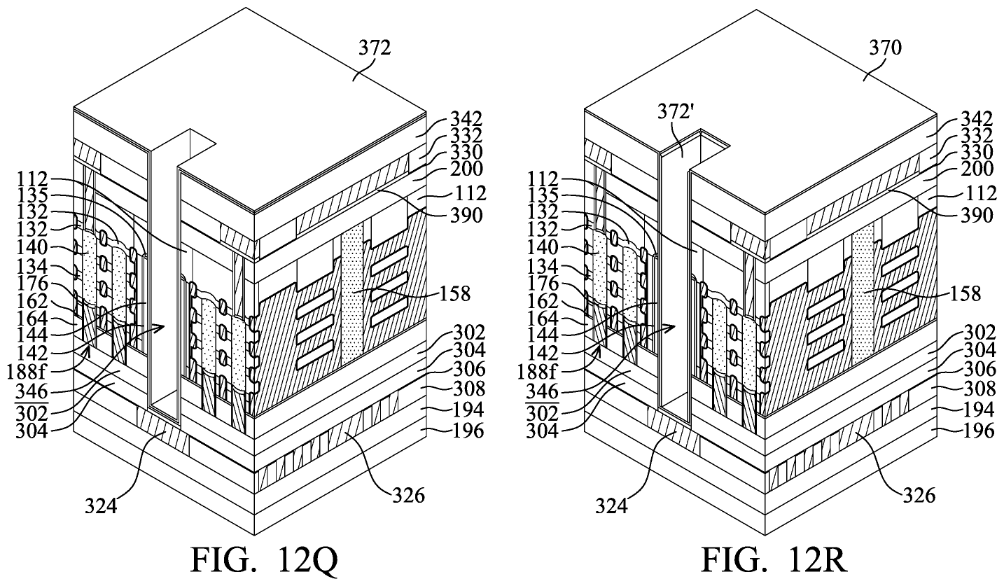

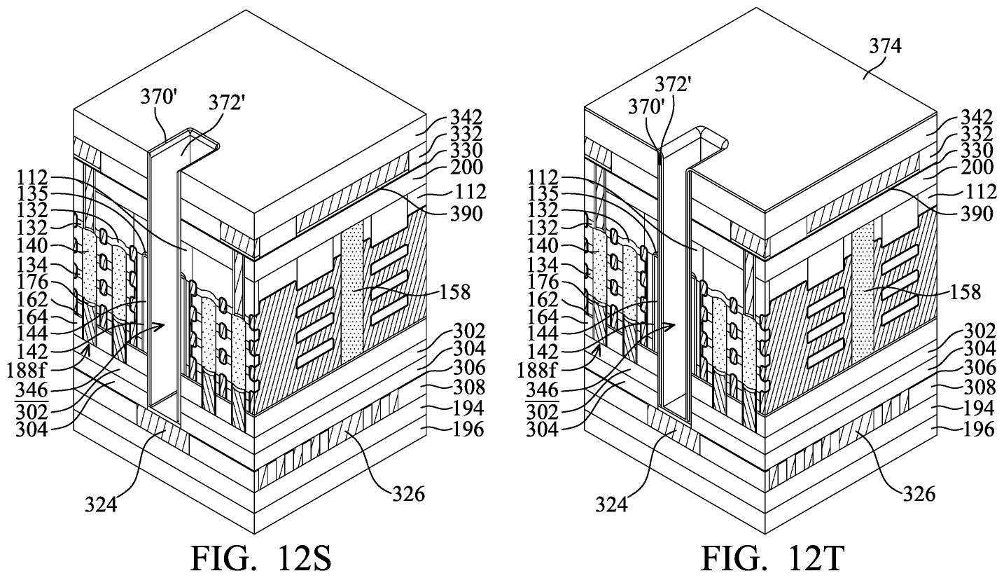

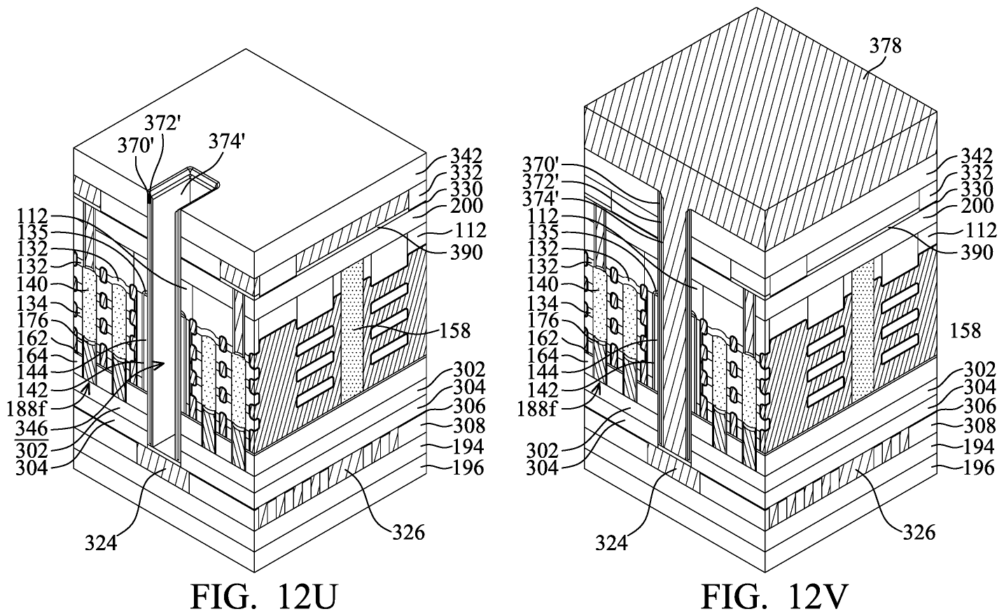

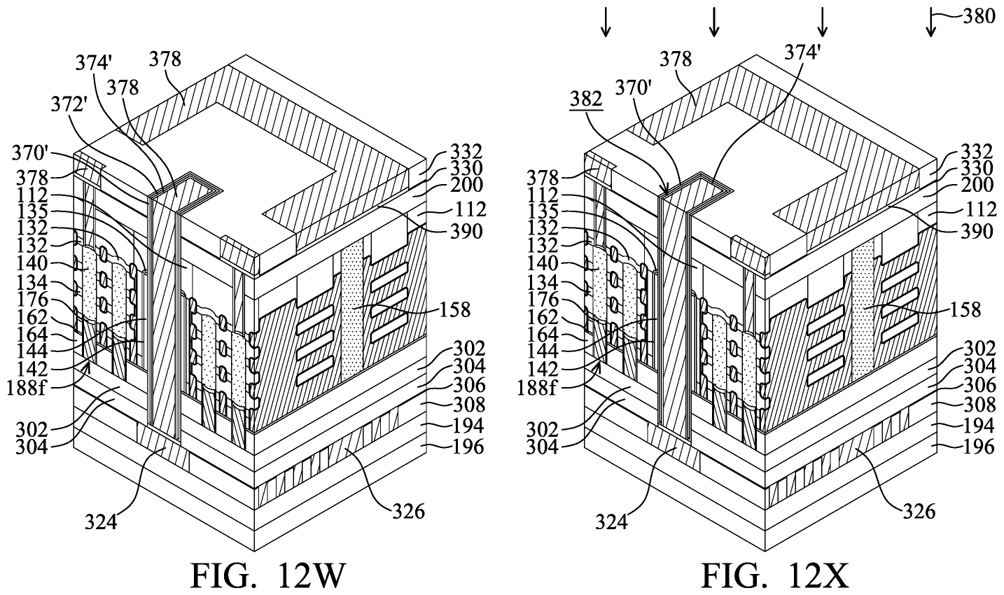

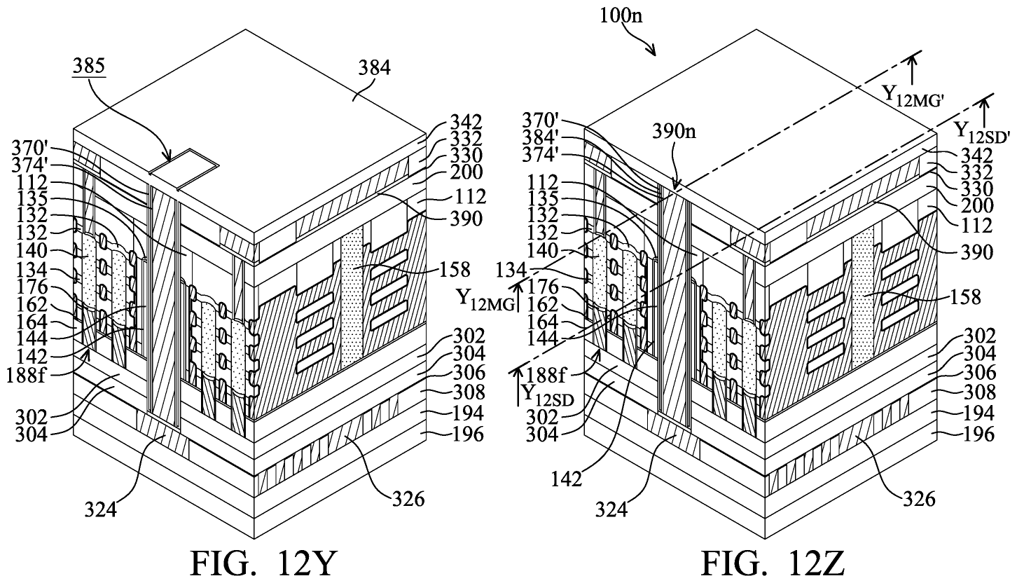

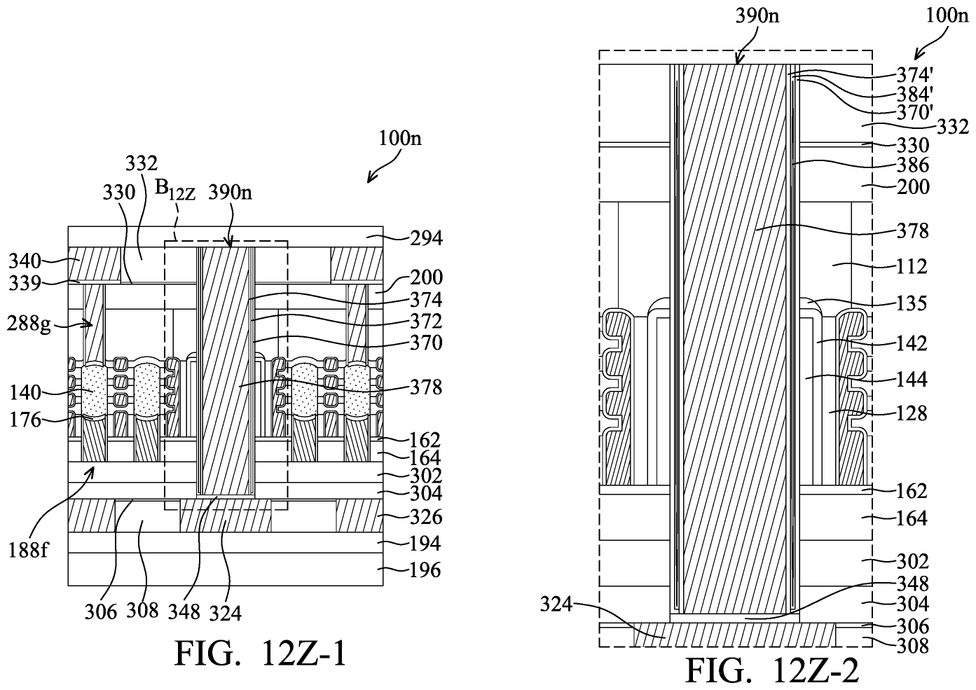

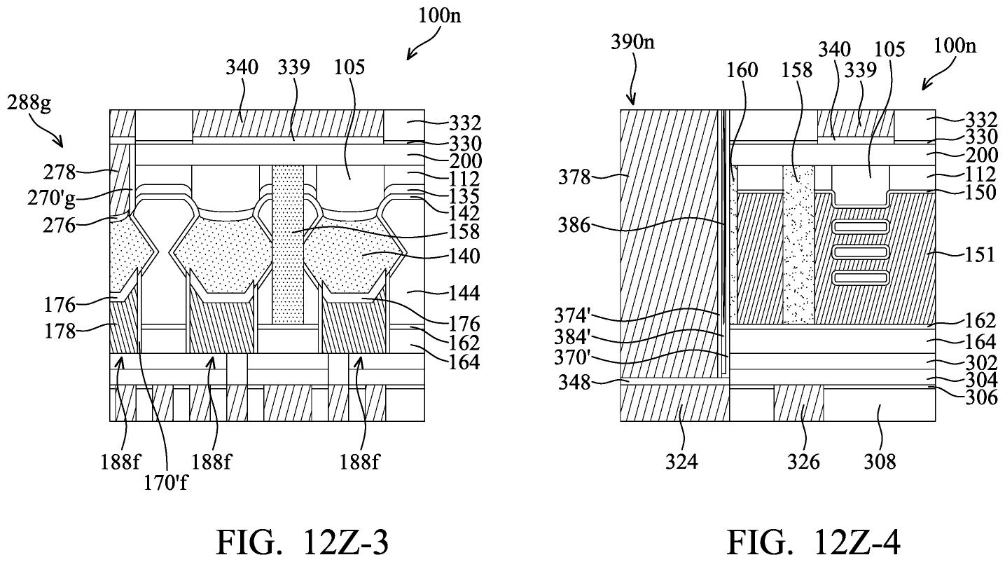

FIGS. 12A to 12Z illustrate diagrammatic perspective views of intermediate stages of manufacturing the semiconductor structure 100n in accordance with some embodiments. Some processes and materials for forming the semiconductor structure 100n may be similar to, or the same as, those for forming the semiconductor structure 100 and 100a to 100m described previously and are not repeated herein.

More specifically, the processes shown in FIGS. 2A to 2K and 2A-1 to 2K-1 may be performed to form the gate isolation structure 158 and the wide isolation structure 160, and a front side interconnect structure may be formed. More specifically, the etch stop layer 162, the dielectric layer 164, and the source/drain contacts 188f (similar to those shown in FIG. 8C) are formed, as shown in FIG. 12A in accordance with some embodiments.

After the source/drain contacts 188f are formed, an etch stop layer 302 and a dielectric layer 304 are formed, and front side via structures 306 are formed through the etch stop layer 302 and the dielectric layer 304, as shown in FIG. 12A in accordance with some embodiments. In some embodiments, the front side via structures 306 are electrically connected to the source/drain contacts 188f.

In some embodiments, the etch stop layer 302 is made of a dielectric material, such as silicon nitride, silicon oxide, silicon oxynitride, another suitable dielectric material, or a combination thereof. The dielectric material for forming the etch stop layers 302 may be conformally deposited over the semiconductor structure by performing CVD, ALD, other application methods, or a combination thereof.

The dielectric layer 304 may include multilayers made of multiple dielectric materials, such as silicon oxide, silicon nitride, silicon oxynitride, phosphosilicate glass (PSG), borophosphosilicate glass (BPSG), or other applicable low-k dielectric materials. The dielectric layer 304 may be formed by chemical vapor deposition (CVD), physical vapor deposition, (PVD), atomic layer deposition (ALD), or other applicable processes.

The front side via structures 306 may be formed by forming front side via trenches through the etch stop layer 302 and the dielectric layer 304 and forming a conductive material in the front side via trenches. In some embodiments, the conductive material includes W, Ru, Co, Cu, Ti, TiN, Ta, TaN, Mo, Ni, or the like. In addition, liners may be formed at the sidewalls of the front side via trenches before forming the conductive material. The liners may be made of materials similar to, or the same as, that the liners 170′ are made of.

After the front side via structures 306 are formed, an etch stop layer 306, a dielectric layer 308, and a mask layer 310 with openings 320 are formed, as shown in FIG. 12B in accordance with some embodiments. The processes and materials for forming the etch stop layer 306, the dielectric layer 308, and the mask layer 310 are similar to, or the same as, those for forming the etch stop layer 302, the dielectric layer 304, and the mask layer 200 described previously and are not repeated herein.

Afterwards, the etch stop layer 306 and the dielectric layer 308 are patterned through the openings 320 of the mask layer 310 to form openings 322, as shown in FIG. 12C in accordance with some embodiments. In some embodiments, an etching process is performed to form the openings 322, such as dry chemical etching, remote plasma etching, wet etching, other applicable technique, and/or a combination thereof.

After the openings 322 are formed, a wide conductive pad 324 and metal lines 326 are formed in the openings 322, and the mask layer 310 is removed, as shown in FIG. 12D in accordance with some embodiments. More specifically, a conductive material may be formed in the openings, and a CMP process may be performed to remove excess conductive material and the mask layer 310. In some embodiments, the conductive material is W, Ru, Co, Cu, Ti, TiN, Ta, TaN, Mo, Ni, or the like. In some embodiments, the wide conductive pad 324 vertically overlaps the wide isolation structure 160. In some embodiments, the width of the wide conductive pad 324 is greater than the width of the wide isolation structure 160 along both the X direction and the Y direction. That is, the edges of the wide isolation structure 160 is completely covered by (e.g. under the projection of) the wide conductive pad 324 in accordance with some embodiments. In some embodiments, the wide conductive pad 324 has a width in the X direction in a range from about 20 nm to about 60 nm. In some embodiments, the wide conductive pad 324 has a width in the Y direction in a range from about 20 nm to about 60 nm. It should be appreciated that the metal lines 326 may have different widths and different lengths and the pattern of the metal lines 326 is not limited to the pattern shown in FIG. 12D.

Next, the front end structure 194 and the carrier substrate 196 is formed over the front end structure 194, as shown in FIG. 12E in accordance with some embodiments. In some embodiments, the wide conductive structure 324 and the metal lines 326 are electrically connected to the conductive structures in the interconnect structure of the front end structure 194.

Next, the substrate 102 may be turned upside down to form elements over the backside of the substrate 102. More specifically, after the carrier substrate 196 is attached to the front end structure 194, the substrate 102 is turned upside down, as shown in FIG. 12F in accordance with some embodiments. Afterwards, a planarization process is performed to the backside of the substrate 102, as shown in FIG. 12G in accordance with some embodiments. The planarization process may be similar to, or the same as, that shown in FIG. 2X and described previously and the details of which are not repeated herein.

Afterwards, the mask layer 200 is formed, and backside conductive via trenches 202 are formed through the mask layer 200, as shown in FIG. 12H in accordance with some embodiments. The silicide layers 276 and the backside conductive vias 288g (e.g. the backside conductive vias 288g shown in FIG. 9C) are then formed in the backside conductive via trenches 202, as shown in FIG. 12I in accordance with some embodiments. In some embodiments, the backside conductive vias 288g are vertically aligned with the source/drain contacts 188f. In some embodiments, the backside conductive vias 288g and the source/drain contacts 188f have substantially the same size. In some embodiments, the backside conductive vias 288g are smaller than the source/drain contacts 188f. In some embodiments, the width of the backside conductive via 288g in the X direction and/or Y direction is smaller than the width of the source/drain contact 188f in the X direction and/or Y direction.

After the backside conductive vias 288g are formed, an etch stop layer 330, a dielectric layer 332, and a mask layer 334 with openings 336 are formed, as shown in FIG. 12J in accordance with some embodiments. The processes and materials for forming the etch stop layer 330, the dielectric layer 332, and the mask layer 334 are similar to, or the same as, those for forming the etch stop layer 302, the dielectric layer 304, and the mask layer 200 described previously and are not repeated herein.

Afterwards, the etch stop layer 330, the dielectric layer 332 are patterned through the openings 336 of the mask layer 334 to form openings 338, as shown in FIG. 12K in accordance with some embodiments. In some embodiments, an etching process is performed to form the openings 338, such as dry chemical etching, remote plasma etching, wet etching, other applicable technique, and/or a combination thereof.

After the openings 338 are formed, a backside barrier layer 339 and backside metal lines 340 are formed in the openings 338, and the mask layer 334 is removed, as shown in FIG. 12L in accordance with some embodiments. In some embodiments, the backside barrier layer 339 is made of Co, Ru, Cu, Moly, W, or the like. In some embodiments, the backside barrier layer 339 is formed by performing a bottom-up deposition process. In some embodiments, the backside barrier layer 339 has a thickness in a range from about 5 nm to about 15 nm. In some embodiments, the backside metal lines 340 are made of Co, Ru, Cu, Moly, W, or the like. In some embodiments, the backside metal line 340 has a thickness in a range from about 5 nm to about 15 nm.

Next, a through via structure 390n may be formed through the wide isolation structure 160. More specifically, a mask layer 342 with an opening 344 is formed, as shown in FIG. 12M in accordance with some embodiments. Afterwards, a through via trench 346 is formed through the dielectric layer 332, the etch stop layer 330, the mask layer 200, the wide isolation structure 160, the etch stop layer 162, the dielectric layer 164, the etch stop layer 302, and the dielectric layer 304, so that the wide conductive pad 324 is exposed, as shown in FIG. 12N in accordance with some embodiments. As described previously, the backside conductive vias 288g may be formed in the backside conductive via trenches 202 first and then be covered by the mask layer 342. Therefore, although the through via trench 346 has a relatively great depth (e.g. compared to the backside conductive via trenches 202), the source/drain structures 140 will not be damaged due to the etching process for forming the through via trench 346.

In some embodiments, the width of the through via trench 346 is no greater than (e.g. substantially equal to) the width of the wide isolation structure 160 along both the X direction and the Y direction. In some embodiments, the contact etch stop layers 142, the interlayer dielectric layer 144, and the isolating capping layers 135 are also exposed by the through via trench 346. In some embodiments, the wide isolation structure 160 is completely removed.

After the through via trench 346 is formed, a bottom barrier layer 348 is formed over the exposed wide conductive pad 324, as shown in FIG. 12O in accordance with some embodiments. In some embodiments, the bottom barrier layer 348 is made of Ru, Co, TaN, TiN, or the like. In some embodiments, the bottom barrier layer 348 has a thickness in a range from about 1 nm to about 5 nm. In some embodiments, the bottom barrier layer 348 is formed by performing a bottom-up deposition process. As shown in FIG. 12O, the bottom barrier layer 348 may cover the exposed surface of the wide conductive pad 324 but may not cover the sidewalls of the through via trench 346. Therefore, the space opened up for forming a through via structure will not be taken up (e.g. remain the same width) by the bottom barrier layer 348.

The conductive structures formed in the through via trench 346 may have the structures that are similar to, or the same as, the though via structures 190 and 290 described above. More specifically, a liner layer 370 is conformally formed in the through via trench 346, as shown in FIG. 12P in accordance with some embodiments. In some embodiments, the liner layer 370 covers the sidewalls of the dielectric layer 332, the etch stop layer 330, the mask layer 200, the etch stop layer 162, the dielectric layer 164, the etch stop layer 302, and the dielectric layer 304. In some embodiments, the through via trench 346 is smaller than the wide isolation structure 160, and the liner layer 370 further covers the sidewalls of the wide isolation structure 160 (e.g. at the Y direction). In some embodiments, at least one width of the through via trench 346 (e.g. at the X direction) is substantially equal to the wide isolation structure 160, and the liner layer 370 further covers the sidewalls of the contact etch stop layers 142, the interlayer dielectric layer 144, and the isolating capping layers 135.

After the liner layer 370 is formed, a dummy spacer layer 372 is formed over the liner layer 370, as shown in FIG. 12Q in accordance with some embodiments. After the dummy spacer layer 372 is formed, an etching process is performed to remove the dummy spacer layer 372 formed over the lateral surface, so that dummy spacers 372′ are formed on the sidewalls of the through via trench 346, as shown in FIG. 12R in accordance with some embodiments. After the dummy spacers 372′ are formed, another etching process is performed to remove the portions of the liner layer 370 formed over the lateral surface, so that liners 370′ are formed on the sidewalls of the through via trench 346, as shown in FIG. 12S in accordance with some embodiments.

Afterwards, a liner layer 374 is conformally formed to cover the liners 370′ and the dummy spacers 372′, as shown in FIG. 12T in accordance with some embodiments. After the liner layer 374 is formed, an etching process is performed to remove the portions of the liner layer 374 formed over the lateral surface, so that liners 374′ are formed on the sidewalls of the through via trench 346, as shown in FIG. 12U in accordance with some embodiments.

After the liners 374′ are formed, a conductive filling layer 378 is formed to fill the through via trench 346, as shown in FIG. 12V in accordance with some embodiments. In some embodiments, the conductive filling layer 378 is made of Co, Ru, Cu, Moly, W, or the like. Afterwards, a polishing process is performed to remove the mask layer 342 and the conductive filling layer 378 over the mask layer 342, as shown in FIG. 12W in accordance with some embodiments. After the polishing process is performed, an etching process 380 is performed to remove the dummy spacer 372′ and to form a gap 382, as shown in FIG. 12X in accordance with some embodiments.

After the gap 382 is formed, a sealing layer 384 is formed, as shown in FIG. 12Y in accordance with some embodiments. In some embodiments, the sealing layer 384 has a recessed portion 385 at its top surface due to the gap 382 underneath. After the sealing layer 384 is formed, a polishing process is performed to form the though via structure 390n, and the backend structure 294 is formed over the though via structure 390n, as shown in FIG. 12Z in accordance with some embodiments.

In some embodiments, the through via structure 390n is electrically connected to both the conductive structures in the interconnect structure of the back end structure 294 and the conductive structures in the interconnect structure of the front end structure 194. In some embodiments, the thickness of the through via structure 390n in the Z direction is greater than the distance between the top surface of the source/drain contact 188f and a bottom surface of the backside conductive via 288g in the Z direction. In some embodiments, the thickness of the through via structure 390n in the Z direction is greater than the thickness of the gate structures 148 in the Z direction.

FIG. 12Z-1 illustrates a cross-sectional view of the semiconductor structure 100n in accordance with some embodiments. FIG. 12Z-2 illustrates an enlarged cross-sectional view of the semiconductor structure 100n in block B_{12Z} shown in FIG. 12Z-1 in accordance with some embodiments. The through via structure 390n includes the conductive filling layer 378, the liner 374′ surrounding the conductive filling layer 378, the sealing structures 384′ covers the sidewall of the liner 374′, and the liner 370′ covers the sidewall of the sealing structure 384′ in accordance with some embodiments. In addition, an air gap 386 is embedded in the sealing structure 384′, as shown in FIG. 12Z-2 in accordance with some embodiments. In some embodiments, the liner air gap 386 has a thickness in the X direction in a range from about 1 nm to about 10 nm.

In some embodiments, the liner 370′ has a thickness in the X direction in a range from about 1 nm to about 10 nm. In some embodiments, the liner 374′ has a thickness in the X direction in a range from about 1 nm to about 10 nm. In some embodiments, a distance between the top surface of the sealing structure 384′ and the topmost portion of the air gap 386 in the Z direction is in a range from about 1 nm to about 10 nm. In some embodiments, a distance between the bottom surface of the sealing structure 384′ and the bottommost portion of the air gap 386 in the Z direction is in a range from about 1 nm to about 10 nm. In some embodiments, the sealing structure that laterally surrounds the air gap 386 has a width in the X direction in a range from about 0.5 nm to about 5 nm.

FIG. 12Z-3 illustrates a cross-sectional view of the semiconductor structure 100n along line Y_{12SD}-Y_{12SD}′ shown in FIG. 12Z in accordance with some embodiments. In some embodiments, the gate isolation structure 158 has a width between the source/drain structures 140 in the Y direction in a range from about 20 nm to about 50 nm. In some embodiments, the backside conductive via 288g has a height in a range from about 5 nm to about 50 nm. In some embodiments, the backside conductive via 288g has a width in the X direction in a range from about 30 nm to about 100 nm. In some embodiments, the backside conductive via 288g has a width in the Y direction in a range from about 30 nm to about 100 nm. In some embodiments, the backside conductive via 288g has a greater thickness in the mask layer 200 and a narrower thickness in the base fin structure 105. In some embodiments, the backside conductive via 288 formed in the mask layer 200 has a thickness in a range from about 2 nm to about 20 nm. In some embodiments, the backside conductive via 288 formed in the base fin structure 105 has a thickness in a range from about 20 nm to about 100 nm. In some embodiments, the silicide layer 276 has a thickness in the Z direction in a range from about 1 nm to about 10 nm. In some embodiments, the source/drain contact 188f has a thickness in the Z direction in a range from about 3 nm to about 50 nm. In some embodiments, the source/drain contact 188f has a thickness in the Y direction in a range from about 30 nm to about 100 nm. In some embodiments, the source/drain contact 188f has a thickness in the X direction in a range from about 30 nm to about 100 nm. In some embodiments, the dielectric layer 164 has a thickness in the Z direction in a range from about 5 nm to about 40 nm.

FIG. 12Z-4 illustrates a cross-sectional view of the semiconductor structure 100n along line Y_{12MG}-Y_{12MG}′ shown in FIG. 12Z in accordance with some embodiments. In some embodiments, the through via structure 390n has a thickness in the Z direction in a range from about 80 nm to about 200 nm. In some embodiments, the through via structure 390n has a width in the Y direction in a range from about 35 nm to about 130 nm.

The processes and materials for forming the liner layer 370, the dummy spacer layer 372, the liner layer 374, the conductive filling layer 378, and the sealing layer 384 and the method for performing the etching process 380 are similar to, or the same as, those for forming the liner layer 270, the dummy spacer layer 272, the liner layer 274, the conductive filling layer 278, and the sealing layer 284 and the method for performing the etching process 280 described previously and are not repeated herein.

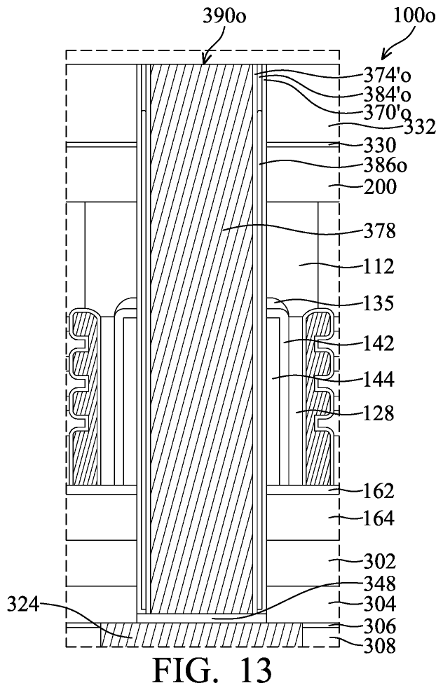

FIG. 13 illustrates a cross-sectional view of a semiconductor structure 100o in accordance with some embodiments. The semiconductor structure 100o may be similar to the semiconductor structure 100n described previously, except the sealing structures in the through via structure do not extend into the bottom portion of the gaps in accordance with some embodiments. Processes and materials for forming the semiconductor structure 100o may be similar to, or the same as, those for forming the semiconductor structure 100n described previously and are not repeated herein.

More specifically, the semiconductor structure 100o includes a through via structure 390o in accordance with some embodiments. The through via structure 390o includes the conductive filling layer 378, liners 370′o, sealing structures 384′o, and the liners 374′o in ac, and the sealing structures 384′o are formed over the upper portions of the gaps between the liners 370′o and 374′o, so that the sidewalls of the liners 370′o and 374′o are partially exposed by an air gap 386o in accordance with some embodiments. The processes and materials for forming the liners 370′o, the sealing structures 384′o, and the liners 374′o are similar to, or the same as, those for forming the liners 170′, the sealing structures 184′, and the liners 174′ described previously and are not repeated herein.

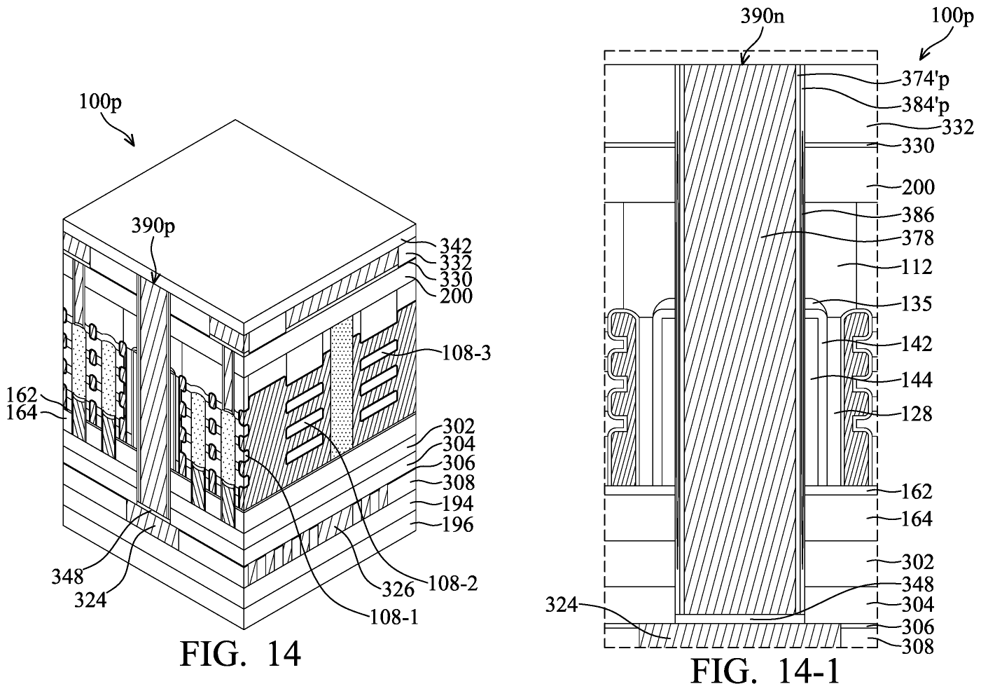

FIG. 14 illustrates a diagrammatic perspective view of a semiconductor structure 100p and FIG. 14-1 illustrates a cross-sectional view of the semiconductor structure 100p in accordance with some embodiments. The semiconductor structure 100p may be similar to the semiconductor structure 100n described previously, except only a single liner is formed in the through via structure in accordance with some embodiments. Processes and materials for forming the semiconductor structure 100p may be similar to, or the same as, those for forming the semiconductor structure 100n described previously and are not repeated herein.

More specifically, the processes shown in FIGS. 12A to 12Z may be performed, except the formation of the liner layer 370 is omitted, so that the dummy spacer layer (e.g. the dummy spacer layer 372) is directly formed on the sidewalls of the though via trench. Therefore, the semiconductor structure 100p includes a through via structure 390p, and through via structure 390p includes the conductive filling layer 378, sealing structures 384′p, and liners 374′p in accordance with some embodiments. In addition, air gaps 386p are formed in the sealing structures 384′p. The processes and materials for forming the sealing structures 384′p and the liners 374′p are similar to, or the same as, those for forming the sealing structures 284′ and the liners 274′ described previously and are not repeated herein.

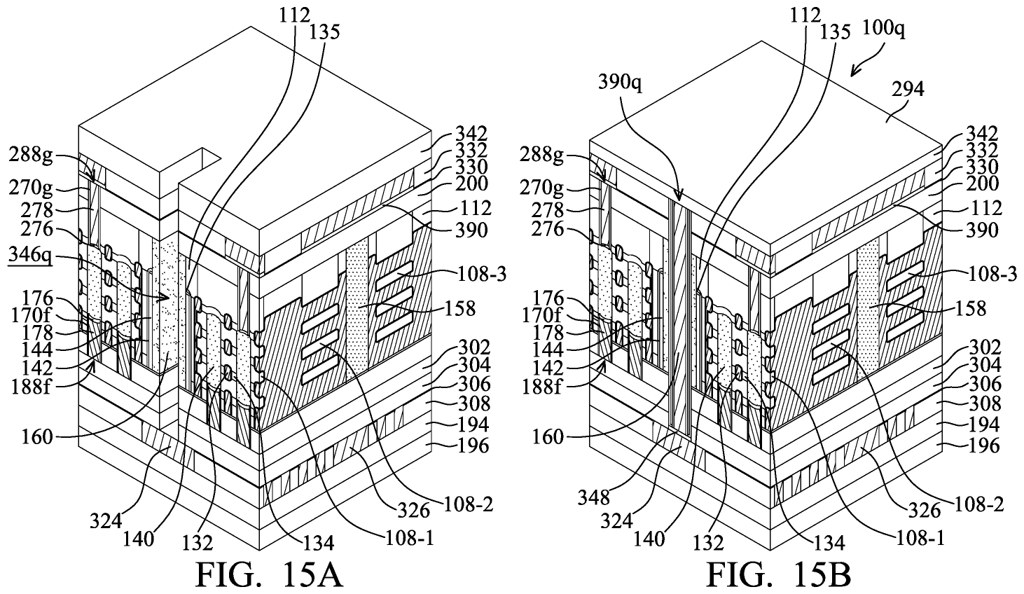

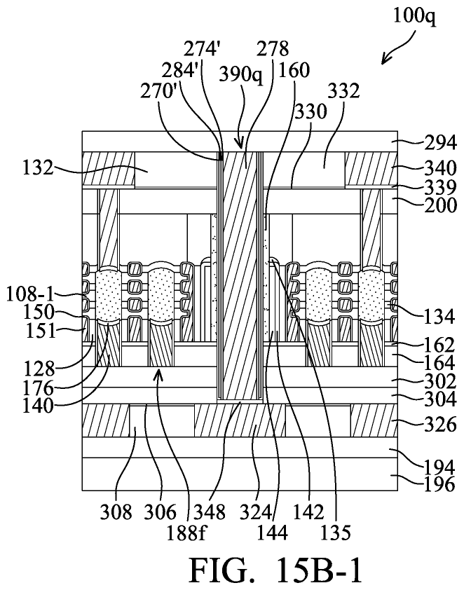

FIGS. 15A and 15B illustrate diagrammatic perspective views of intermediate stages of manufacturing a semiconductor structure 100q in accordance with some embodiments. The semiconductor structure 100q may be similar to the semiconductor structure 100n described previously, except the through via structure is narrower than that of the semiconductor structure 100n in accordance with some embodiments. Processes and materials for forming the semiconductor structure 100q may be similar to, or the same as, those for forming the semiconductor structure 100n described previously and are not repeated herein.

More specifically, the processes shown in FIGS. 12A to 12L are performed, and a through via trench 346q is formed through the dielectric layer 332, the etch stop layer 330, the mask layer 200, the wide isolation structure 160, the etch stop layer 162, the dielectric layer 164, the etch stop layer 302, and the dielectric layer 304, so that the wide conductive pad 324 is exposed, as shown in FIG. 15A in accordance with some embodiments. In some embodiments, the width of the through via trench 346 is smaller than the width of the wide isolation structure 160 along both the X direction and the Y direction. In some embodiments, the through via trench 346q is surrounded by the wide isolation structure 160 and is spaced apart from the contact etch stop layers 142, the interlayer dielectric layer 144, and the isolating capping layers 135.

Afterwards, the processes shown in FIGS. 12O to 12Z are performed to form the semiconductor structure 100q, as shown in FIG. 15B in accordance with some embodiments. FIG. 15B-1 illustrates a cross-sectional view of the semiconductor structure 100q in accordance with some embodiments. In some embodiments, a through via structure 390q formed in the through via trench 346q is surrounded by the wide isolation structure 160 and is spaced apart from the contact etch stop layers 142, the interlayer dielectric layer 144, and the isolating capping layers 135.

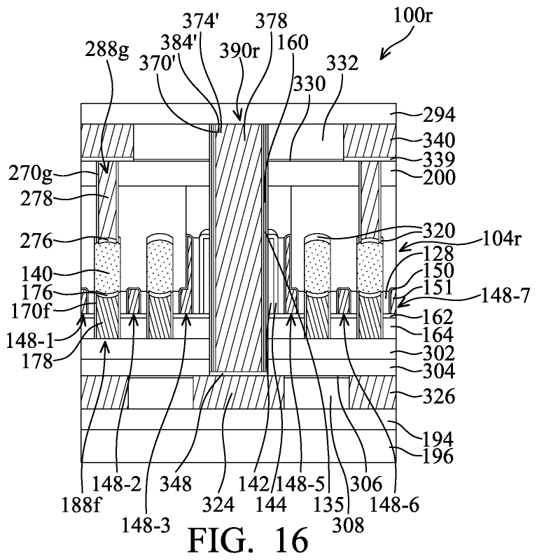

FIG. 16 illustrates a cross-sectional view of a semiconductor structure 100r in accordance with some embodiments. The semiconductor structure 100r may be similar to the semiconductor structure 100n described previously, except the semiconductor structure 100r is a FinFET structure in accordance with some embodiments. Processes and materials for forming the semiconductor structure 100r may be similar to, or the same as, those for forming the semiconductor structure 100n described previously and are not repeated herein.

More specifically, the substrate is patterned to form fin structures 104r without forming the first semiconductor material layers and the second semiconductor material layers thereon in accordance with some embodiments. The processes shown in FIGS. 12A to 12Z may be performed, except the channel members and the inner spacers are not formed. As shown in FIG. 16, the through via structure 390r is thicker than the fin structure 104r in the Z direction in accordance with some embodiments.

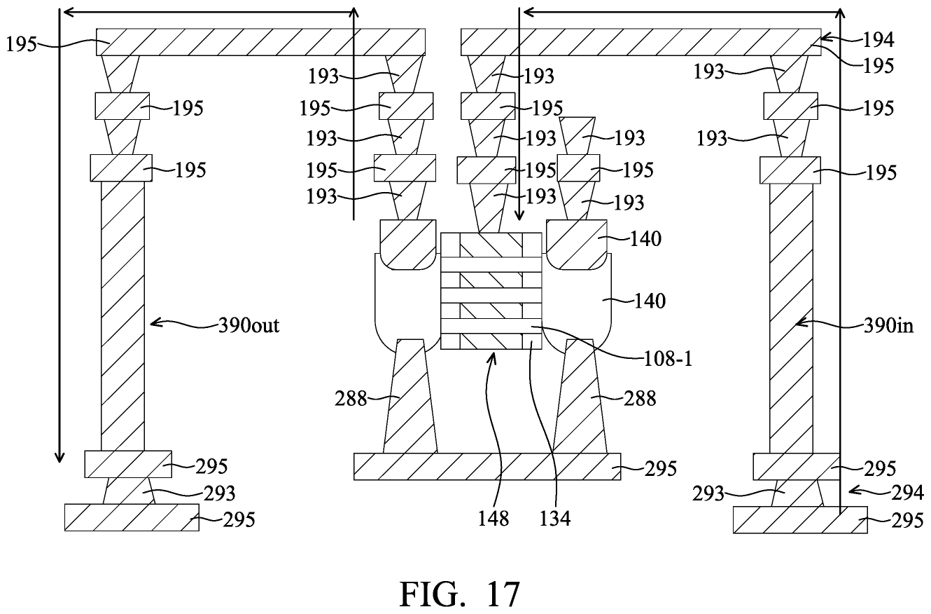

It should be appreciated that the through via structures (e.g. the through via structures 390 and 390n) may be used in various application. FIG. 17 illustrates through via structures used as input and output connection in a semiconductor device in accordance with some embodiments. More specifically, a transistor structure includes the channel members 108-1 vertically stacked and spaced apart from each other and the gate structure 148 wrapping around the channel members 108-1 in accordance with some embodiments. In addition, the inner spacers 134 are vertically stacked in the spaces between the channel members 108-1, and the source/drain structures 140 are attached to the channel members 108-1 in accordance with some embodiments.

Furthermore, the front end structure 194 is formed over the front side of the transistor structure, and the back end structure 294 is formed below the back side of the transistor structure in accordance with some embodiments. In some embodiments, the front end structure 194 includes vias 193 and metal lines 195, and the back end structure 294 includes vias 293 and metal lines 295. The source/drain contacts 188 are formed over the front side of the source/drain structures 140 to electrically connect the source/drain structures 140 and the front end structure 194 in accordance with some embodiments. In addition, the backside conductive vias 288 are formed below the backside of the source/drain structures 140 to electrically connect the source/drain structures 140 and the back end structure 294 in accordance with some embodiments. The backside conductive vias 288 may be configured to connect the backside power of the semiconductor device.

A through via structure 390ᵢₙ and a through via structure 390ₒᵤₜ are directly connected to both the front end structure 194 and the backend structure 294 in accordance with some embodiments. The through via structure 390ᵢₙ may be configured to pass input signal and the through via structure 390ₒᵤₜ may be configured to pass output signal in the semiconductor device. Since the through via structure 390ᵢₙ and the through via structure 390ₒᵤₜ are directly connected to both the front end structure 194 and the backend structure 294, complicated electrical routing may be avoided, and the size of the device may be reduced. In addition, the through via structure 390ᵢₙ and the through via structure 390ₒᵤₜ may be similar to, or the same as, the through via structures having air gaps formed under the sealing structure described previously, and the air gaps may help to reduce the capacitance of the semiconductor device in accordance with some embodiments.

It should be appreciated that the elements shown in the semiconductor structures 100 and 100a to 100r may be combined and/or exchanged. For example, the structures of the sealing structure 184′a shown in FIG. 3 may be applied to the sealing structures in other semiconductor structures. In addition, the semiconductor structures 100a to 100r may have similar, or the same, layout as that shown in FIG. 1.

As described above, a through via structure (e.g. the through via structure 390 and 390n) is formed to connect an interconnect structure in the front end structure (e.g. the front end structure 194) and an interconnect structure in the back end structure (e.g. the back end structure 294), so that complicated electrical routing may be reduced and signal routing resistance and capacitance may therefore be reduced in accordance with some embodiments. In addition, air gaps are formed in the liners of the through via structure, so that the coupling capacitance of the resulting semiconductor device may be further reduced. Furthermore, in some embodiments, the source/drain contacts (e.g. the source/drain contacts 188) and the backside conductive vias (e.g. the backside conductive vias 288) also have air gaps formed in the liners. Therefore, the coupling capacitance of the resulting semiconductor device may be further reduced.

It should be noted that same elements in FIGS. 1 to 17 may be designated by the same numerals and may include materials that are the same or similar and may be formed by processes that are the same or similar; therefore such redundant details are omitted in the interests of brevity. In addition, although FIGS. 1 to 17 are described in relation to the method, it will be appreciated that the structures disclosed in FIGS. 1 to 17 are not limited to the method but may stand alone as structures independent of the method. Similarly, the methods shown in FIGS. 1 to 17 are not limited to the disclosed structures but may stand alone independent of the structures. Furthermore, the channel members described above may include nanostructures such as nanowires, nanosheets, or other applicable nanostructures in accordance with some embodiments.

Also, while the disclosed methods are illustrated and described below as a series of acts or events, it should be appreciated that the illustrated ordering of such acts or events may be altered in some other embodiments. For example, some acts may occur in different orders and/or concurrently with other acts or events apart from those illustrated and/or described above. In addition, not all illustrated acts may be required to implement one or more aspects or embodiments of the description above. Further, one or more of the acts depicted above may be carried out in one or more separate acts and/or phases.

Furthermore, the terms “approximately,” “substantially,” “substantial” and “about” describe above account for small variations and may be varied in different technologies and be in the deviation range understood by the skilled in the art. For example, when used in conjunction with an event or circumstance, the terms can refer to instances in which the event or circumstance occurs precisely as well as instances in which the event or circumstance occurs to a close approximation.

Embodiments for forming semiconductor structures may be provided. The semiconductor structure may include a gate structure and an isolation structure formed through the gate structure. In addition, a through via structure may be formed through the isolation structure and spaced apart from the gate structure. Furthermore, an air gap is formed in the periphery region of the through via structure, so that the capacitance of the semiconductor structure may be reduced.

In some embodiments, a semiconductor structure is provided. The semiconductor structure includes a channel member having a longitudinal axis along a first direction, and the channel member has a first portion and a second portion separated from each other by a blank region. The semiconductor structure also includes a first gate structure formed over the blank region and having a longitudinal axis along a second direction different from the first direction and an isolation structure formed in the blank region and abutting the first gate structure in the second direction. The semiconductor structure also includes a through via structure formed through the isolation structure. In addition, the through via structure includes a first conductive filling layer, and a first air gap is sandwiched between the first conductive filling layer and the isolation structure.

In some embodiments, a semiconductor structure is provided. The semiconductor structure includes a channel member and a gate structure engaging the channel member. The semiconductor structure also includes a dielectric layer surrounding the gate structure and an isolation structure formed through the dielectric layer. The semiconductor structure also includes a backside conductive via formed adjacent to the gate structure and a source/drain structure formed over the backside conductive via and attaching to the channel member. The semiconductor structure also includes a source/drain contact formed over the source/drain structure and a through via structure formed through the isolation structure. In addition, an air gap is formed at a periphery region of the through via structure.

In some embodiments, a method for manufacturing a semiconductor structure is provided. The method for manufacturing the semiconductor structure includes forming a channel member having a longitudinal axis along a first direction, and the channel member has a first portion and a second portion separated from each other. The method for manufacturing the semiconductor structure also includes forming a gate structure between the first portion and the second portion of the channel member and having a longitudinal axis along a second direction. The method for manufacturing the semiconductor structure also includes forming an isolation structure abutting the gate structure and forming a first trench in the isolation structure. The method for manufacturing the semiconductor structure also includes forming a first dummy spacer over a sidewall of the first trench and forming a first liner covering the first dummy spacer. The method for manufacturing the semiconductor structure also includes forming a first conductive filling layer over the first liner in the first trench and removing the first dummy spacer to form a first gap exposing a sidewall of the first liner. The method for manufacturing the semiconductor structure also includes forming a first sealing structure to block a first end portion of the first gap.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor structure, comprising:
a channel member having a longitudinal axis in a first direction, wherein the channel member has a first portion and a second portion separated from each other by a blank region;
a first gate structure formed over the blank region and having a longitudinal axis in a second direction different from the first direction;
an isolation structure formed in the blank region and abutting the first gate structure in the second direction; and
a through via structure formed through the isolation structure, wherein the through via structure comprises a first conductive filling layer, and a first air gap is sandwiched between the first conductive filling layer and the isolation structure.

2. The semiconductor structure as claimed in claim 1, wherein the through via structure further comprises a second conductive filling layer vertically overlapping the first conductive filling layer, the first conductive filling layer has a first dimension in the first direction, the second conductive filling layer has a second dimension in the first direction, and the first dimension is greater than the second dimension.

3. The semiconductor structure as claimed in claim 2, wherein a second air gap is sandwiched between the second conductive filling layer and the isolation structure.

4. The semiconductor structure as claimed in claim 1, further comprising:
a second gate structure wrapping around the first portion of the channel member;
a source/drain structure attached to the first portion of the channel member;
a source/drain contact attached to a first side of the source/drain structure; and
a backside conductive via attached to a second side of the source/drain structure, wherein the second side is opposite the first side.

5. The semiconductor structure as claimed in claim 4, wherein the source/drain structure is sandwiched between the source/drain contact and the backside conductive via in a third direction, a thickness of the through via structure in the third direction is substantially equal to or greater than a distance between a top surface of the source/drain contact and a bottom surface of the backside conductive via in the third direction.

6. The semiconductor structure as claimed in claim 4, wherein a third air gap is formed in the source/drain contact.

7. The semiconductor structure as claimed in claim 4, wherein a fourth air gap is formed in the backside conductive via.

8. A semiconductor structure, comprising:
a channel member;
a gate structure engaging the channel member;
a dielectric layer surrounding the gate structure;
an isolation structure formed through the dielectric layer;
a backside conductive via formed adjacent to the gate structure;
a source/drain structure formed over the backside conductive via and attached to the channel member;
a source/drain contact formed over the source/drain structure; and
a through via structure formed through the isolation structure, wherein an air gap is formed at a periphery region of the through via structure.

9. The semiconductor structure as claimed in claim 8, wherein the through via structure comprises:
a conductive filling layer;
a first liner covering a sidewall of the conductive filling layer; and
a sealing structure at least partially covering a sidewall of the first liner, wherein the air gap is below a top surface of the sealing structure.

10. The semiconductor structure as claimed in claim 9, wherein the air gap is embedded in the sealing structure.

11. The semiconductor structure as claimed in claim 9, further comprising:
a second liner at least partially covering a sidewall of the sealing structure, wherein the air gap is sandwiched between the first liner and the second liner.

12. The semiconductor structure as claimed in claim 8, further comprising:
a first interconnect structure formed over and connected to the source/drain contact; and
a second interconnect structure formed below and connected to the backside conductive via,
wherein a first end of the through via structure is connected to the first interconnect structure, and a second end of the through via structure is connected to the second interconnect structure.

13. A method for manufacturing a semiconductor structure, comprising:
forming a channel member having a longitudinal axis in a first direction, wherein the channel member has a first portion and a second portion separated from each other;
forming a gate structure between the first portion and the second portion of the channel member and having a longitudinal axis in a second direction;
forming an isolation structure abutting the gate structure;
forming a first trench in the isolation structure;
forming a first dummy spacer over a sidewall of the first trench;
forming a first liner covering the first dummy spacer;
forming a first conductive filling layer over the first liner in the first trench;
removing the first dummy spacer to form a first gap exposing a sidewall of the first liner; and
forming a first sealing structure to block a first end portion of the first gap.

14. The method for manufacturing the semiconductor structure as claimed in claim 13, wherein a first air gap is embedded in the first sealing structure.

15. The method for manufacturing the semiconductor structure as claimed in claim 13, further comprising:
forming a second liner on the sidewall of the first trench,
wherein a first air gap is sandwiched between the first liner and the second liner.

16. The method for manufacturing the semiconductor structure as claimed in claim 13, further comprising:
forming a second trench in the isolation structure; and
forming a second conductive filling layer in the second trench,
wherein the first conductive filling layer is in physical contact with the second conductive filling layer.

17. The method for manufacturing the semiconductor structure as claimed in claim 16, further comprising:
forming a second dummy spacer over a sidewall of the second trench;
forming a third liner covering the second dummy spacer;
forming the second conductive filling layer over the third liner in the second trench;
removing the second dummy spacer to form a second gap exposing a sidewall of the third liner; and
forming a second sealing structure to block a second end portion of the second gap,
wherein a second air gap is formed adjacent to the third liner.

18. The method for manufacturing the semiconductor structure as claimed in claim 13, further comprising:
forming a source/drain structure abutting the first portion of the first channel member, wherein the source/drain structure is substantially aligned with the first portion and the second portion of the channel member in the first direction;
forming a source/drain contact connected to a first side of the source/drain structure; and
forming a backside conductive via connected to a second side of the source/drain structure, wherein the second side is opposite the first side,
wherein the source/drain contact, the source/drain structure, and the backside conductive via are substantially aligned in a third direction.

19. The method for manufacturing the semiconductor structure as claimed in claim 18, wherein a thickness of the first filling layer in the third direction is greater than a thickness of the gate structure in the third direction.

20. The method for manufacturing the semiconductor structure as claimed in claim 13, wherein the first dummy spacer is made of Si, SiGe, SiGeB, or SiB.
